(19) United States
(12) Patent Application Publication
(10) Pub. No.: US 2015/0315460 A1
(43) Pub. Date: Nov. 5, 2015

(54) LUMINESCENT QUANTUM DOT

(71) Applicant: DONGJIN SEMICHEM Co., Ltd., Incheon (KR)

(72) Inventors: Geun-Tae GIM, Hawaseong (KR); Hyun-Cheol AN, Hawaseong (KR); Ho-Wan HAM, Hawaseong (KR); Jeong-Woo HAN, Hawaseong (KR); Dong-Jun KIM, Hawaseong (KR); Hee-Yeop CHAE, Hawaseong (KR)

(21) Appl. No.: 14/649,235

(22) PCT Filed: Dec. 3, 2013
(86) PCT No.: PCT/KR2013/011106

§ 371 Date: Jun. 3, 2015

(30) Foreign Application Priority Data
Dec. 3, 2012 (KR) 10-2012-0138758
Dec. 3, 2013 (KR) 10-2013-0148953

(51) Int. Cl. C09K 11/06; H01L 51/00; C09K 11/88

(52) U.S. Cl. CPC C09K 11/06; C09K 11/883; H01L 51/0052; H01L 51/0054; H01L 51/0055; H01L 51/0056; H01L 51/0072; H01L 51/0071; H01L 51/0073; H01L 51/0085; H01L 51/0086; H01L 51/0087; H01L 51/0089; H01L 51/0088; Y10S 977/774; B82Y 20/00

(57) ABSTRACT

The present invention relates to a light-emitting quantum dot, and more particularly, to a light-emitting quantum dot of which ligand for capping the quantum dot contains a light-emitting material and which has excellent dispersibility and stability in an aqueous solution and has high color purity and light-emitting properties when applied to a light-emitting device, and a method for the preparation of the same.

### BACKGROUND OF THE INVENTION

The present invention relates to a light-emitting quantum dot, and more particularly, to a light-emitting quantum dot of which ligand for capping the quantum dot contains a light-emitting material and which has excellent dispersibility and stability in an aqueous solution and has high color purity and light-emitting properties when applied to a light-emitting device, and a method for the preparation of the same.

A quantum dot, which is a semiconductor material of a nano size, exhibits quantum confinement effects. When the quantum dot receives light from an excitation source and reaches its energy excitation state, it releases energy according to its own given energy band gap. Also, since its electrical and optical properties can be adjusted by controlling the size of the quantum dot to adjust its given band gap, its emission wavelength can be easily controlled by merely controlling the size of the quantum dot, and since it shows excellent color purity and high luminous efficiency, it can be applied to various devices such as a light-emitting device or photoelectric conversion device.

Previously developed quantum dots as a light-emitting device have poor dispersibility and stability in aqueous solutions and also show undesirable color purity and light-emitting properties so that they have difficulties in use as a light-emitting device, and steady researches for addressing these issues are going on.

### SUMMARY OF THE INVENTION

In order to solve the above problems, it is an object of the present invention to provide a light-emitting quantum dot having excellent dispersibility and stability in an aqueous solution and high color purity and light-emitting properties when applied to a light-emitting device, a method for the preparation of the same, and a light-emitting device comprising the same.

To achieve the above object, the present invention provides a quantum dot comprising a core/shell structure and a ligand which is attached to the surface of the shell, wherein the ligand comprises a light-emitting group.

Further, the invention provides a method for the preparation of a light-emitting quantum dot comprising adding a ligand containing a light-emitting group to a solution dispersed with a core/shell structure, and then stirring it.

Still further, the invention provides a light-emitting device comprising the above light-emitting quantum dot as a light-emitting material.

Still further, the invention provides a method of manufacturing a light-emitting device comprising a step of forming a light-emitting layer using the above light-emitting quantum dot.

The light-emitting quantum dot in accordance with the present invention has excellent dispersibility and stability in an aqueous solution and is excellent in color purity and light-emitting properties when applied to a light-emitting device so that it enables excellent color purity, high stability, and high luminous efficiency when compared to the previous light-emitting devices.

### BRIEF DESCRIPTION OF THE DRAWINGS

FIG. 1 shows a method for the preparation of QD according to one embodiment of the present invention.

FIG. 2 shows a schematic diagram of a light-emitting device using a light-emitting quantum dot according to one embodiment of the invention.

FIG. 3 shows UV absorption and PL spectrum measurement of a light-emitting quantum dot according to one embodiment of the invention.

FIG. 4 shows UV absorption and PL spectrum measurement of a light-emitting device according to one embodiment of the invention.

FIG. 5 shows IVL characteristics and EL spectrum measurement of an electroluminescent (EL) device according to one embodiment of the invention.

FIG. 6 shows the color coordinates of an electroluminescent (EL) device according to one embodiment of the invention.

### DETAILED DESCRIPTION OF THE INVENTION

Hereafter, the present invention will be described in detail.

The light-emitting quantum dot of the present invention is a quantum dot comprising a core/shell structure and a ligand which is attached to the surface of the shell, which is characterized in that the ligand comprises a light-emitting group.

The ligand comprises a light-emitting group, and a linking group for connecting the light-emitting group and the shell, and if necessary, may include a spacer between the linking group and the light-emitting group.

The following structural formula 1 shows a schematic diagram of a light-emitting quantum dot according to one embodiment of the present invention.

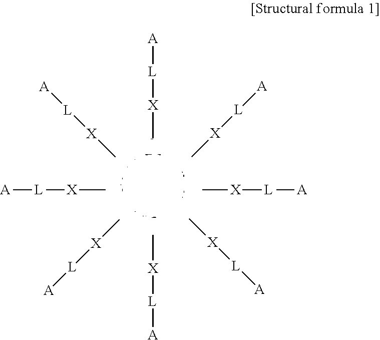

In the above structural formula 1, A represents a light-emitting group, L represents a spacer, and X represents a linking group. In the present invention, the light-emitting groups may be each independently the same as or different from one another and they may emit the same color or two or more different colors at the same time.

For the core/shell structure in the light-emitting quantum dot of the present invention, a known core/shell structure may be used and for example, a core/shell structure described in Korea Patent Application Publication No. 2010-35466 may be utilized. More particularly, the core/shell structure may be a substance selected from the group consisting of a) a first element selected from Group 2, Group 12, Group 13 and Group 14, and a second element selected from Group 16; b) a first element selected from Group 13, and a second element selected from Group 15; and c) an element of Group 14, or a core/shell structure formed therefrom and for example, there can be used at least one selected from the group consisting of MgO, MgS, MgSe, MgTe, CaO, CaS, CaSe, CaTe, SrO, SrS, SrSe, SrTe, BaO, BaS, BaSe, BaTE, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs, InSb, BP, Si, and Ge, or a structure in a core/shell shape formed therefrom.

The average diameter of the above core/shell structure can be optionally controlled, and those of 1-12 nm may be used. Preferably, the core/shell structure for emitting light in the region of 500 to 800 nm may have a diameter of 5-12 nm, and the core/shell structure for emitting light in the region of 400 to 500 nm may have a diameter of 1-3 nm.

In addition, for the light-emitting group in the light-emitting quantum dot of the present invention, a group for emitting light between 400 and 800 nm can be applied.

For the light-emitting group, a known light-emitting group may be used and for example, fluorescent or phosphorescent light-emitting group may be used. More particularly, the light-emitting group may be any one of FL1 to FL38, or PL1 to PL59.

In the following FL1 to FL38, or PL1 to PL59, * is a connection portion wherein the connection portion may be connected to at least one of the substitution positions in parentheses, and R1 to R16 are each independently hydrogen; deuterium; halogen; an amino group; a nitrile group; a nitro group; an alkyl group of C₁-C₄₀; an alkenyl group of C₂-C₄₀; an alkoxy group of C₁-C₄₀; a cycloalkyl group of C₃-C₄₀; a heterocycloalkyl group of C₃-C₄₀; an aryl group of C₆-C₄₀; a heteroaryl group of C₃-C₄₀; an aralkyl group of C₃-C₄₀; an aryloxy group of C₃-C₄₀; an arylthio group of C₃-C₄₀ optionally substituted with deuterium, halogen, an amino group, a nitrile group or a nitro group; or Si. Optionally, two or more selected from R1 to R16 may be bonded to one another to form a ring, and S, N, O, or Si may be included.

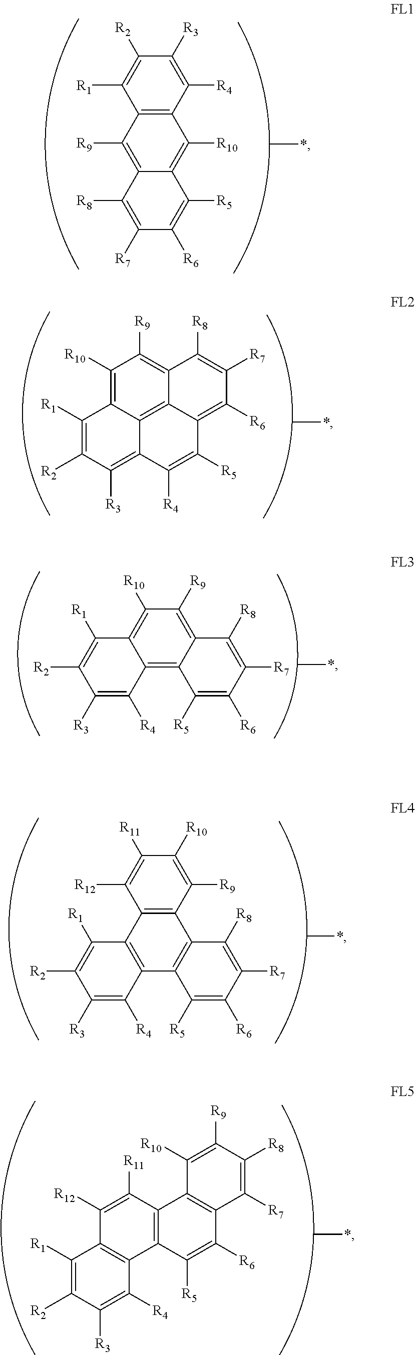

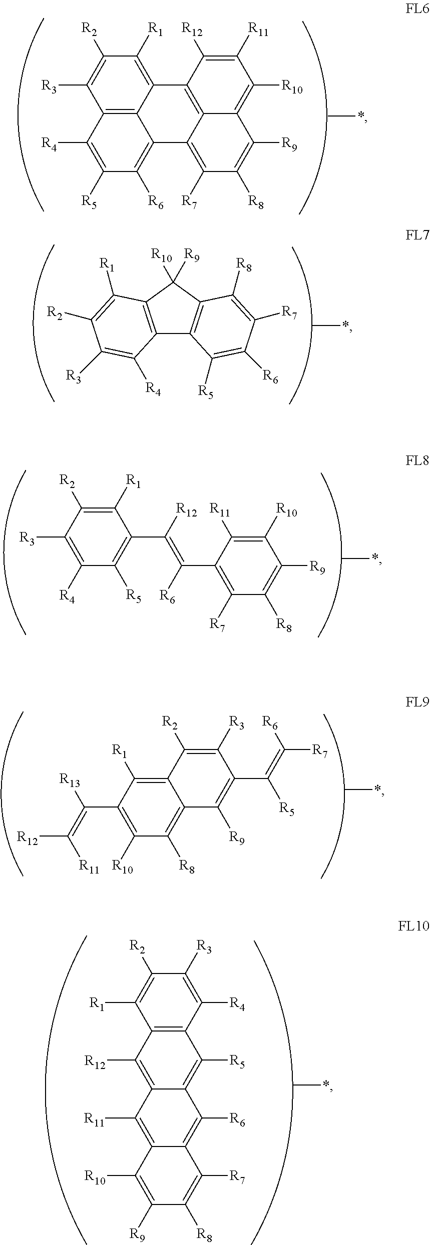

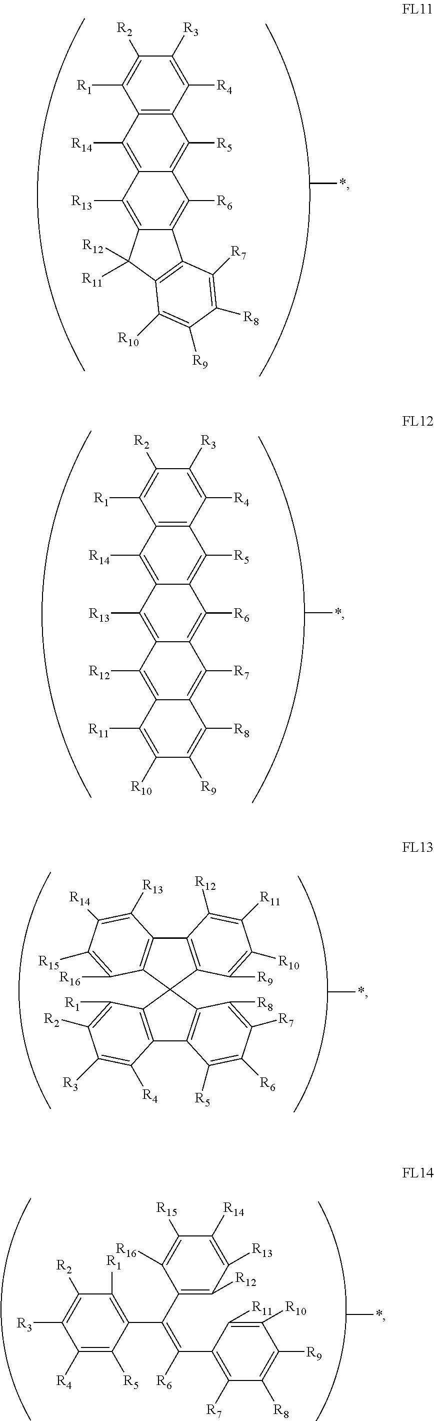

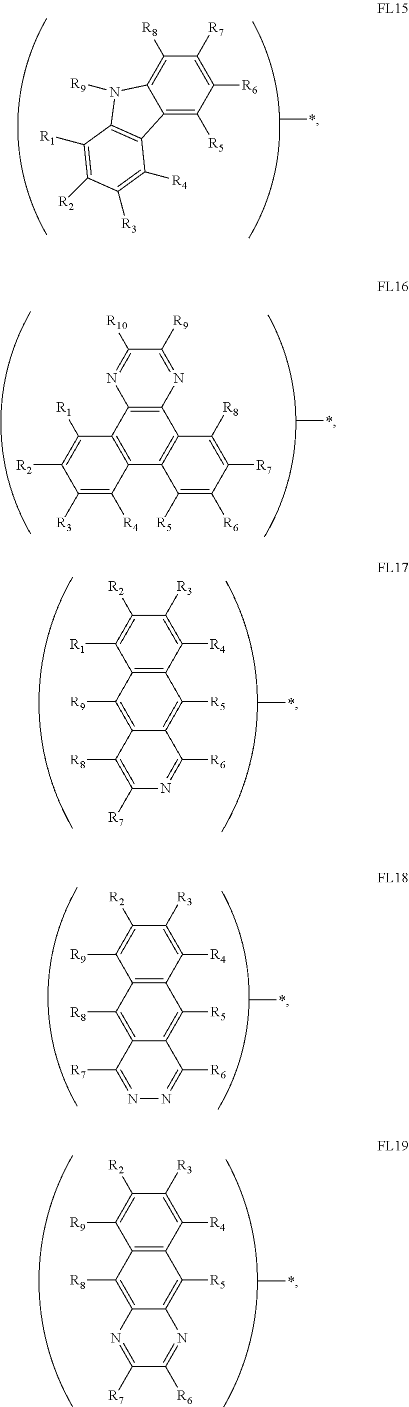

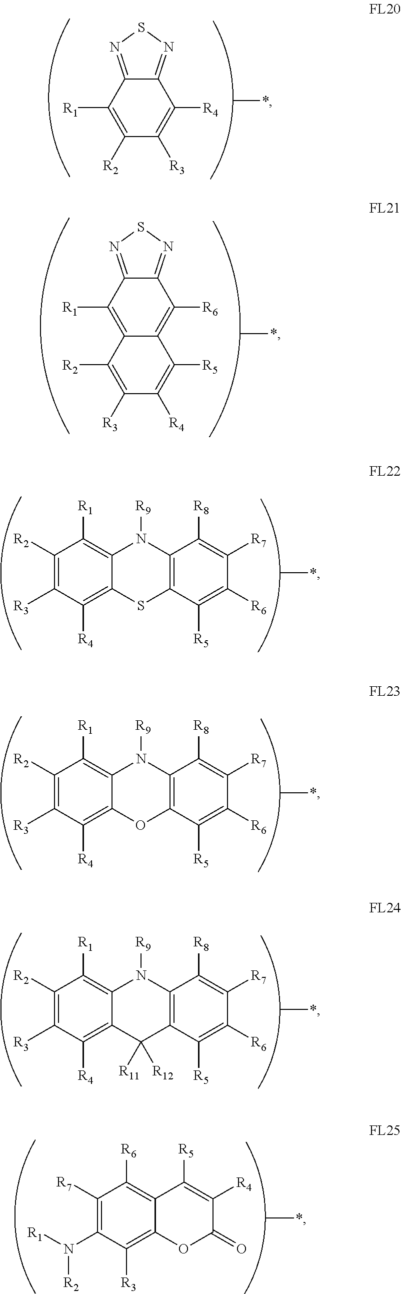

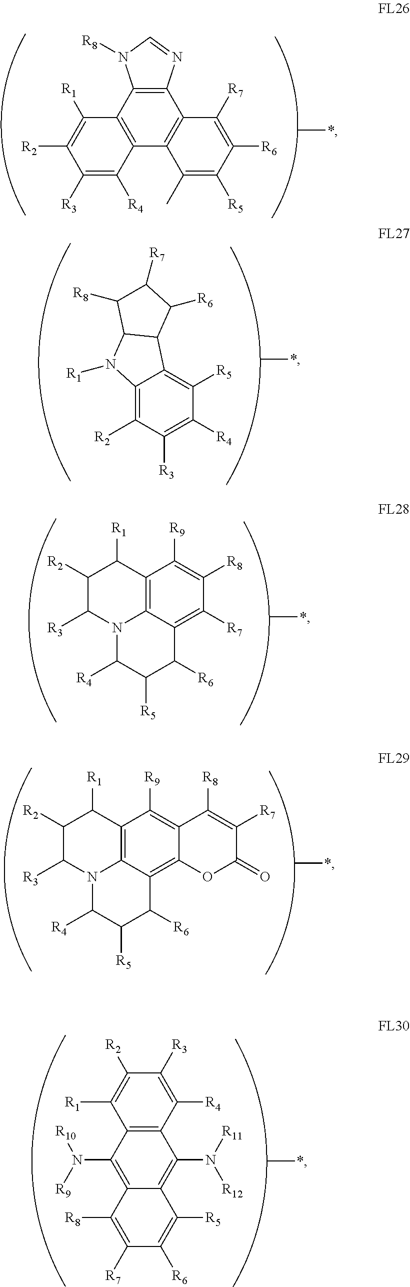

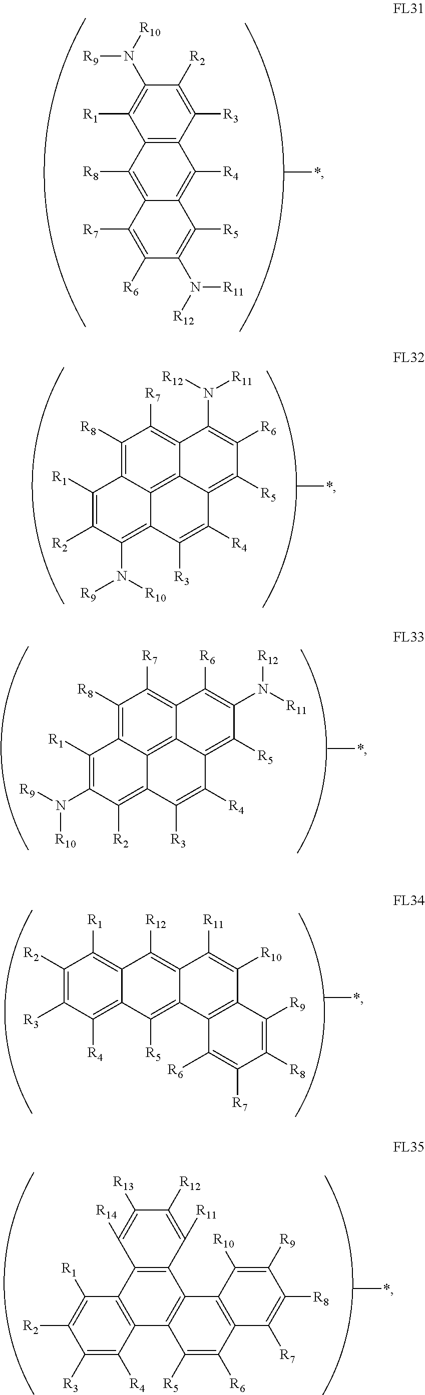

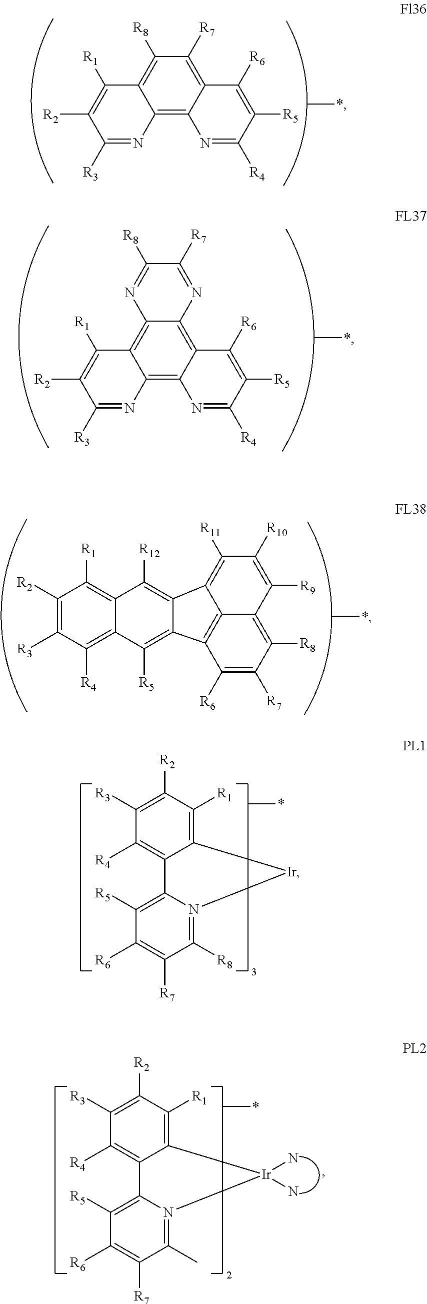

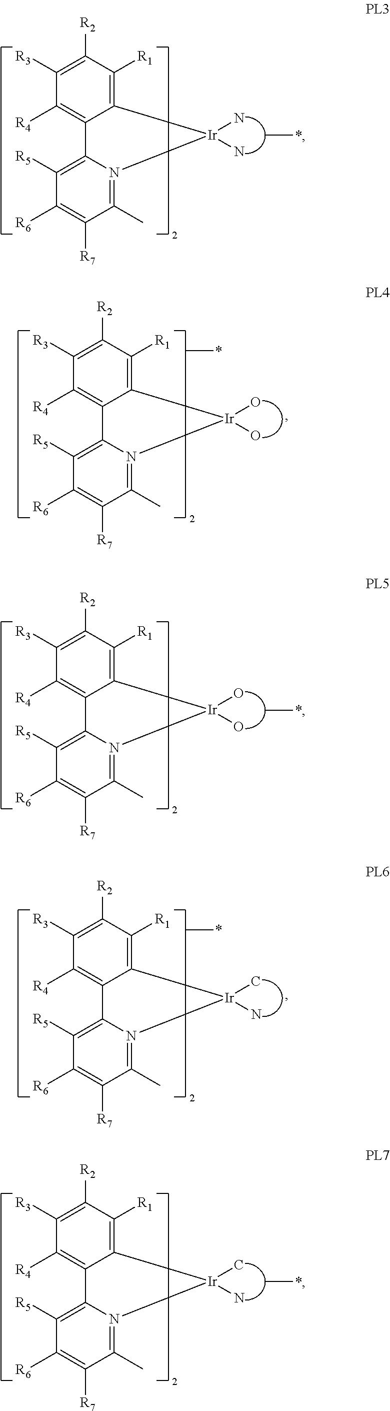

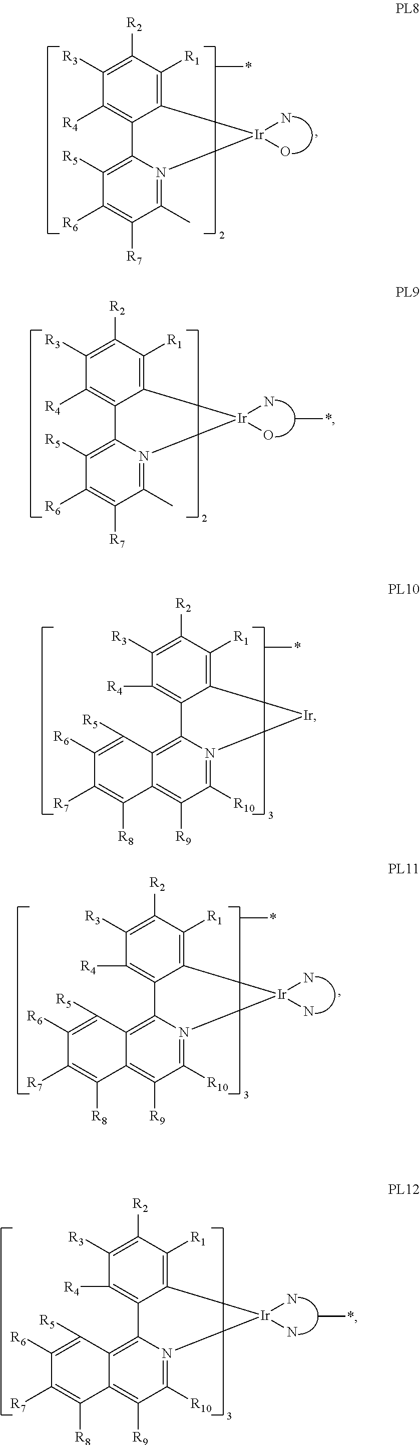

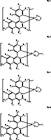

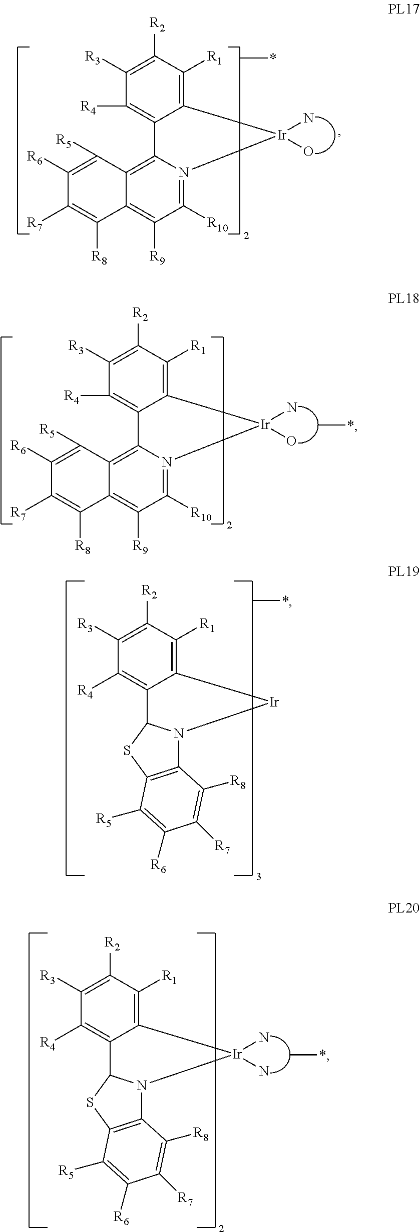

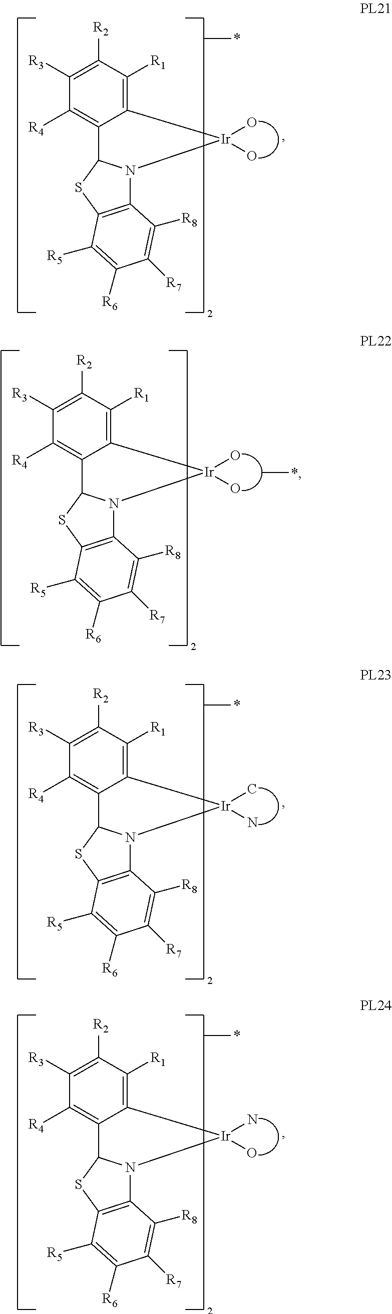

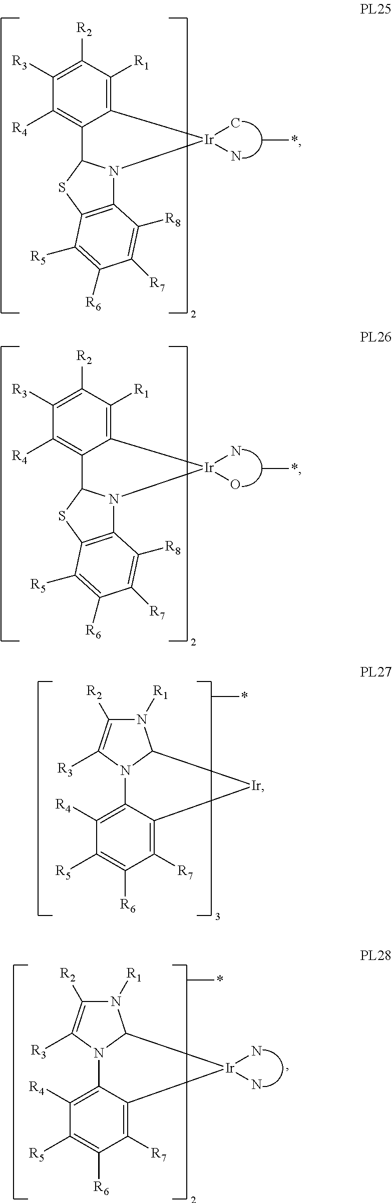

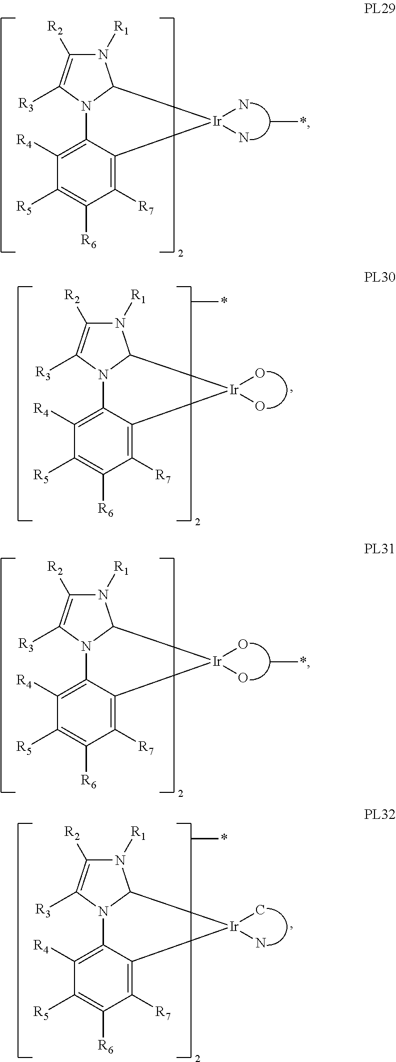

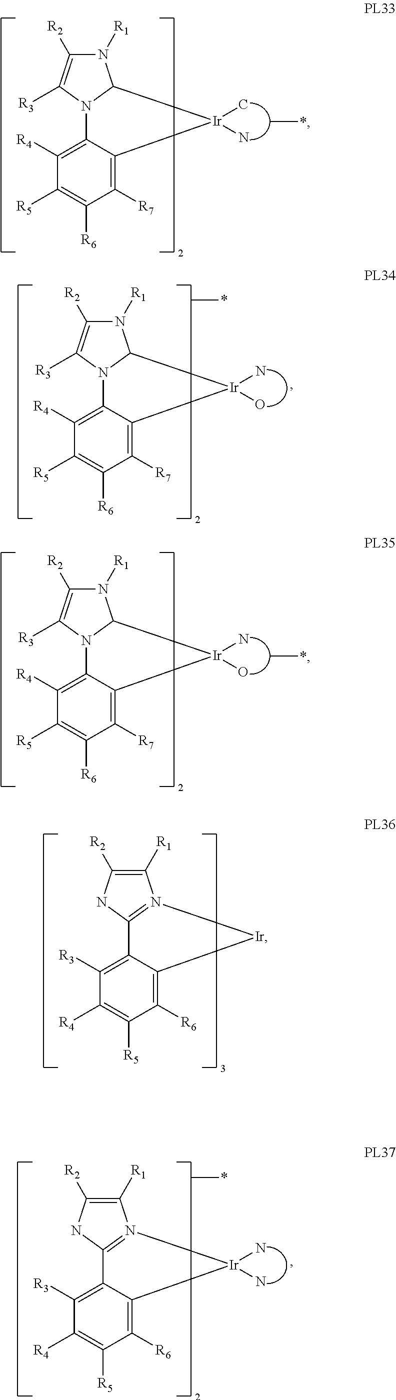

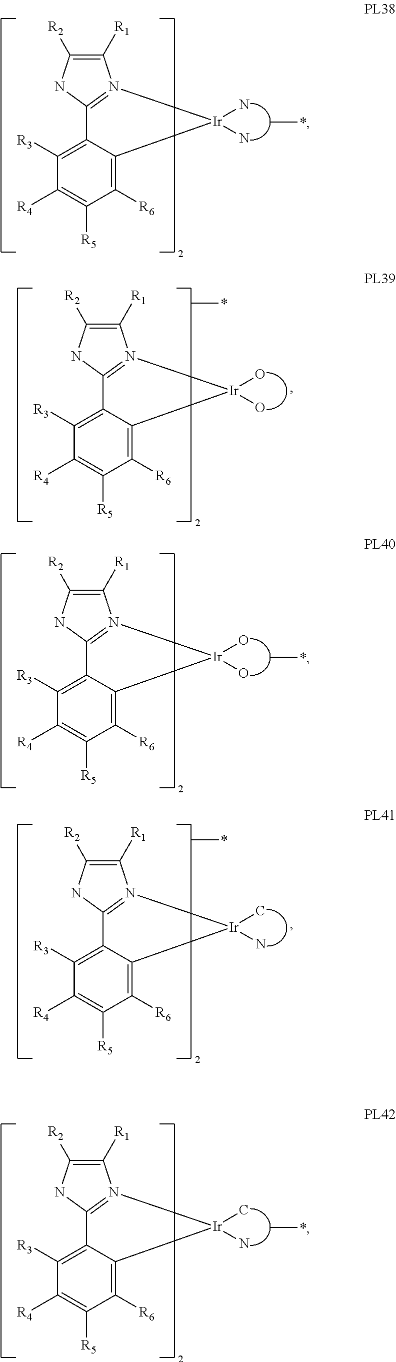

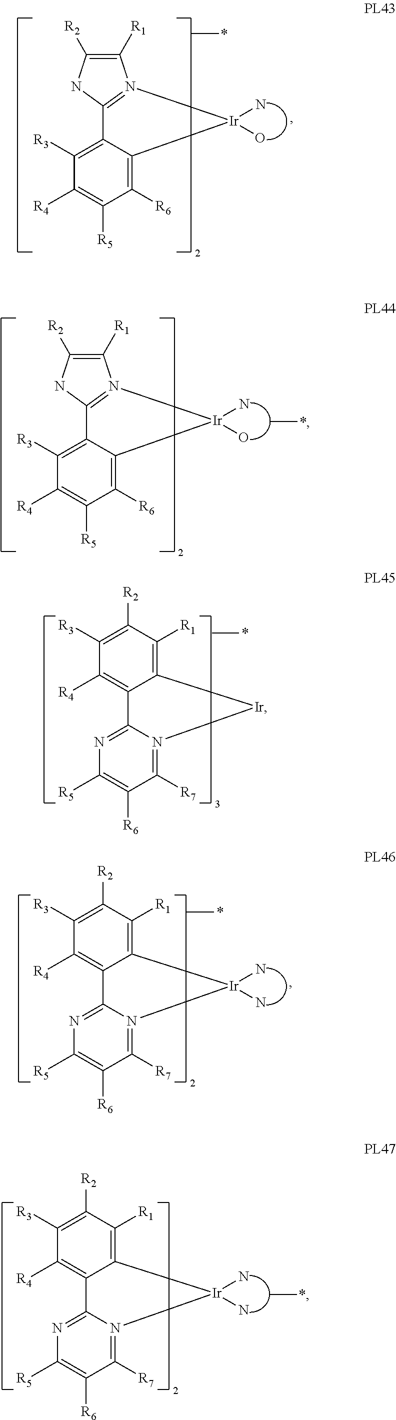

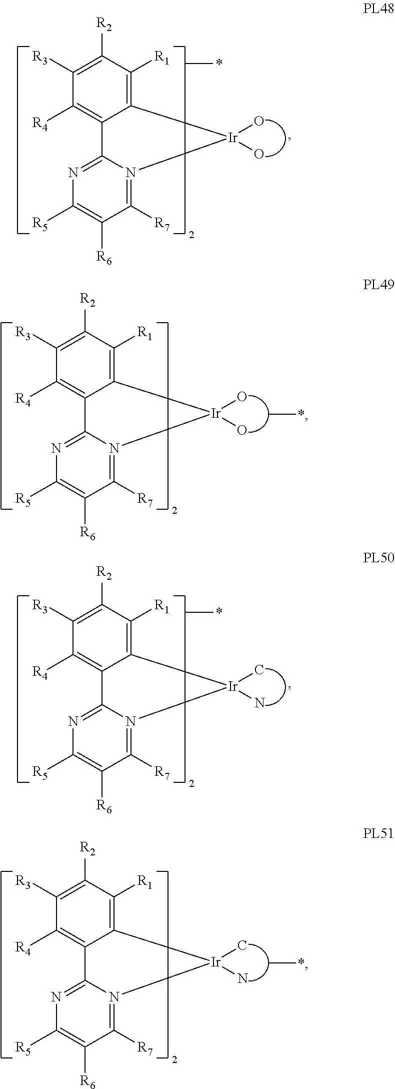

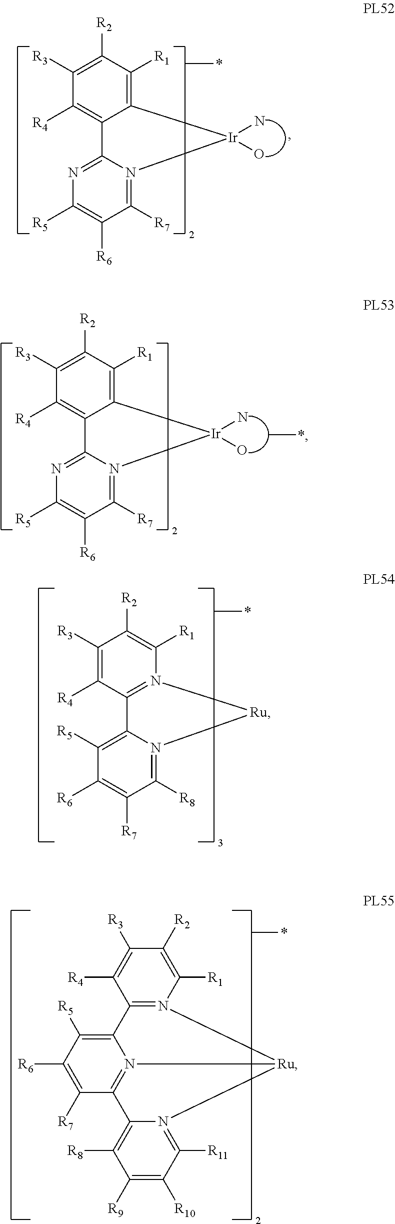

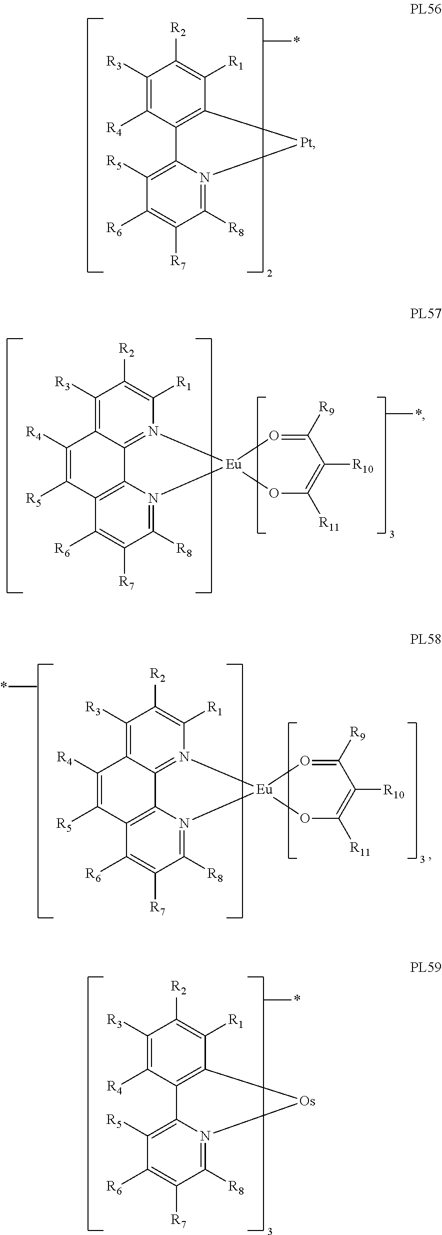

In addition, the above linking group in the light-emitting quantum dot of the present invention is not particularly limited to a specific one as long as it can be connected to a light-emitting group or a spacer while being attached to the shell and for example, there can be used one or more groups selected from the group consisting of a thiol group, carboxy group, amine group, phosphine group and phosphide. Preferably, the linking group is a thiol.

Also, the light-emitting quantum dot of the present invention may further a spacer between the light-emitting group and the linking group. The spacer may expand the number of light-emitting groups capable of being attached to the core/shell structure, facilitate the dispersion of the ligand containing the light-emitting material in a solvent during the preparation of the light-emitting quantum dot, and block energy transfer to contribute to the achievement of high purity white color. Specifically, the spacer may be a substituted or unsubstituted, saturated or unsaturated alkyl group of C₁-C₃₀, cycloalkyl group of C₃-C₄₀, or silane of Si₁-Si₃₀, but not be limited thereto.

Preferably, the light-emitting quantum dot of the present invention may comprise the light-emitting group, the spacer, and the linking group altogether, and for example, it may have structures shown below. In the following structures, a portion H in —SH, COOH, and NH is a portion for binding to the core/shell structure.

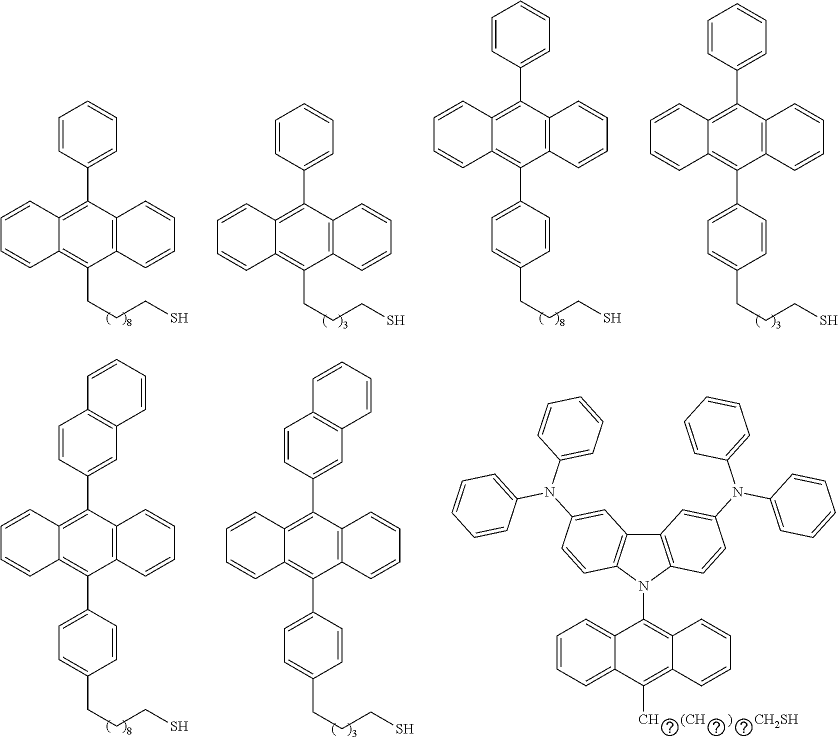

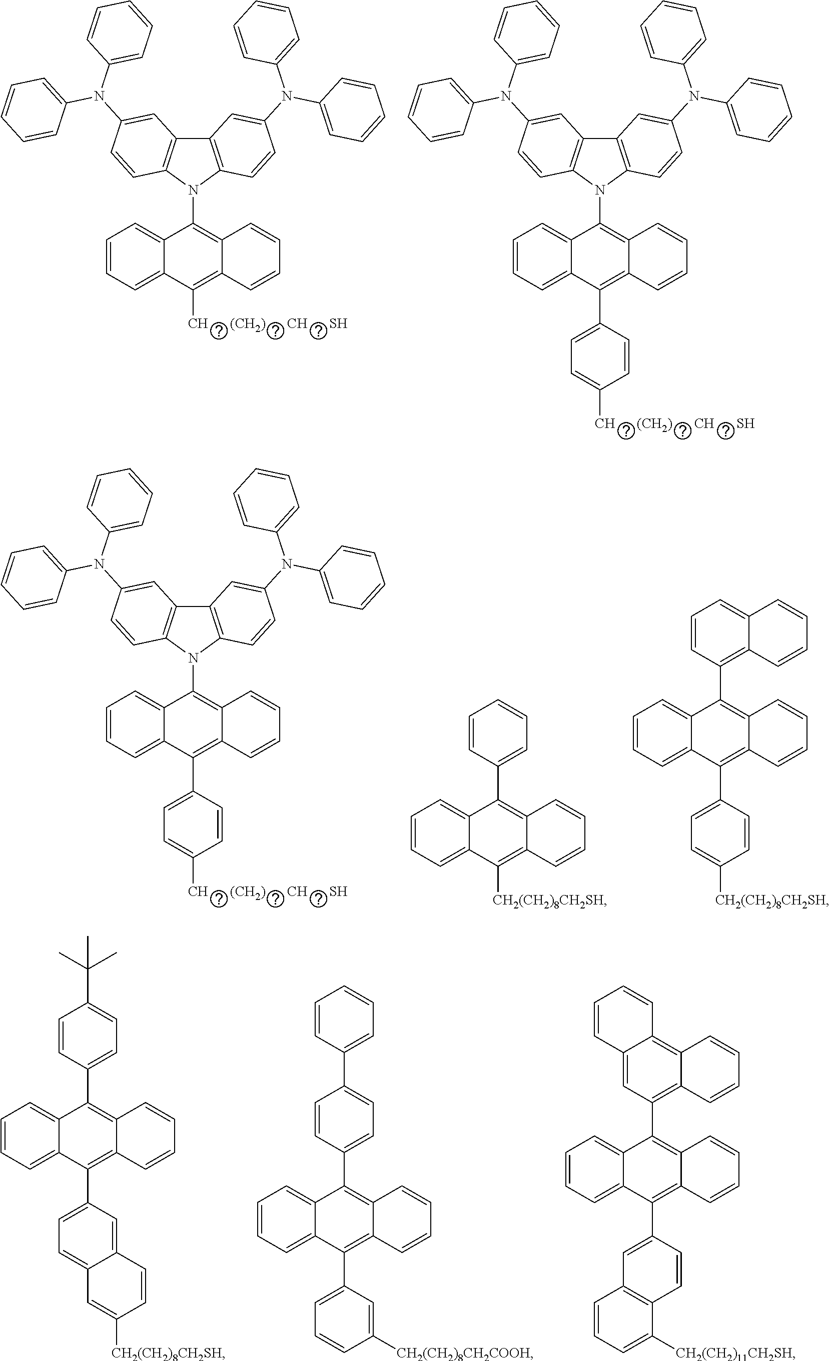

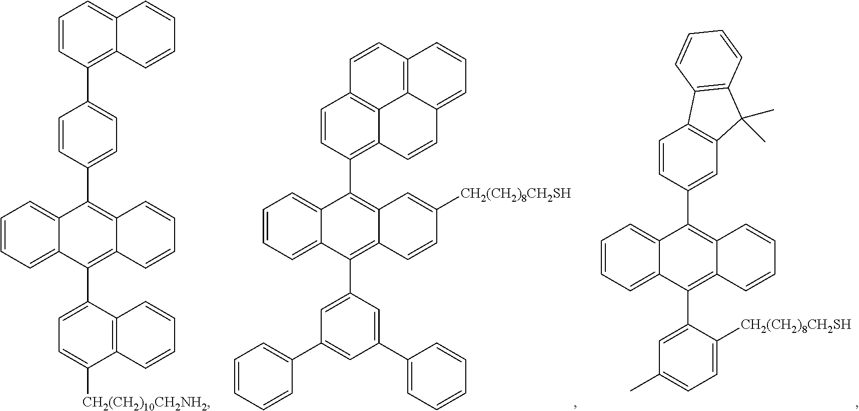

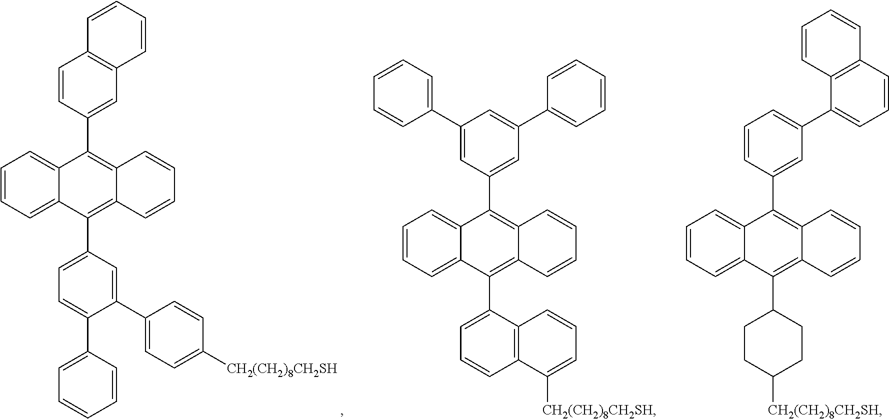

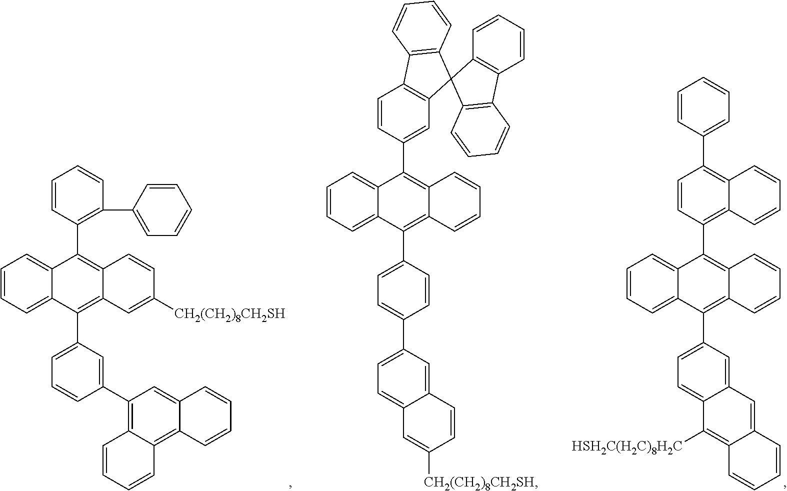

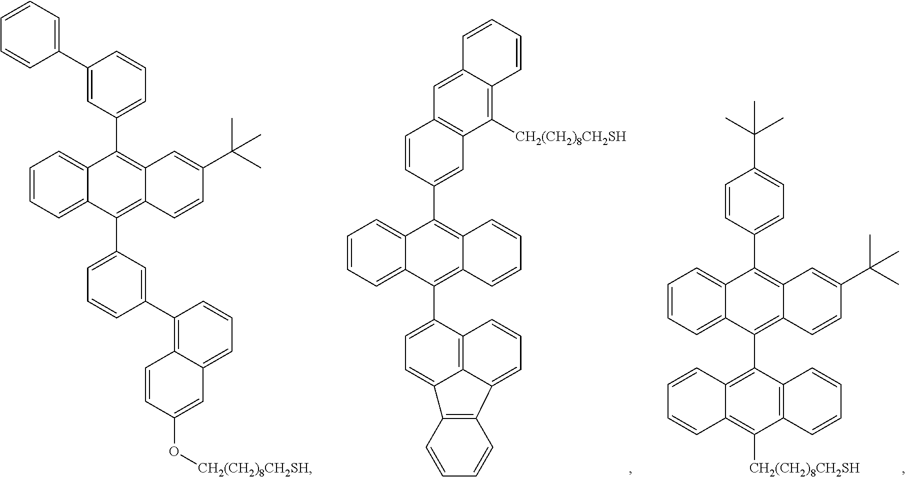

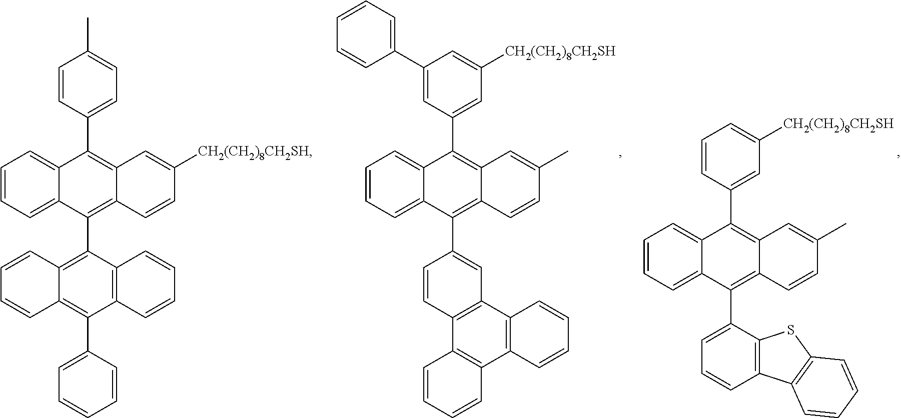

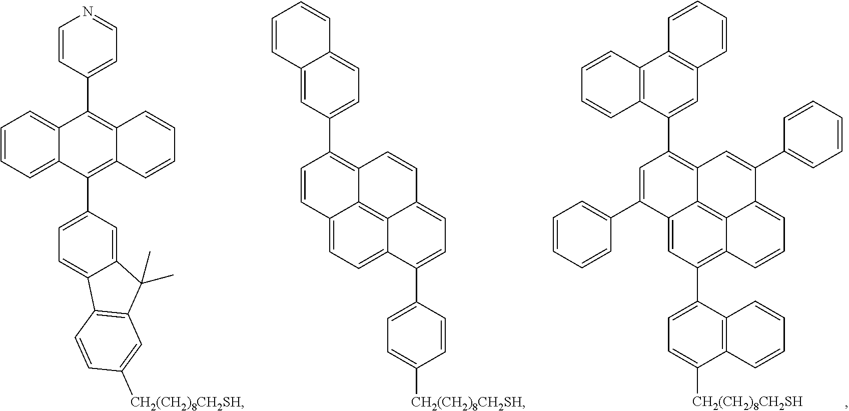

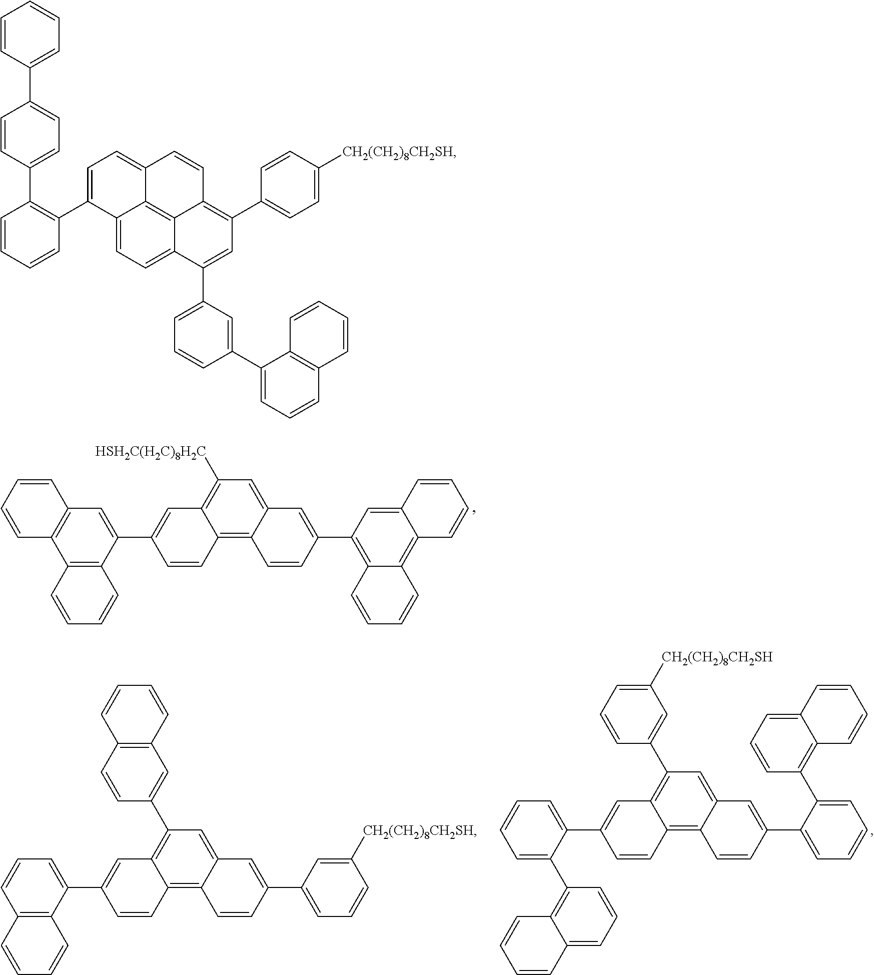

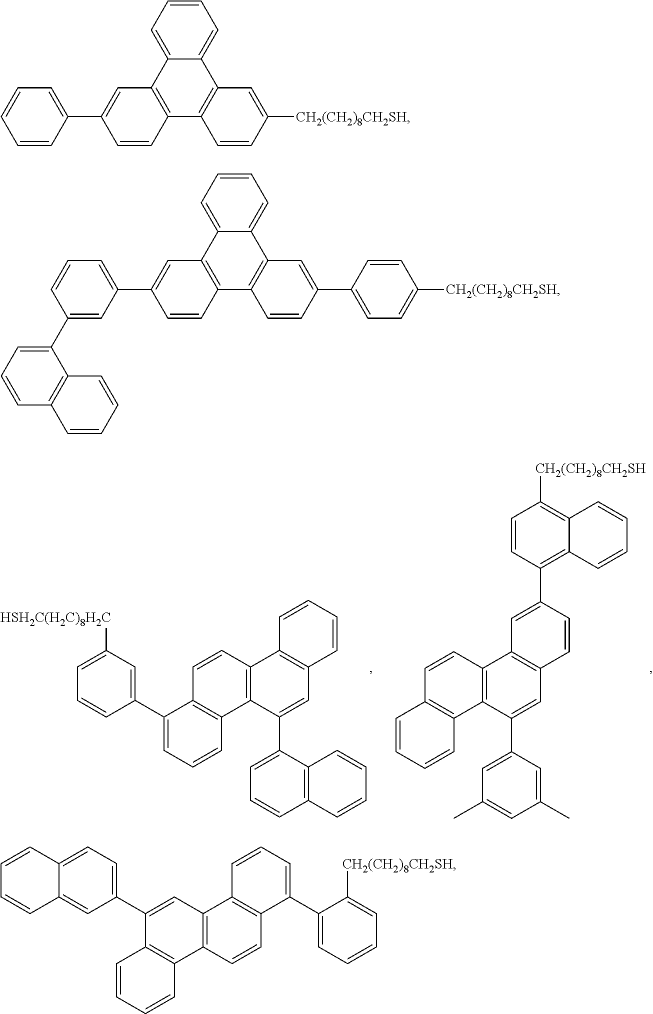

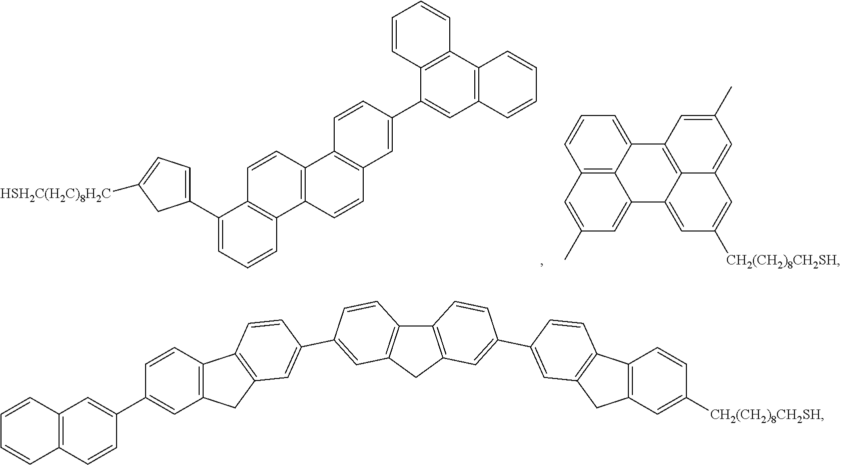

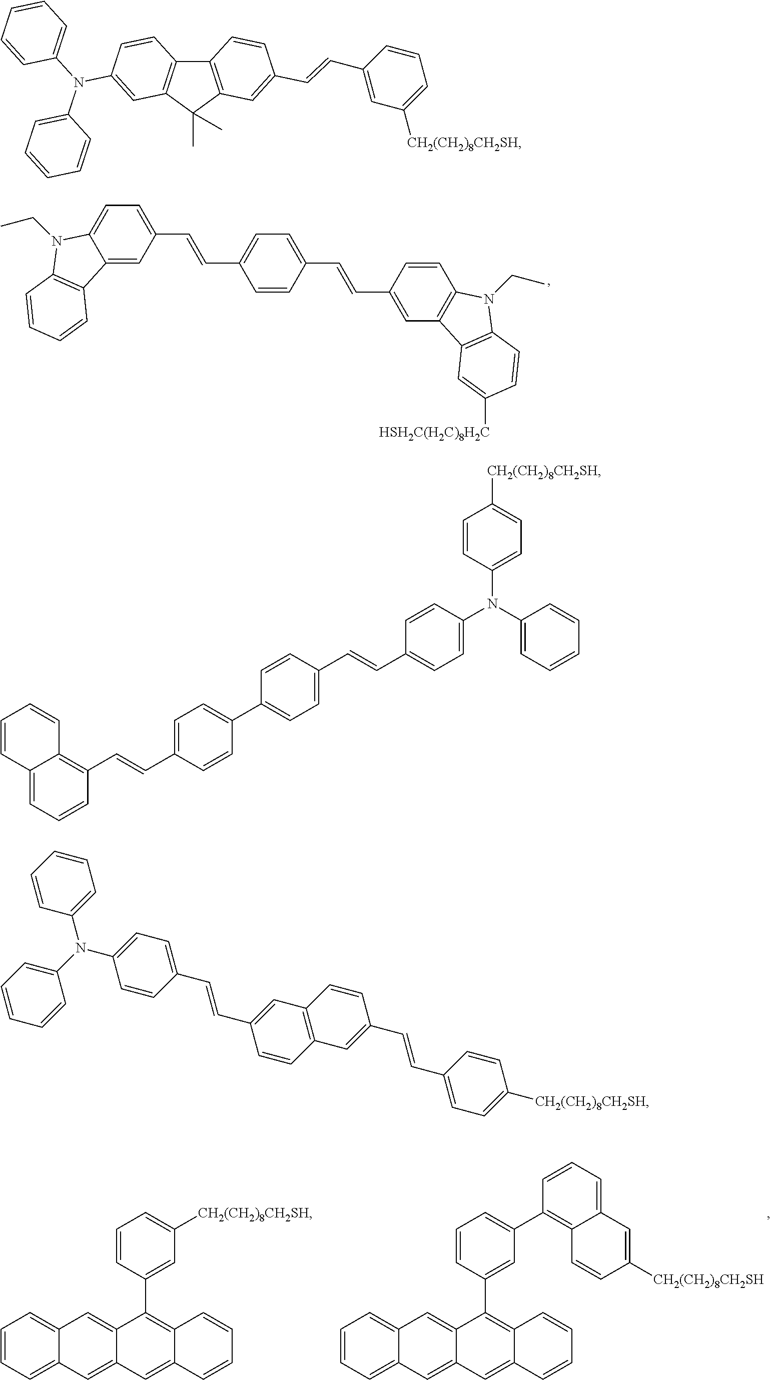

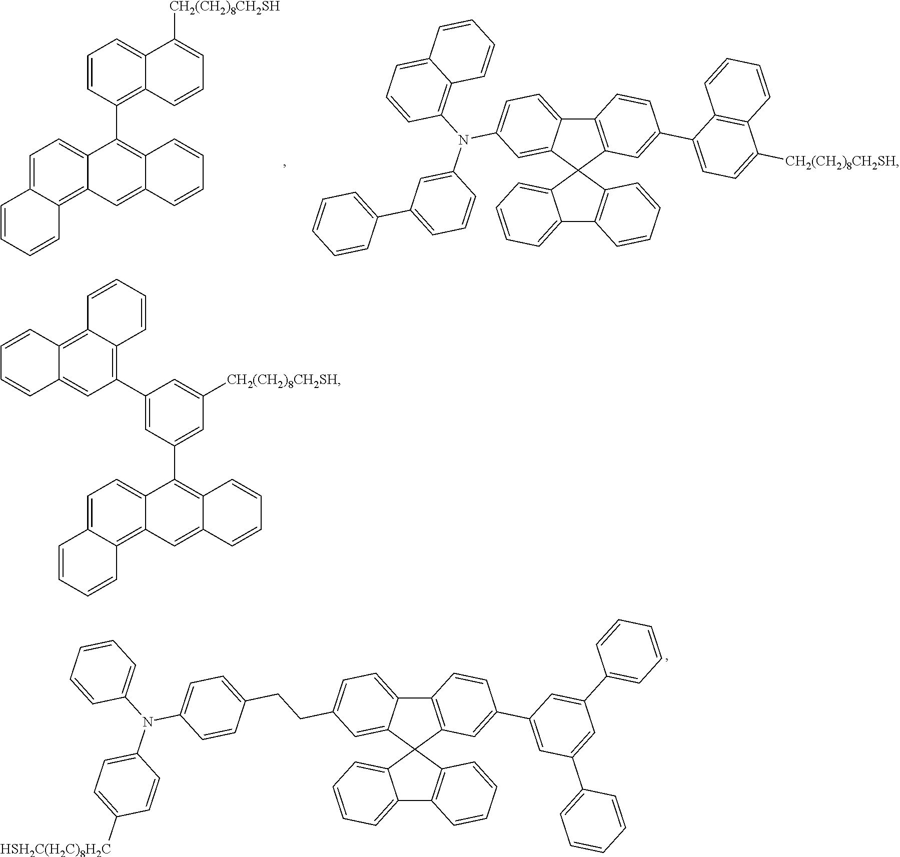

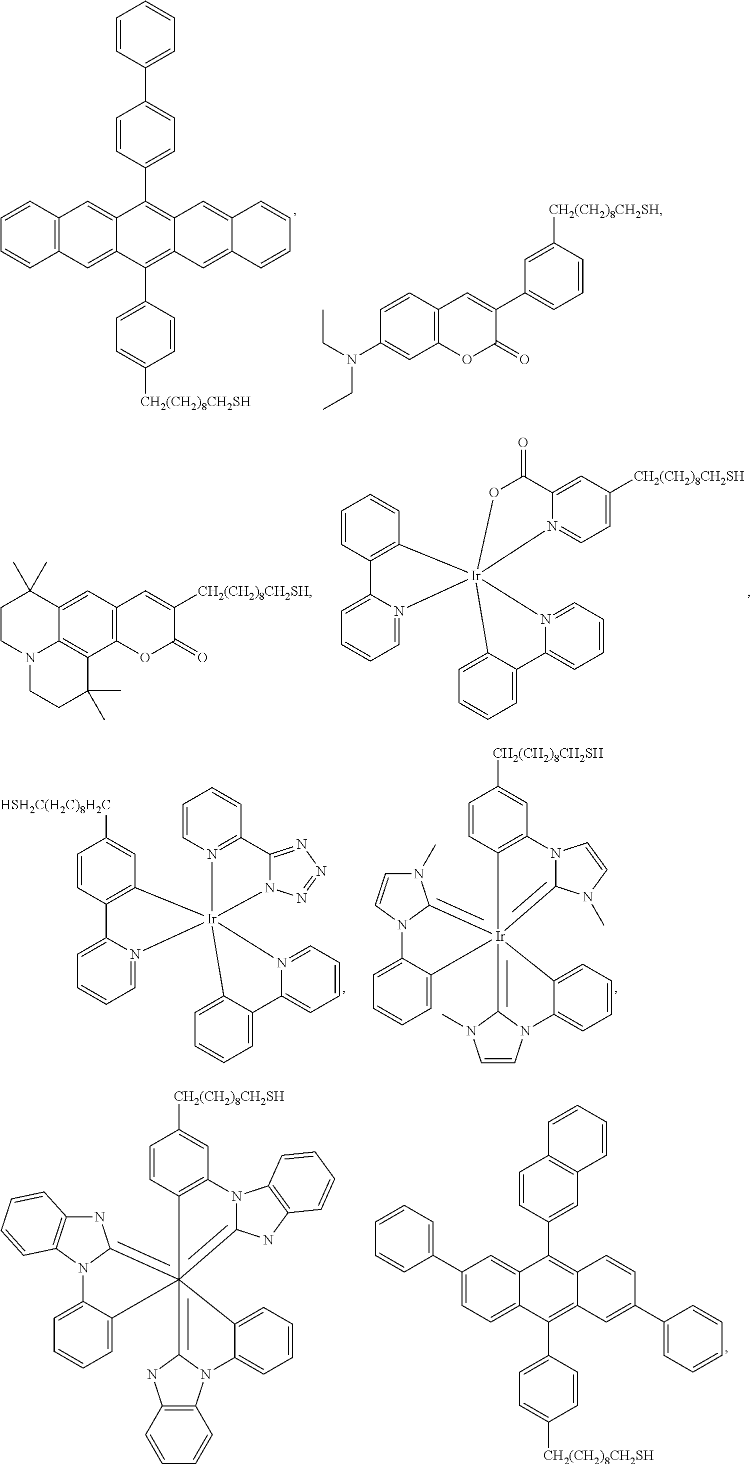

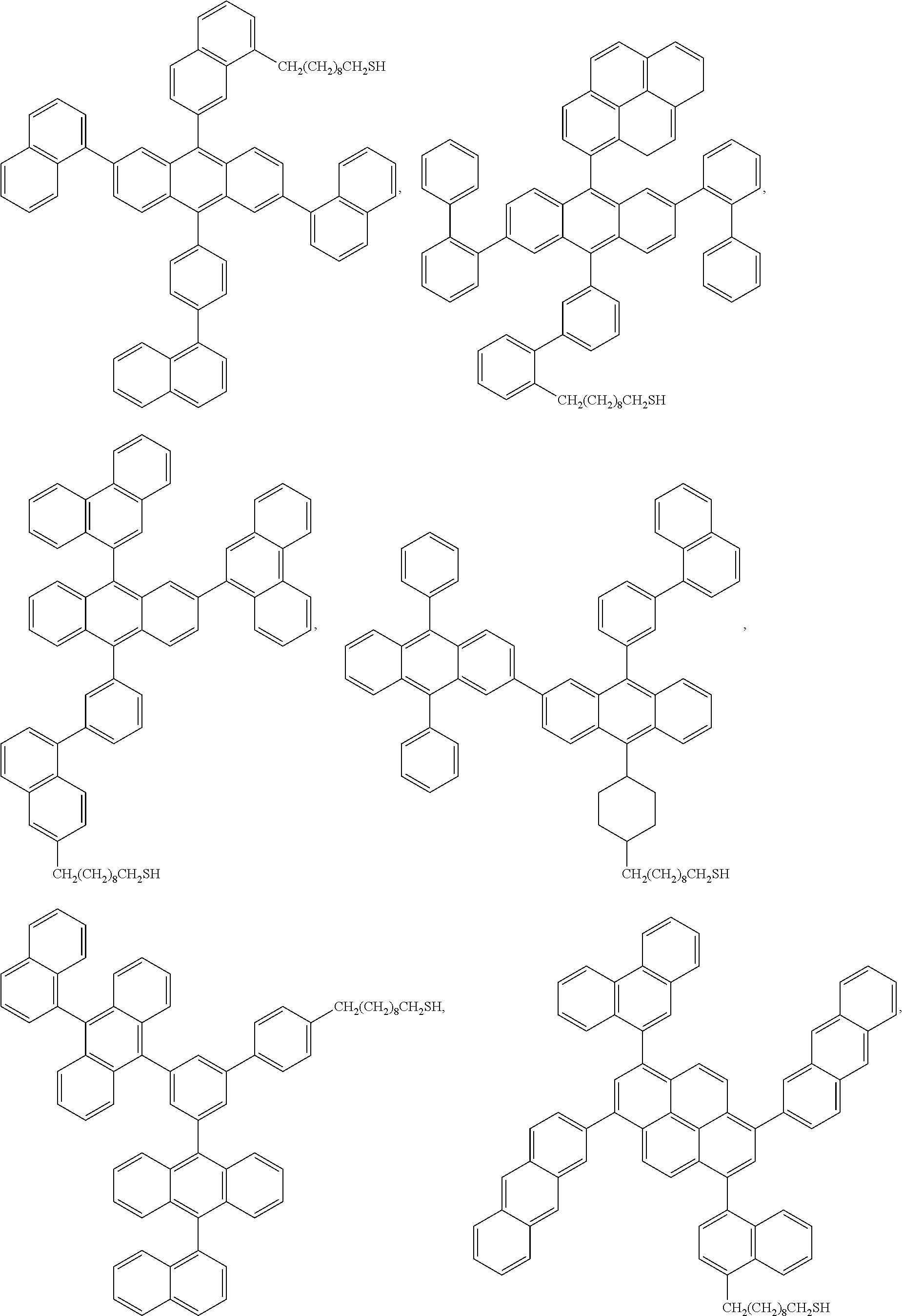

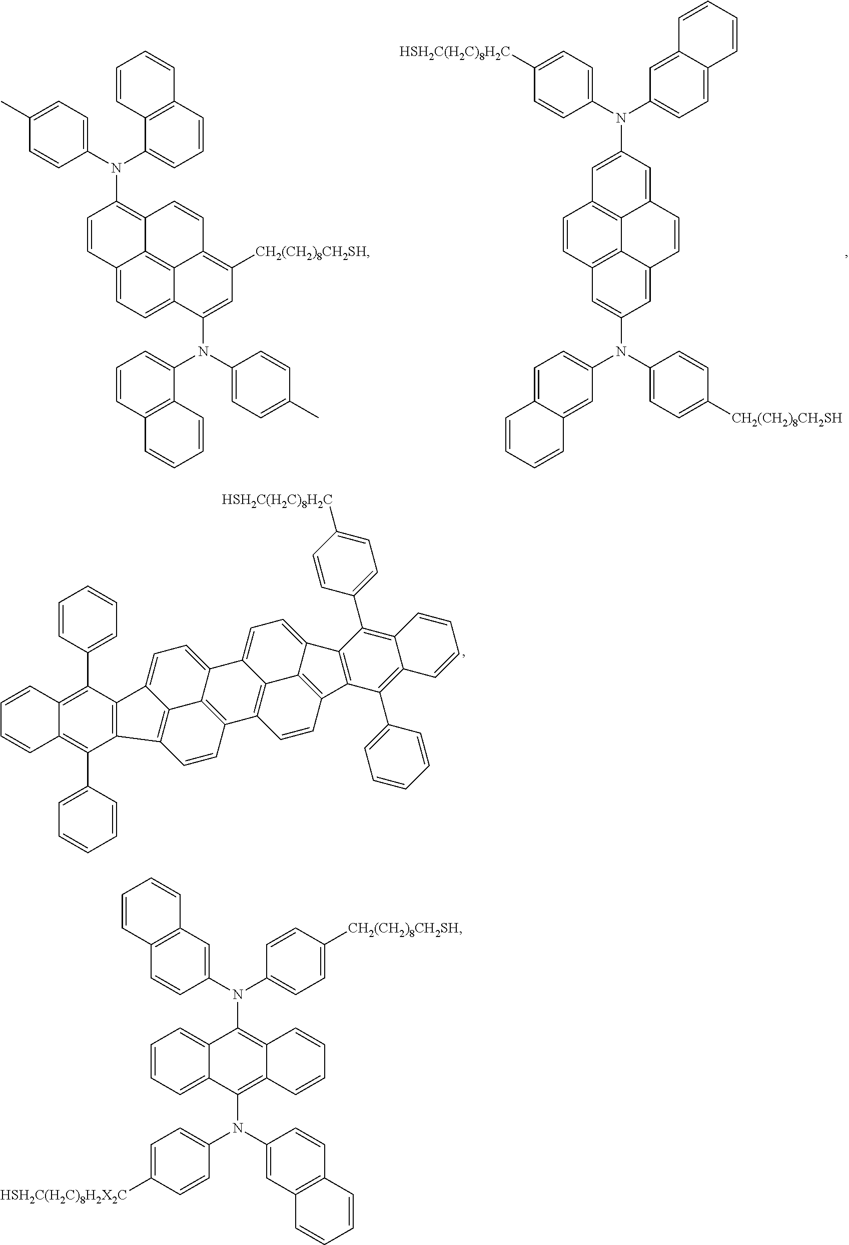

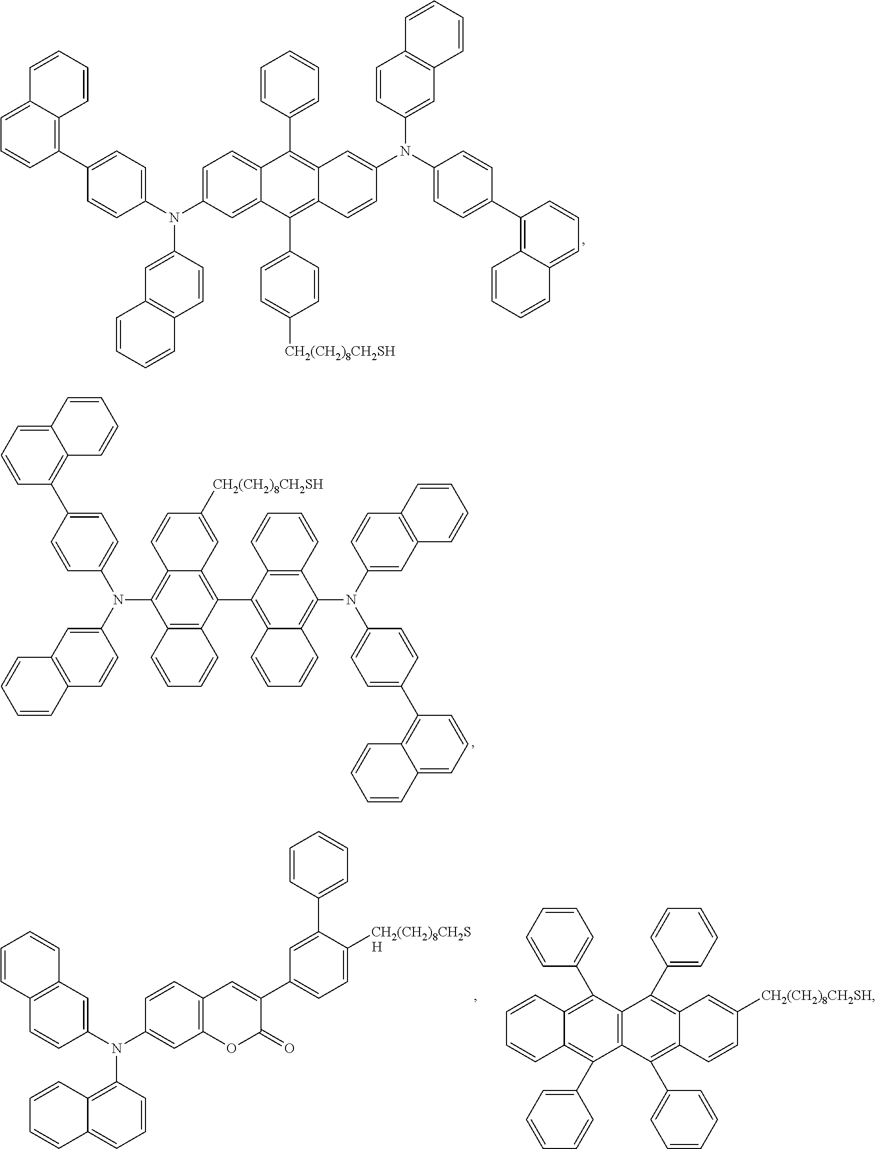

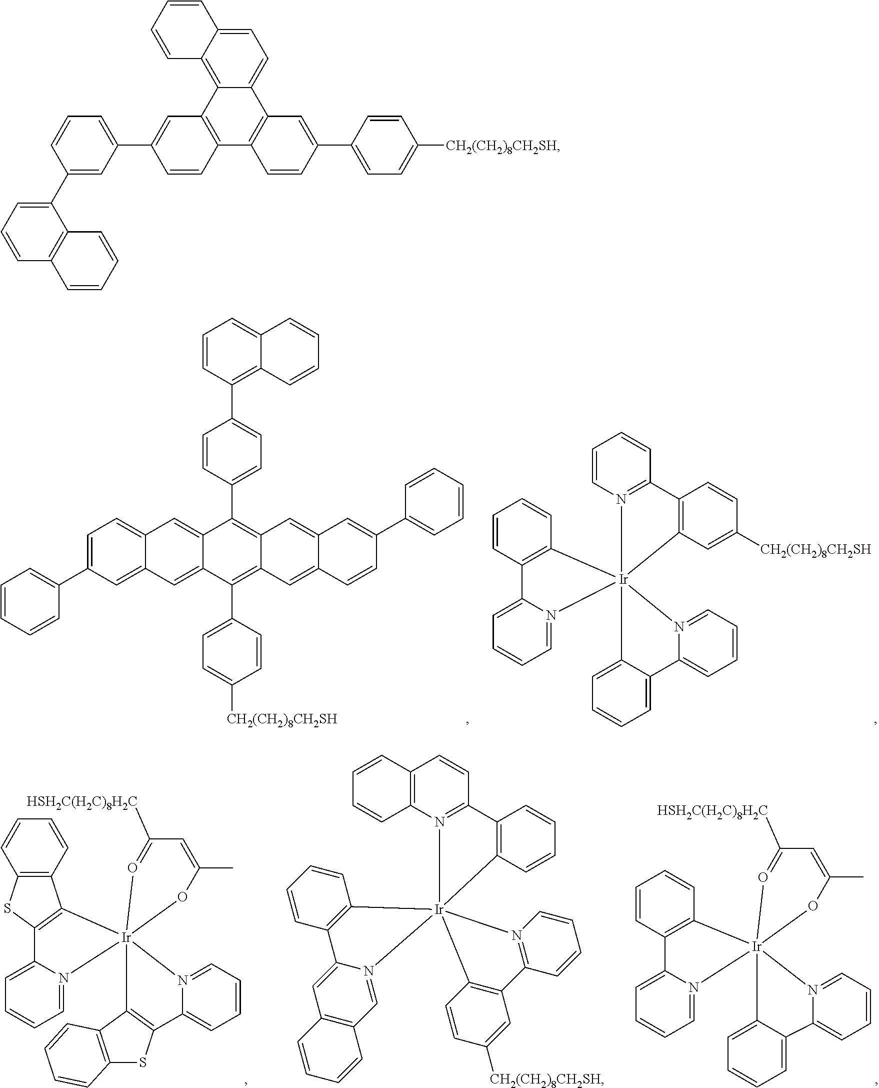

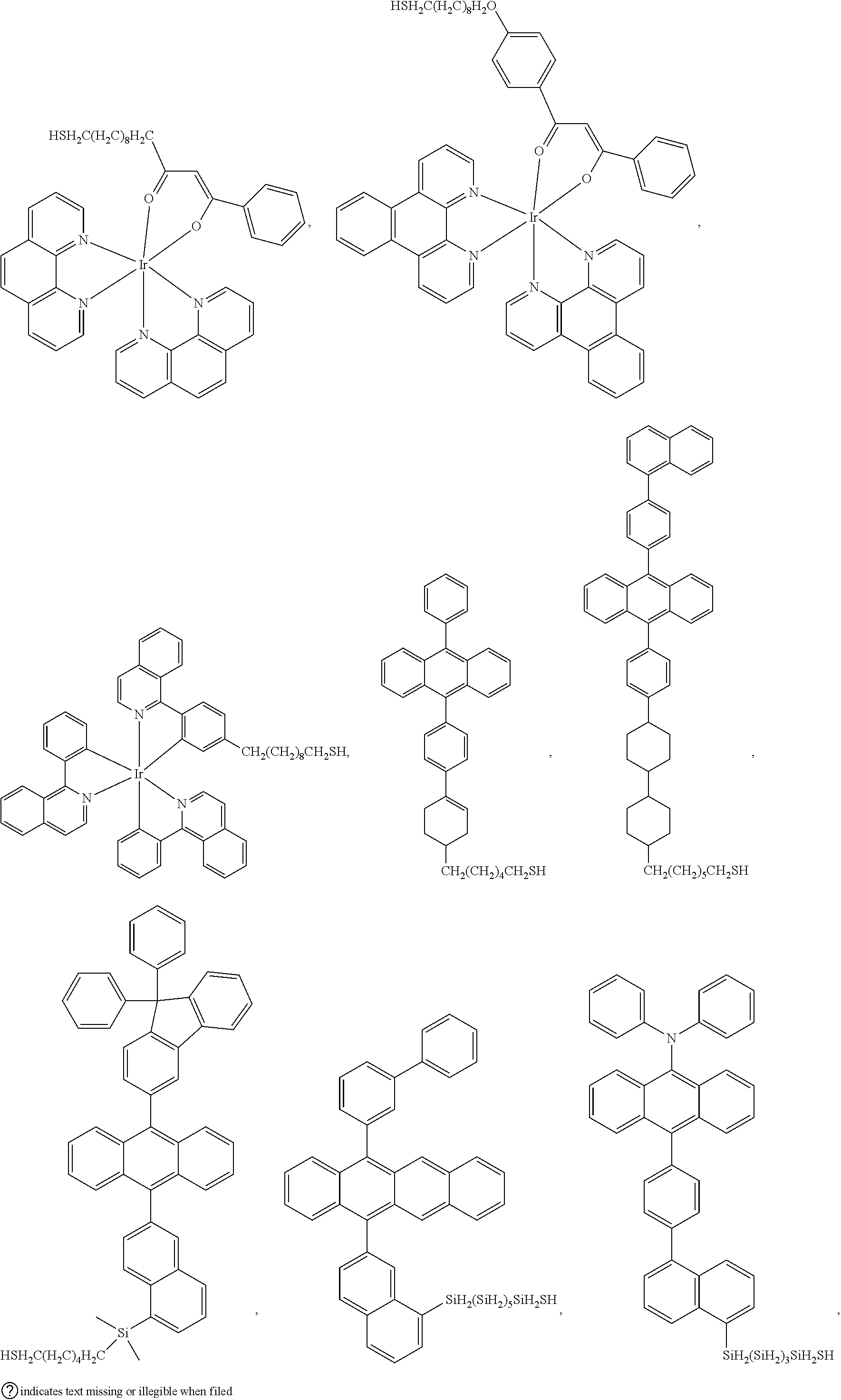

The size of the entire light-emitting quantum dot including the light-emitting group at its end in the present invention may be optionally adjusted and preferably, it may be 5 to 30 nm, more preferably 10-20 nm. Further, the luminescence strength of the core/shell structure and the light-emitting group in the present invention is optionally adjustable and preferably, when the core/shell structure and the light-emitting group in the invention are complementary colors, the difference of the luminescence intensity ratio of the core/shell structure and the light-emitting group may be preferably within 30% as a white light source. For example, when the luminescence intensity in the region of 400 to 500 nm is one, the luminescence intensity in the region of 500 to 800 nm may be preferably 0.7-1.3, and when the luminescence intensity in the region of 500 to 800 nm is one, the luminescence intensity in the region of 400 and 500 nm may be preferably 0.7-1.3.

The following structural formula 2 illustrates a schematic diagram of a light-emitting quantum dot according to a specific embodiment of the present invention, in which the light-emitting material emits light in the region of 400 to 500 nm, and the core/shell structure may be a known quantum dot.

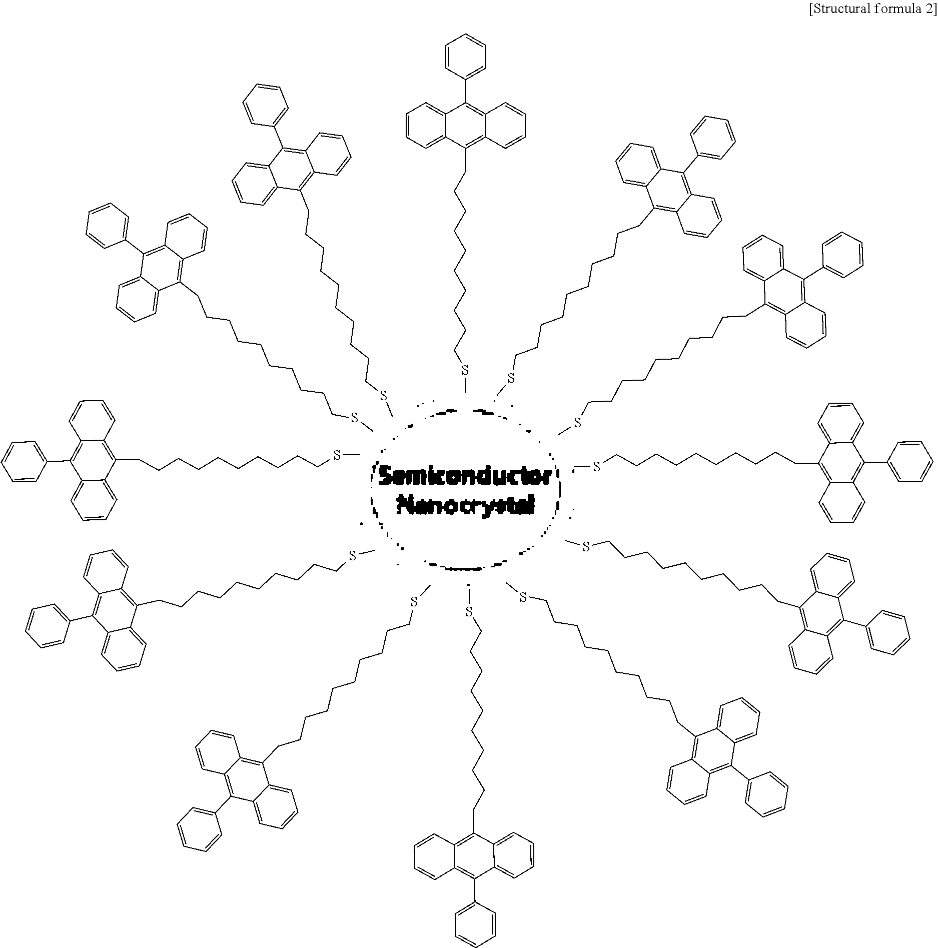

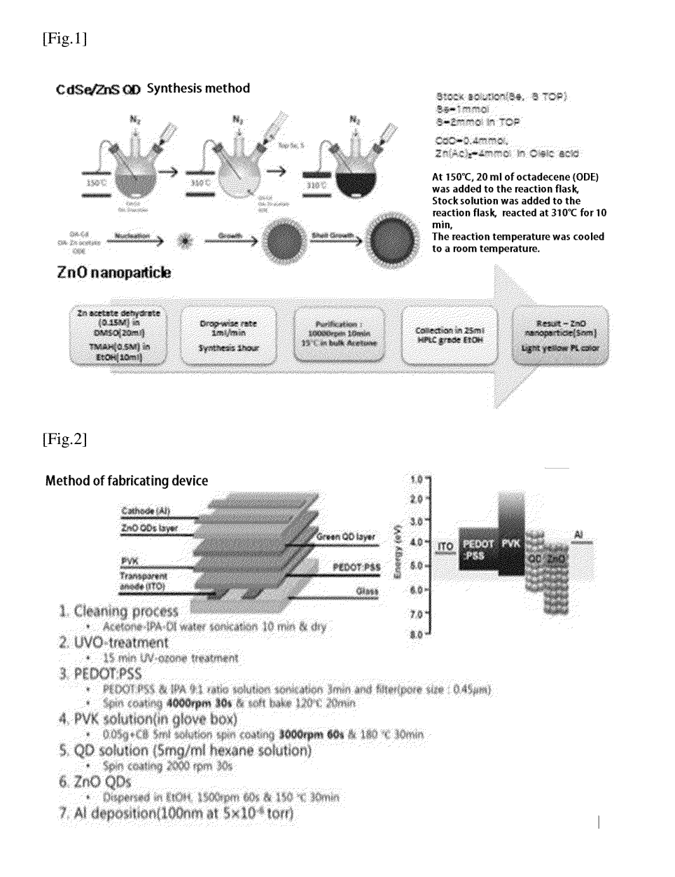

The light-emitting quantum dot according to the present invention may be prepared by a method comprising adding a ligand containing a light-emitting group to a solvent dispersed with a core/shell structure and then stirring it. For the preparation of the core/shell structure in the above, a known method may be used and in particular, the synthesis method described in FIG. 1 may be carried out.

Also, the preparation of the ligand containing the light-emitting group may be carried out by binding a linking group to the light-emitting group, or by including a spacer between the light-emitting group and the linking group via the following reaction formulae 1 and 2.

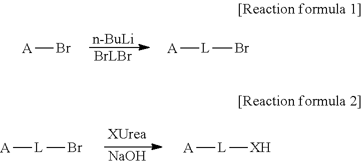

Specifically, the above reaction formula 2 may be reaction formula 3.

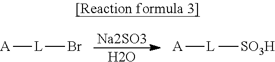

In the above reaction formulae, A, L, and X are as defined in structural formula 1.

Further, in the method of attaching the ligand containing the light-emitting group to the core/shell structure, the stirring process may be performed at a temperature from a room temperature to 100° C. for 0.1 to 100 hours.

In another aspect, the present invention provides a light-emitting device (QLED) and a method for the preparation thereof using the above light-emitting quantum dot. In the light-emitting device in the present invention, other known techniques can be applied except for the light-emitting layer formed using the light-emitting quantum dot according to the invention.

For example, the light-emitting device may be constructed in such a manner that a substrate-cathode-light-emitting layer formed with the light-emitting quantum dot according to the present invention—anode can formed sequentially, and an electron transport layer may be further formed between the cathode and the light-emitting layer, and a hole transport layer may be further formed between the light-emitting layer and the anode. In addition, if necessary, a hole blocking layer may be further included between the electron transport layer and the light-emitting layer, and a buffer layer may be formed between layers.

The light-emitting device (QLED) using the light-emitting quantum dot in the present invention can be formed by a conventional manufacturing method and the thickness of each organic film including the light-emitting layer may be made to be 30 to 100 nm.

In the light-emitting device according to the present invention, the buffer layer may be formed between the layers as stated above, and the buffer layer may be made from conventionally-used materials and for example, it may use copper phthalocyanine, polythiophene, polyaniline, polyacetylene, polypyrrole, polyphenylene vinylene, or derivatives thereof but not be limited thereto.

The hole transport layer may be made from conventionally-used materials and for example, it may use polytriphenylamine but not be limited thereto.

The electron transport layer may be made from conventionally-used materials and for example, it may use polyoxadiazole but not be limited thereto.

The hole blocking layer may be made from conventionally-used materials and for example, it may use LiF, BaF₂ or MgF₂ but not be limited thereto.

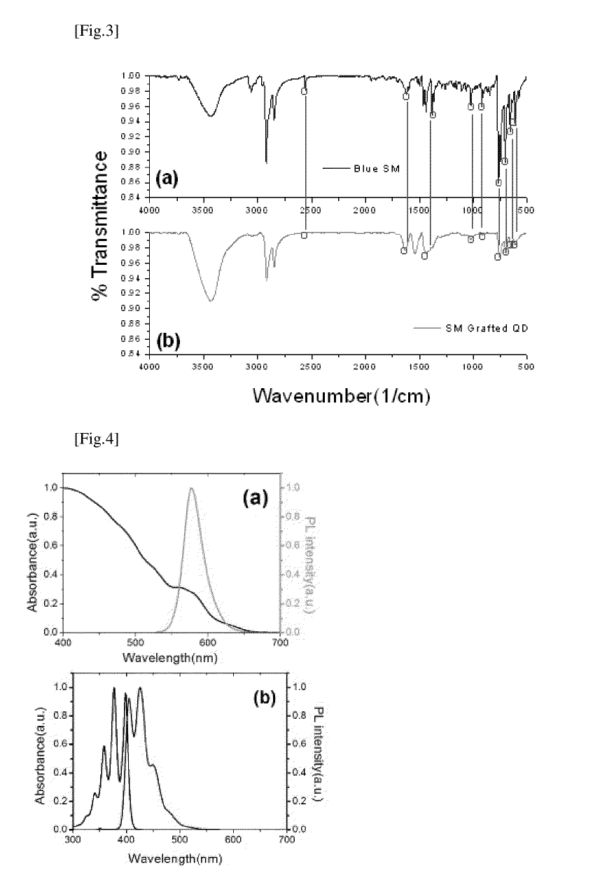

More particularly, the light-emitting device of the present invention may be prepared according to the method depicted in FIG. 2.

The light-emitting device according to the invention prepared as described above is highly stable, and have excellent color purity and high luminous efficiency in comparison with the previous light-emitting devices.

Hereafter, preferred examples will be presented for a better understanding of the present invention. The following examples are merely to illustrate the invention, and the scope of the invention is not limited to the following examples in any ways.

### EXAMPLES

### Synthesis Example 1

### Synthesis of 9-bromo-10-phenylanthracene (synthesis of light-emitting material)

Under an argon or nitrogen atmosphere, 4.2 g of 2-naphthalene boronic acid, 6.8 g of 9-bromoanthracene, 0.6 g of tetrakis(triphenylphosphine) palladium (0), 50 ml of toluene, and 8.4 g of sodium carbonate dissolved in 50 ml of water were added to a 250 ml flask and stirred for 24 hours while heating under reflux. After the reaction, it was cooled to a room temperature, and precipitated crystals were separated by filtration. The products were recrystallized from toluene, to give a crystal of 7.5 g.

Under an argon or nitrogen atmosphere, 7.5 g of the above crystal and 100 ml of dehydrated DMF (dimethylformamide) were added to a 250 ml flask, heated to 80° C. to dissolve the materials, and stirred for 2 hours after the addition of 4.8 g of N-bromo succinic acid imide at 50° C. After the completion of the reaction, the reaction solution was injected to 200 ml of purified water and precipitated crystals were separated by filtration. The products were recrystallized from toluene, to give a crystal of 6.8 g.

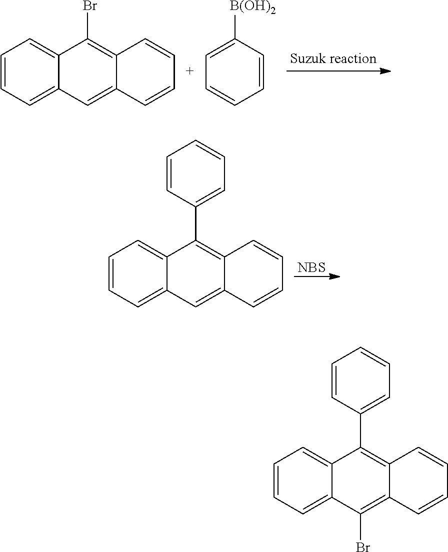

### Synthesis Example 2

### 9-(10-bromodecyl)-10-phenylanthracene (synthesis of spacer)

8 G of 9-bromo-10-phenylanthracene was dissolved in 300 ml of anhydrous diethyl ether. At 0° C., 18 ml of n-BuLi (2 M) was added slowly thereto. After the obtained mixture was kept at 0° C. for 1 hour, 21.6 ml of 1,10-dibromodecene was added thereto. After 30 minutes, the mixture was stirred for 2 hours under reflux. If the reaction was no longer occurring, the mixture was then cooled to a room temperature, followed by the addition of 80 ml of distilled water. The organic layer was collected and the water layer was extracted three times with 40 ml of ethyl ether. After water was eliminated with anhydrous magnesium sulfate, the products were separated by column using hexane as a mobile phase, to give 5.7 g (50%) of green oily phase 9-(10-bromodecyl)-10-phenyl anthracene.

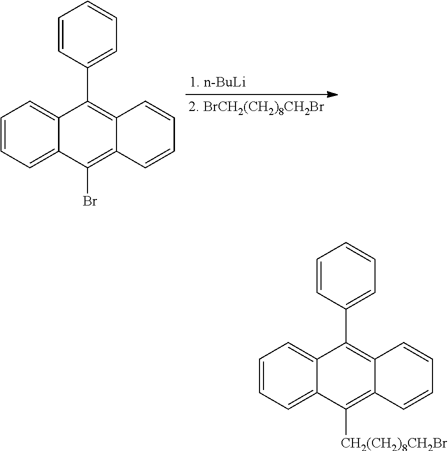

¹H NMR (CDCl₃, 400 MHz): 8.32 (2H, d), 7.63 (2H, d), 7.59 (9H, m), 3.92 (2H, t), 3.65 (2H, t), 1.70-1.68 (2H, m), 1.64-1.60 (4H, m), 1.52 (10H, m)

### Synthesis Example 3

### Synthesis of Compound DJ-A-1

4 G (1 eq) of 9-(10-bromodecyl)-10-phenylanthracene and 1.3 g (2 eq) of thiourea were dissolved in 50 ml of anhydrous ethanol and then stirred under reflux for 4 hours. 50 Ml of 6 M sodium hydroxide was added thereto and then stirred under reflux for 2 hours. If the reaction was no longer occurring, the obtained mixture was extracted three times with 30 ml of ethyl acetate after the elimination of ethanol. After the obtained mixture was washed with a brine solution and water was eliminated with anhydrous magnesium sulfate, the products were separated by column using CHCl₃ as a mobile phase, to give 1.4 g (39%) of green oily phase 10-(10-phenylanthrace-9-yl)-decane-1-thiol.

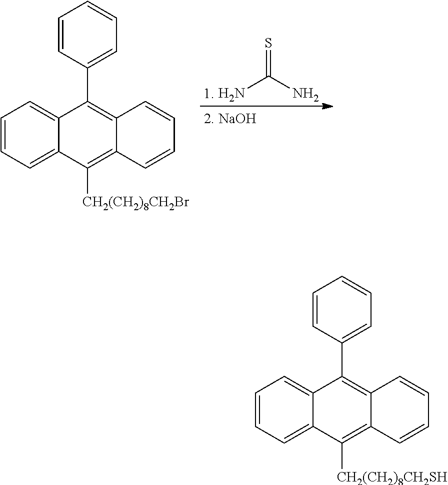

¹H-NMR (CDCl₃, Varian 400 MHz): δ 1.26-1.38 (6H, m), 1.43-1.46 (4H, m), 1.62-1.66 (2H, m), 1.85-1.90 (4H, m), 3.42 (2H, t, J=6.8 Hz), 3.64-3.69 (2H, m), 7.31-7.35 (2H, m), 7.40-7.42 (2H, m), 7.48-7.59 (5H, m), 7.66 (2H, d, J=8.8 Hz), 8.33 (2H, d, J=9.2 Hz).

LC-MS (LC: Agilent 1200, MS: LCQ Advantage Max): Mobile phase from 0% [water+0.01% HFBA+1.0% IPA] and 100% [CH3CN+0.01% HFBA+1.0% IPA] to 0%[water+0.01% HFBA+1.0% IPA] and 100% [CH3 CN+0.01% HFBA+1.0% IPA] in 6.0 min). Purity is 99.72%, Rt=2.48 min; MS Calcd.: 426.24; MS Found 426.2[M].

### Synthesis Example 4

### Synthesis of Compound DJ-A-2

The process of the above synthesis examples 1 through 3 was repeated, except that 1.5-dibrompentane was used instead of 1,10-dibromodecene in synthesis example 2, to synthesize a pale yellow DJ-A-2.

¹H-NMR (CDCl₃, Varian 400 MHz): δ 1.45 (1H, t, J=7.6 Hz), 1.74-1.81 (4H, m), 1.87-1.92 (2H, m), 2.60 (2H, q, J=7.6 Hz), 3.66-3.70 (2H, m), 7.32-7.35 (2H, m), 7.40-7.42 (2H, m), 7.48-7.54 (3H, m), 7.55-7.59 (2H, m), 7.66 (2H, d, J=8.4 Hz), 8.31 (2H, d, J=8.8 Hz).

LC-MS (LC: Agilent 1200, MS: LCQ Advantage Max): Mobile phase from 10% [water+0.01% HFBA+1.0% IPA] and 90% [CH3CN+0.01% HFBA+1.0% IPA] to 5%[water+0.01% HFBA+1.0% IPA] and 95% [CH3CN+0.01% HFBA+1.0% IPA] in 6.0 min). Purity is 99.52%, Rt=2.61 min; MS Calcd.: 356.16; MS Found 356.2[M].

The entire reaction schemes of the above synthesis examples 3 and 4 are as follows.

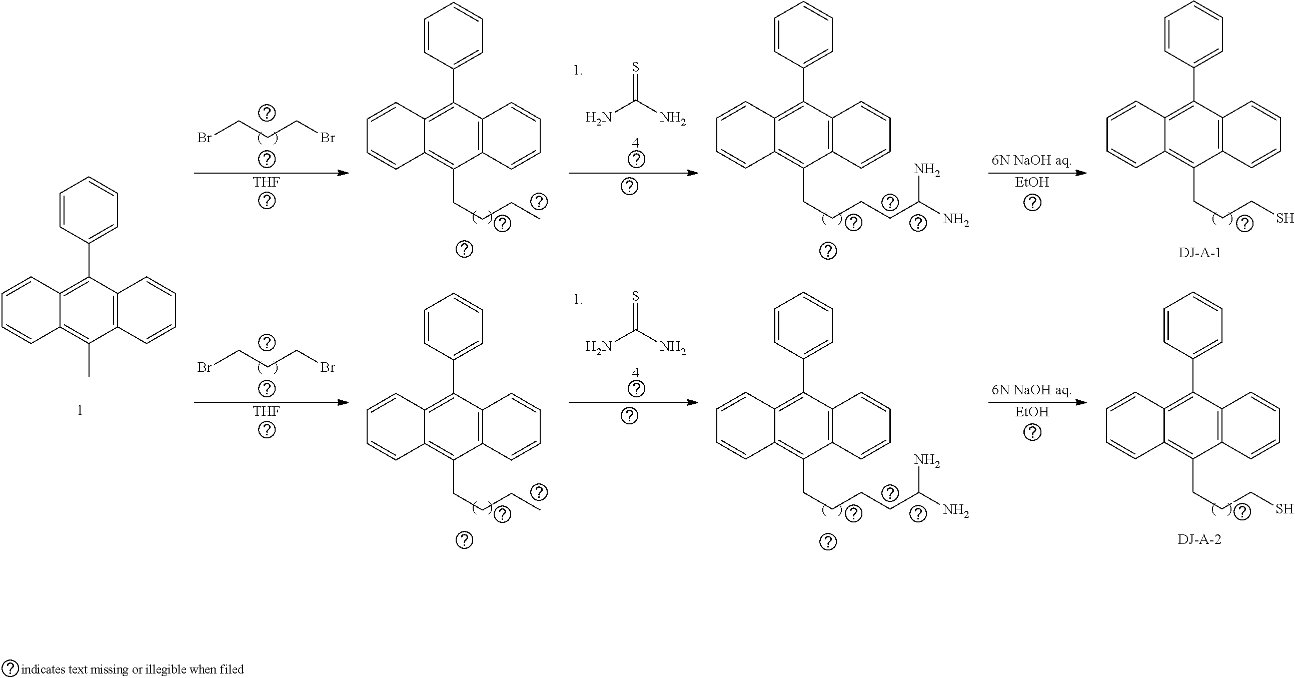

### Synthesis Example 5

### Synthesis of Compound DJ-A-3

The process of the above synthesis examples 1 through 3 was repeated, except that 9-(4-bromopheneyl)-10-phenylanthracene was used instead of 9-bromo-10-phenyl anthracene in synthesis example 1, to synthesize a white solid DJ-A-3.

¹H-NMR (CDCl₃, Varian 400 MHz): δ 1.32-1.45 (12H, m), 1.60-1.63 (2H, m), 1.75-1.78 (2H, m), 2.52 (2H, q, J=7.6 Hz), 2.75-2.79 (2H, m), 7.30-7.32 (4H, m), 7.35-7.41 (4H, m), 7.46-7.48 (2H, m), 7.53-7.61 (3H, m), 7.66-7.73 (4H, m).

LC-MS (LC: Agilent 1200, MS: LCQ Advantage Max): Mobile phase from 0% [water+0.01% HFBA+1.0% IPA] and 100% [CH3CN+0.01% HFBA+1.0% IPA] to 0%[water+0.01% HFBA+1.0% IPA] and 100% [CH3CN+0.01% HFBA+1.0% IPA] in 10 min) Purity is 99.62%, Rt=3.94 min; MS Calcd.: 502.27; MS Found 502.2[M].

### Synthesis Example 6

### Synthesis of Compound DJ-A-4

1,5-Dibromopentane was used instead of 1,10-dibromodecene in the above synthesis example 5 to synthesize a pale yellow solid DJ-A-4.

¹H-NMR (CDCl₃, Varian 400 MHz): δ 1.39 (1H, t, J=7.6 Hz), 1.54-1.60 (2H, m), 1.73-1.82 (2H, m), 2.61 (2H, q, J=7.6 Hz), 2.79-2.82 (2H, m), 7.31-7.33 (4H, m), 7.39-7.40 (4H, m), 7.47-7.49 (2H, m), 7.54-7.60 (3H, m), 7.67-7.73 (4H, m).

LC-MS (LC: Agilent 1200, MS: LCQ Advantage Max): Mobile phase from 5% [water+0.01% HFBA+1.0% IPA] and 95% [CH3CN+0.01% HFBA+1.0% IPA] to 0%[water+0.01% HFBA+1.0% IPA] and 100% [CH3 CN+0.01% HFBA+1.0% IPA] in 6.0 min). Purity is 99.58%, Rt=2.85 min; MS Calcd.: 432.19; MS Found 432.2[M].

The entire reaction schemes of the above synthesis examples 5 and 6 are as follows.

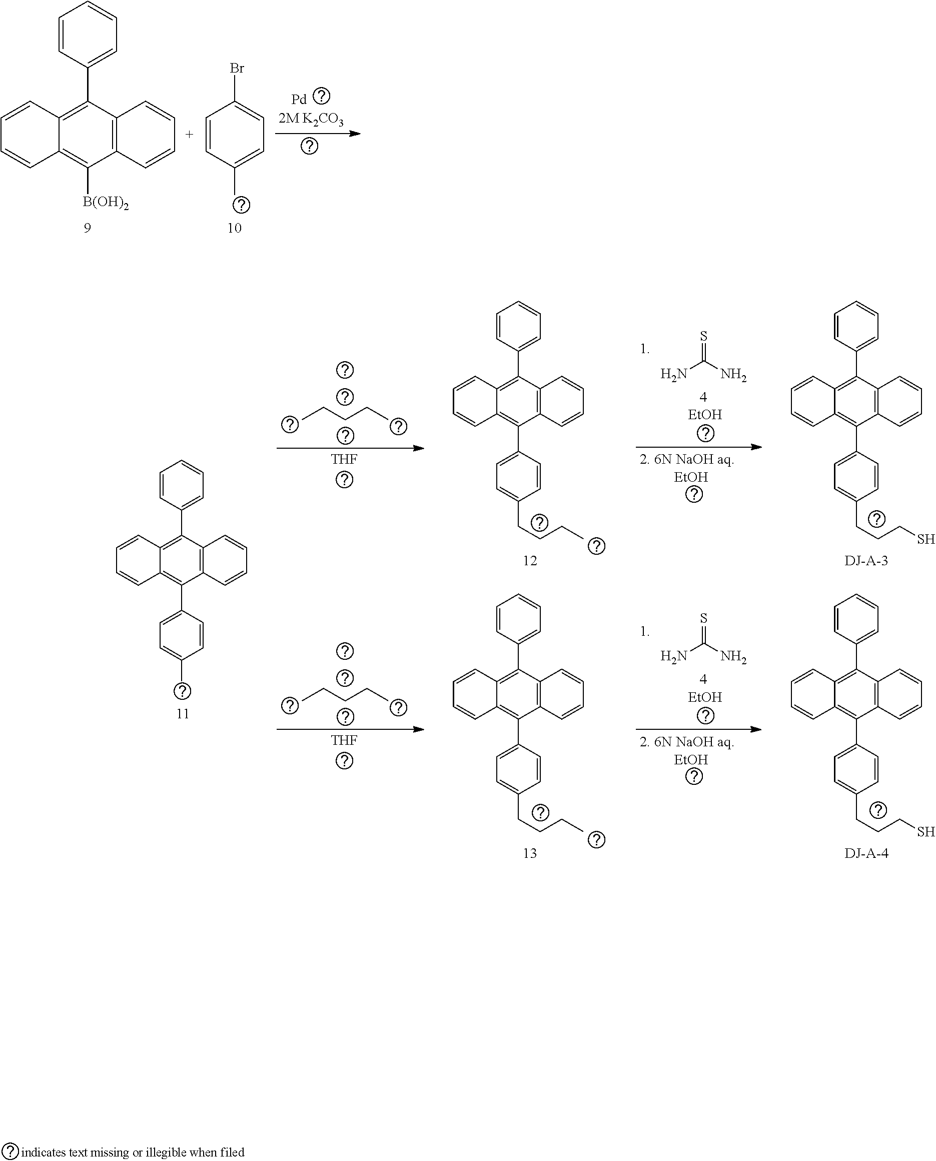

### Synthesis Example 7

### Synthesis of Compound DJ-A-5

The process of the above synthesis examples 1 through 3 was repeated, except that 9-bromo-10-(2-napthyl)anthracene was used instead of 9-bromo-10-phenyl anthracene in synthesis example 1, to synthesize a yellow solid DJ-A-5.

¹H-NMR (CDCl₃, Varian 400 MHz): δ 1.32-1.42 (12H, m), 1.59-1.65 (2H, m), 1.75-1.81 (2H, m), 2.54 (2H, q, J=7.6 Hz), 2.79 (2H, t, J=7.6 Hz), 7.28-7.35 (4H, m), 7.39-7.43 (4H, m), 7.57-7.62 (3H, m), 7.69-7.76 (4H, m), 7.90-7.93 (1H, m), 7.98 (1H, s), 8.01-8.04 (1H, m), 8.07 (1H, d, J=8.4 Hz).

LC-MS (LC: Agilent 1200, MS: LCQ Advantage Max): Mobile phase from 0% [water+0.01% HFBA+1.0% IPA] and 100% [CH3CN+0.01% HFBA+1.0% IPA] to 0% [water+0.01% HFBA+1.0% IPA] and 100% [CH3 CN+0.01% HFBA+1.0% IPA] in 10 min) Purity is 99.84%, Rt=4.95 min; MS Calcd.: 552.29; MS Found 552.2[M].

The entire reaction scheme of synthesis example 7 is as follows.

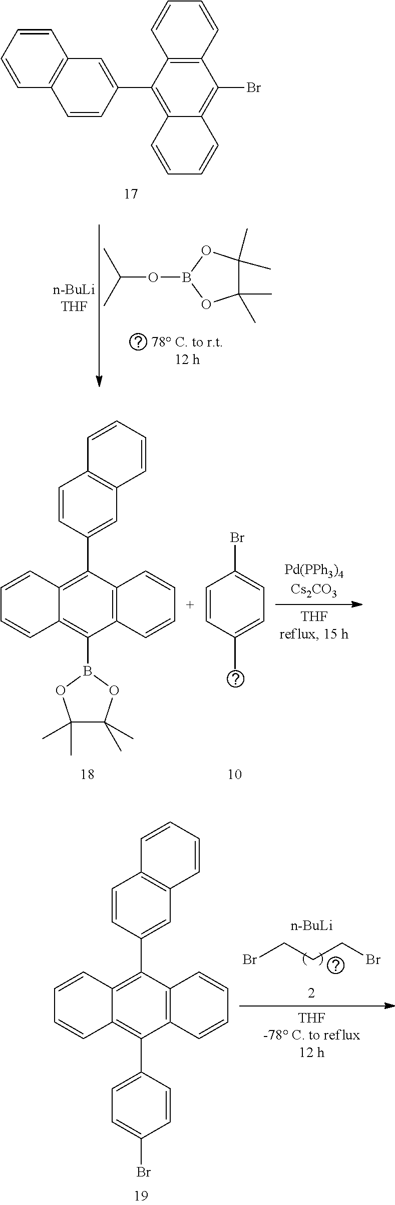

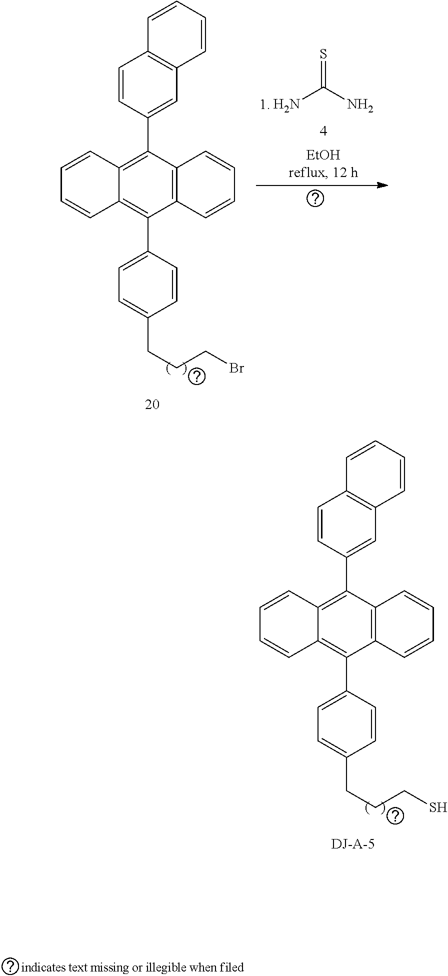

### Synthesis Example 8

### Synthesis of Compound DJ-A-6

The process of the above synthesis example 7 was repeated, except 1,5-dibromopentane was used instead of 1,10-dibromodecene in synthesis example 2, to synthesize a yellow solid DJ-A-6.

¹H-NMR (CDCl₃, Varian 400 MHz): δ 1.39 (1H, t, J=7.2 Hz), 1.62-1.54 (2H, m), 1.85-1.71 (4H, m), 2.61 (2H, q, J=7.2 Hz), 2.83-2.79 (2H, m), 7.36-7.28 (4H, m), 7.42 (4H, s), 7.63-7.59 (3H, m), 7.76-7.70 (4H, m), 7.93-7.91 (1H, m), 7.98 (1H, s), 8.04-8.02 (1H, m), 8.07 (1H, d, J=8.4 Hz).

LC-MS (LC: Agilent 1200, MS: LCQ Advantage Max): Mobile phase from 0% [water+0.01% HFBA+1.0% IPA] and 100% [CH3CN+0.01% HFBA+1.0% IPA] to 0%[water+0.01% HFBA+1.0% IPA] and 100% [CH3 CN+0.01% HFBA+1.0% IPA] in 6.0 min). Purity is 99.76%, Rt=2.23 min; MS Calcd.: 482.21; MS Found 482.2[M].

The entire reaction scheme of synthesis example 8 is as follows.

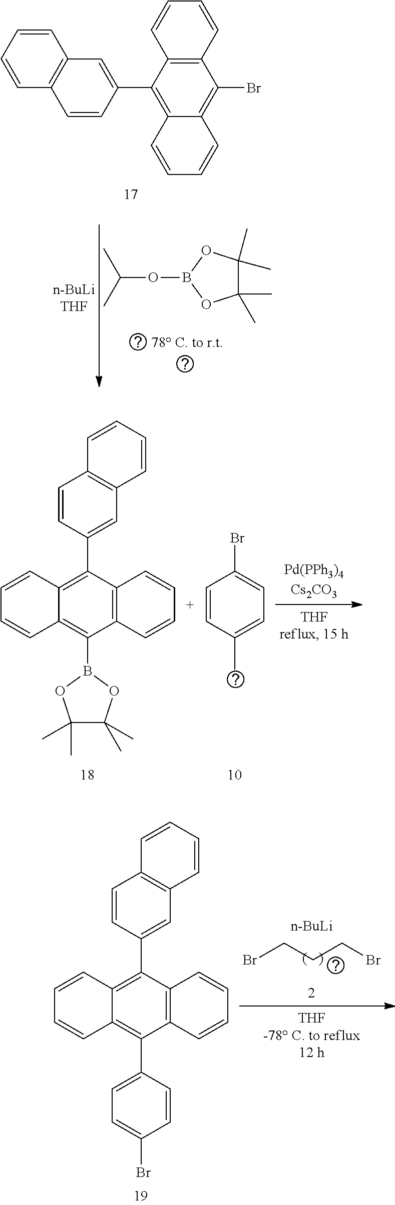

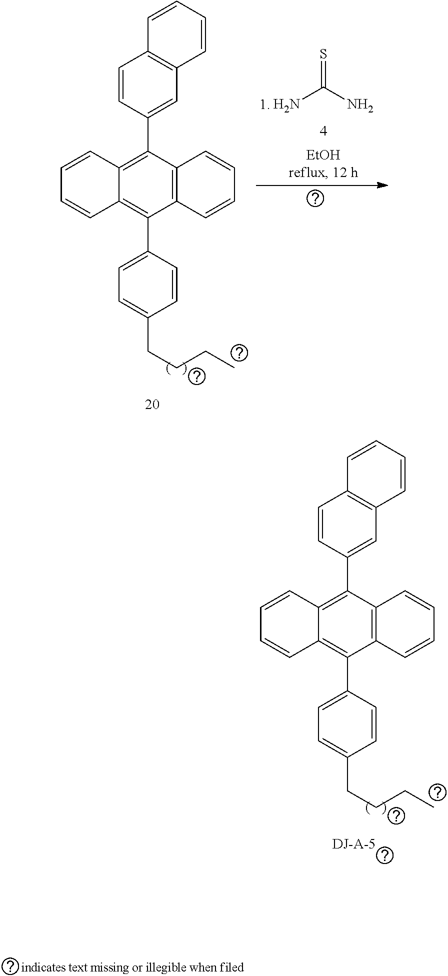

### Synthesis Example 9

### Synthesis of 9-(10-bromo-9-anthracyl)-N³,N³,N⁶,N⁶-tetraphenyl-9H-carbazole-3,6-diamine (synthesis of light-emitting material)

Under an argon or nitrogen atmosphere, 32.5 g of 2,7-dibromo-9H-carbazole, 37.2 g of diphenyl amine, 4.6 g of tris(dibenzylideneacetone) palladium (0), 300 ml of toluene, and 100 g of sodium tetrabutoxide were added to a 1000 ml flask, which was then stirred for 24 hours while heating under reflux. After the reaction, it was cooled to a room temperature, and precipitated crystals were separated by filtration. This was recrystallized from toluene, to give a crystal of 40 g.

Under an argon or nitrogen atmosphere, 40 g of the above crystal, 38 g of 9-bromoanthracene, 2.2 g of tris(dibenzylideneacetone) palladium (0), 400 ml of toluene and 60 g of sodium tetrabutoxide were added to a 1000 ml flask, which was then stirred for 24 hours while heating under reflux. After the reaction, it was cooled to a room temperature, and precipitated crystals were separated by filtration. The obtained products were recrystallized from toluene, to give a crystal of 45 g.

Under an argon or nitrogen atmosphere, 45 g of the above crystal and 500 ml of dehydrated DMF (dimethylformamide) were added to a 1000 ml flask, which was then heated to 80° C. to dissolve the materials, and after the addition of 15 g of N-bromosuccinic acid imide at 50° C., the mixture was stirred for two hours. After the completion of the reaction, the reaction solution was added to 200 ml of purified water, and precipitated crystals were separated by filtration. The obtained products were recrystallized from toluene, to give a crystal of 42 g.

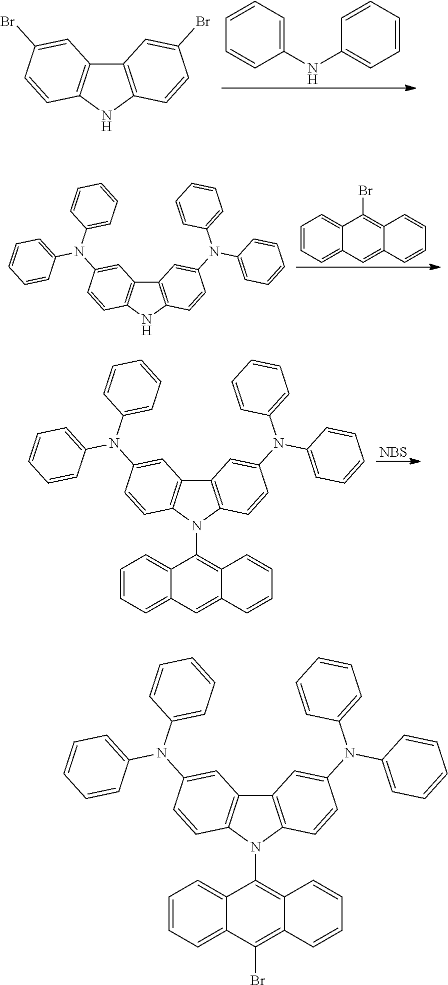

### Synthesis Example 10

### 9-(10-bromodecyl-9-anthracyl)-N³,N³,N⁶,N⁶-tetraphenyl-9H-carbazole-3,6-diamine (Synthesis of spacer)

9.5 G of 9-(10-bromo-9-anthracyl)-N³,N³,N⁶,N⁶-tetraphenyl-9H-carbazole-3,6-diamine was dissolved in 300 ml of anhydrous diethyl ether. At 0° C., 17.5 ml of n-BuLi (2 M) was added slowly thereto. After the obtained mixture was kept at 0° C. for 1 hour, 22.4 ml of 1,10-dibromodecene was added thereto. After 30 minutes, the mixture was stirred for 2 hours under reflux. If the reaction was no longer occurring, the mixture was then cooled to a room temperature, followed by the addition of 80 ml of distilled water. The organic layer was collected and the water layer was extracted three times with 40 ml of ethyl ether. After water was eliminated with anhydrous magnesium sulfate, the products were separated by column using hexane as a mobile phase, to give 6.3 g (49%) of green oily phase

### 9-(10-bromodecyl-9-anthracyl)-N³,N³,N⁶,N⁶-tetraphenyl-9H-carbazole-3,6-diamine

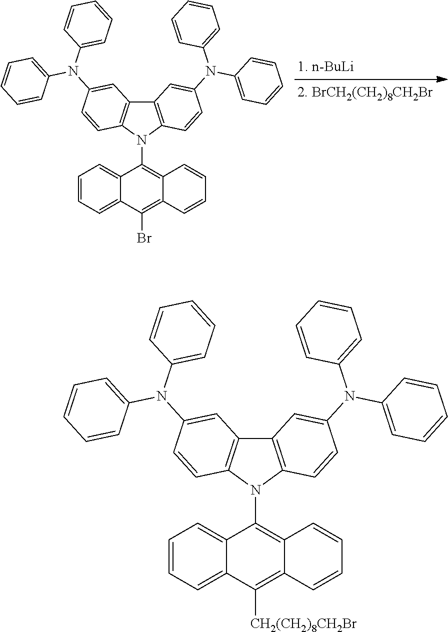

¹H NMR (CDCl₃, 400 MHz): 8.32 (2H, d), 8.17 (2H, s), 7.89 (4H, m), 7.63 (2H, d), 7.59 (14H, m), 3.92 (2H, t), 3.65 (2H, t), 1.70-1.68 (2H, m), 1.64-1.60 (4H, m), 1.52 (10H, m)

### Synthesis Example 11

### Synthesis of Compound DJ-A-7

4.1 G (1 eq) of 9-(10-bromodecyl-9-anthracyl)-N³,N³,N⁶,N⁶-tetraphenyl-9H-carbazole-3,6-diamine and 1.2 g (2 eq) of thiourea were dissolved in 50 ml of anhydrous ethanol and then stirred for four hours under reflux. 50 Ml of 6 M sodium hydroxide was added thereto and then stirred for two hours under reflux. If the reaction was no longer occurring, the obtained mixture was extracted three times with 30 ml of ethyl acetate after the elimination of ethanol. After the obtained mixture was washed with a brine solution and water was eliminated with anhydrous magnesium sulfate, the products were separated by column using CHCl₃ as a mobile phase, to give 1.4 g (36%) of green oily phase 10-(10-phenylanthrace-9-yl)-decane-1-thiol.

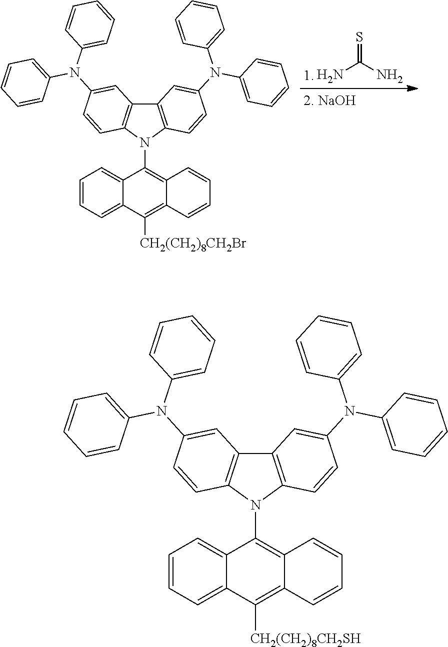

¹H NMR (CDCl₃, 400 MHz): 8.32 (2H, d), 8.17 (2H, s), 7.89 (4H, m), 7.63 (2H, d), 7.59 (14H, m), 3.92 (2H, t), 3.65 (2H, t), 1.70-1.68 (2H, m), 1.63-1.60 (4H, m), 1.51 (10H, m)

### Synthesis Example 12

### Synthesis of Compound DJ-A-8

The process of the above synthesis examples 9 through 11 was repeated, except that 1,5-dibromopentene was used instead of 1,10-dibromodecene in synthesis example 2, to synthesize a pale yellow DJ-A-8.

¹H NMR (CDCl₃, 400 MHz): 8.31 (2H, d), 8.18 (2H, s), 7.98 (4H, m), 7.73 (2H, d), 7.59 (14H, m), 3.94 (2H, t), 3.65 (2H, t), 1.70-1.68 (2H, m), 1.63-1.60 (4H, m), 1.51 (5H, m)

The entire synthesis schemes of the above synthesis examples 10 and 12 are as follows.

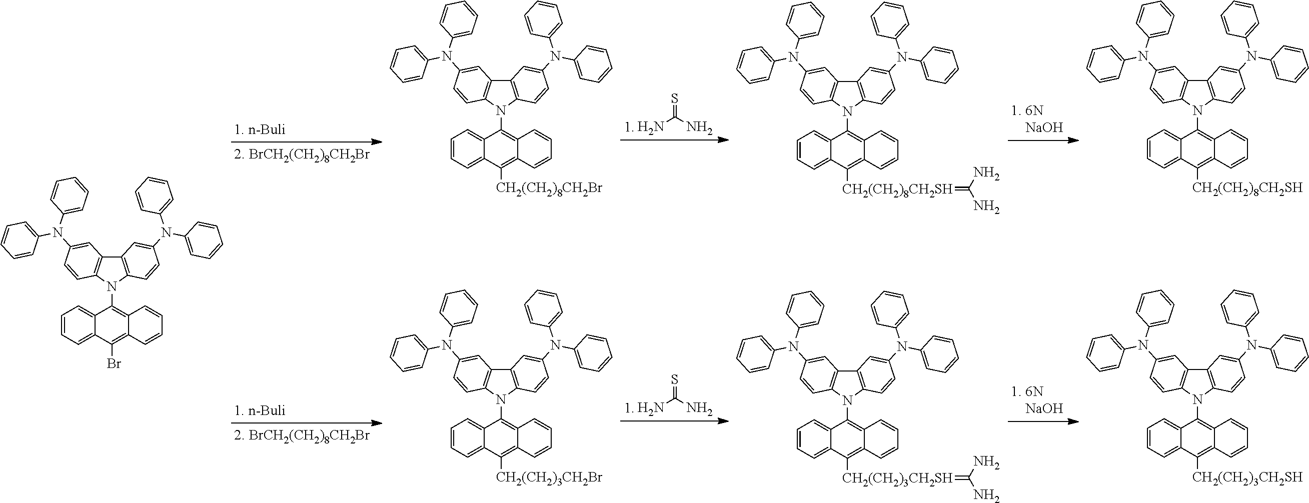

### Synthesis 13

### Synthesis of Compound DJ-A-9

The process of the above synthesis examples 9 through 11 was repeated, except that 9-(10-(4-bromophenyl)-9-anthracyl)-N³,N³,N⁶,N⁶-tetraphenyl-9H-carbazole-3,6-diamine was used instead of 9-(10-bromo-9-anthracyl)-N³,N³,N⁶,N⁶-tetraphenyl-9H-carbazole-3,6-diamine in synthesis example 11, to synthesize a white solid DJ-A-9.

¹H NMR (CDCl₃, 400 MHz): 8.32 (2H, d), 8.17 (2H, s), 7.89 (8H, m), 7.63 (2H, d), 7.59 (14H, m), 3.92 (2H, t), 3.65 (2H, t), 1.70-1.68 (2H, m), 1.63-1.60 (4H, m), 1.51 (10H, m)

### Synthesis Example 14

### Synthesis of DJ-A-10

1,5-Dibromopentane was used instead of 1,10-dibromodecene in the above synthesis example 13, to synthesize a pale yellow solid DJ-A-10.

¹H NMR (CDCl₃, 400 MHz): 8.42 (2H, d), 8.24 (2H, s), 7.79 (8H, m), 7.68 (2H, d), 7.57 (14H, m), 3.92 (2H, t), 3.63 (2H, t), 1.74-1.68 (2H, m), 1.63-1.60 (4H, m), 1.49 (10H, m)

The entire reaction schemes of the above synthesis examples 13 and 14 are as follows.

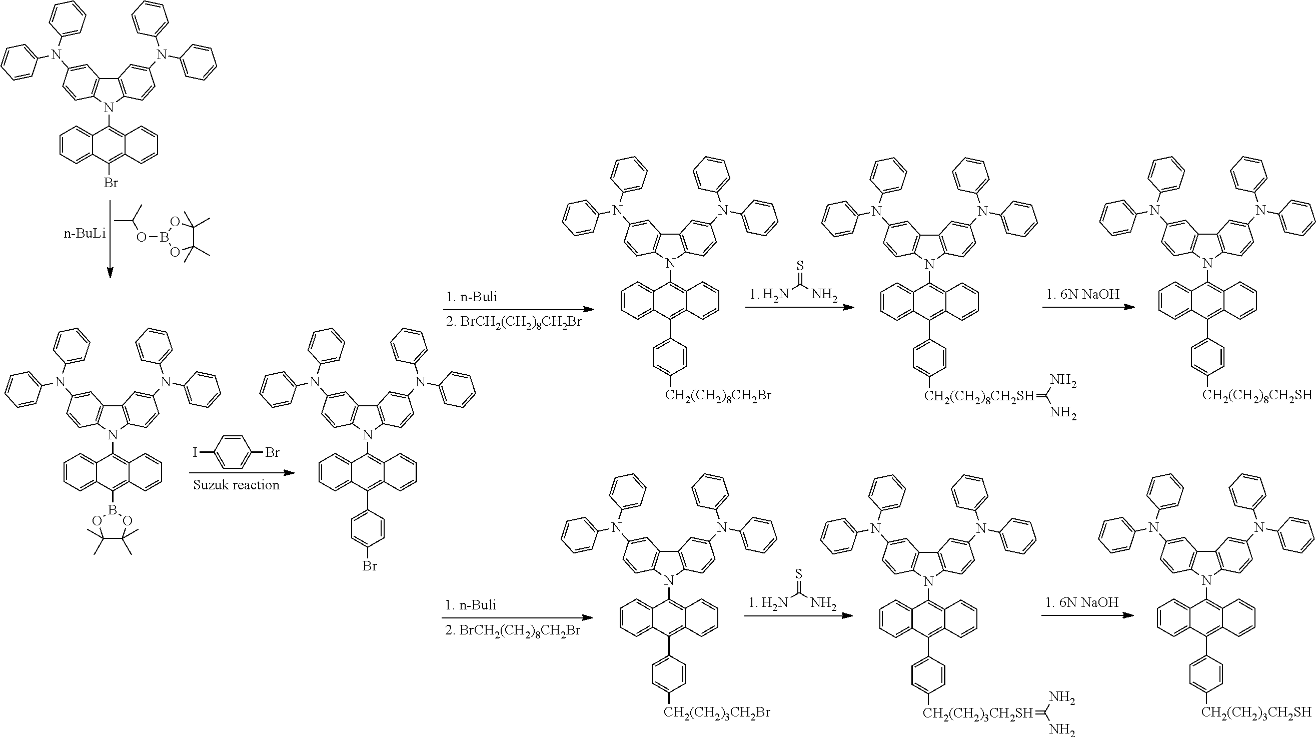

### Synthesis Example 15

### Synthesis of CdSe/ZnS

0.4 Mmol of cadmium oxide CDO (99.99%), 4 mmol of zinc acetate (99.9%, powder), and 5.58 mL of oleic acid (OA) were added to a 100 mL three-necked flask, which was then heated to 150° C. for 30 minutes under a nitrogen atmosphere. Next, 20 ml of octadecene (ODE) was added thereto and then temperature was increased to 310° C. 3 Ml of trioctylphosphine (TOP), 1 mmol of selenium (SE), and 2.3 mmol of sulfur (S) were quickly injected into the flask. The reaction temperature was kept at 310° C. for 10 min and cooled to a room temperature. The resulting quantum dots were purified with 20 mL of chloroform and excessive acetone (3 times or more). The quantum dots were redispersed at a concentration of 5.0 mg/mL in chloroform or hexane.

### Synthesis Example 16

### Synthesis of ZnO Nanoparticles

ZnO nanoparticles are used as an electron transport layer, and a general method for synthesizing the ZnO nanoparticles is as follows Zinc acetate was added to 30 ml of dimethyl sulfoxide (DMSO, 0.5 M), which was then added to a tetramethyl ammonium hydroxide (TMAH) (0.55 M) mixture in an ethanol and stirred for one hour. After centrifugation, it was washed with a mixture of ethanol and excessive acetone. The synthesized ZnO nanoparticles were dispersed at a concentration of 30 mg/mL in an ethanol and used as an electron transport layer material for LED manufacturing devices.

### Example 1

### Synthesis of White Quantum Dots (Ligand Exchange)

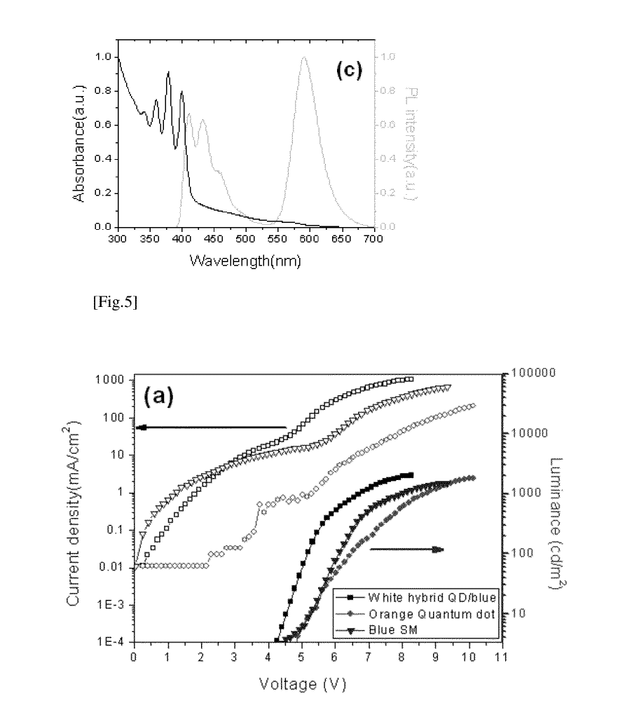

CdSe/ZnS solution (0.2 ml, 5 mg/ml in hexane) was prepared with the quantum dot prepared in the above synthesis example 15, and the light-emitting material (0.5 ml, 3 mM in hexane) prepared in the synthesis example 3 was added thereto and then stirred at a room temperature for 30 minutes. Methanol was added to the reaction flask to solidify the reactant, which was then centrifuged to prepare white quantum dots. Ligand exchange results were confirmed by IR DATA and their UV absorption and PL spectra (FIG. 3 FT-IR spectra (a) DJ-A-1, (b) DJ-A-1+CdSe/ZnS) were also confirmed.

### Example 2

### Synthesis of High Color Purity White Quantum Dots (Ligand Exchange)

CdSe/ZnS solution (0.2 ml, 5 mg/ml in hexane) was prepared with the quantum dot prepared in the above synthesis example 15, and the light-emitting material (0.5 ml, 3 mM in hexane) prepared in the synthesis example 3 and the light-emitting material (0.5 ml, 3 mM in hexane) prepared in the synthesis example 11 were added thereto and then stirred at a room temperature for 30 minutes. Methanol was added to the reaction flask to solidify the reactant, which was then centrifuged to prepare white quantum dots. Ligand exchange results were confirmed by IR DATA and their UV absorption and PL spectra were also confirmed.

### Example 3

### Fabrication of QD-LED Device

QD-LED was manufactured on (ITO/glass) substrate (sheet resistance <10Ω/□) coated with indium tin oxide. ITO glass was washed with acetone and isopropylalcohol using ultrasonic wave for one minute and underwent argon/oxygen plasma treatment for one minute.

Poly(3,4-ethylene dioxythiophene):poly(styrene sulfonate) (PEDOT:PSS, Baytron P AI 4083) was diluted at a 9:1 volume ratio with isopropylalcohol and then spin-coated at 4000 rpm for 30 seconds. ITO glass coated with PEDOT:PSS was baked by a hot plate to 120° C. in the air for 10 minutes.

After the coated substrate was spin-coated at 3,000 rpm with polyvinylcarbazole (PVK, 0.01 g/mL of chlorobenzene) in a glove box filled with N₂ for 30 minutes, the substrate underwent baking treatment at 180° C. for 30 minutes, and used as a hole transport layer. The white quantum dot solution produced in the above example 1 as a light-emitting layer was spin-coated at 1,500 rpm for 20 seconds.

Next, ZnO nanoparticle (30 mg/mL) solution was spin-coated at 1,500 rpm for 30 seconds and the substrate was baked at 150° C. for 30 minutes. Lastly, the produced multilayer thin film substrate was placed into a high vacuum deposition chamber (background pressure ˜5×10⁻⁶ torr) to deposit aluminum cathode (thickness of 100 nm).

### Comparative Example 1

### Fabrication of Orange QD-LED Device

Orange quantum dots (CdSe/ZnO580) were used as a light-emitting layer, instead of the white quantum dots in Example 3.

### Comparative Example 2

### Fabrication of Blue OLED Device

DJ-A-1 of the above synthesis example 3 was used as a light-emitting layer, instead of the white quantum dots in Example 3.

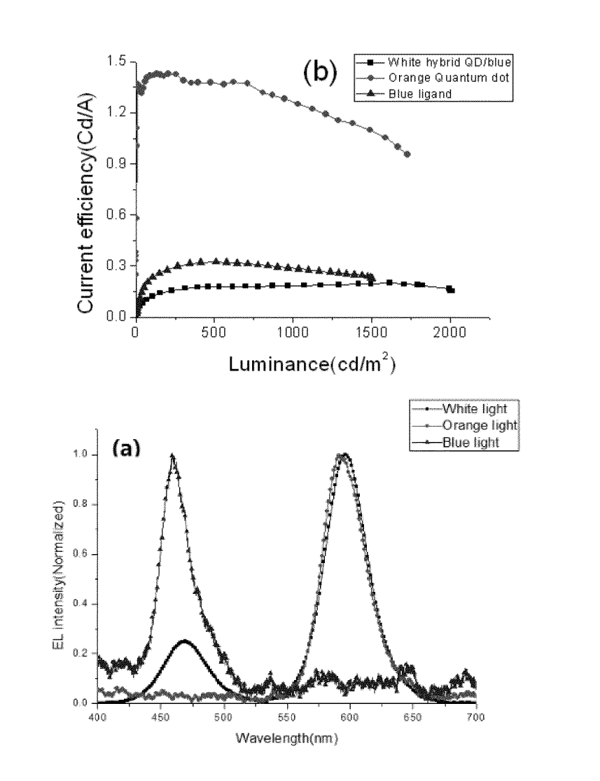

UV absorption and PL spectra of the light-emitting devices of above Example 3 and Comparative Examples 1-2 were measured and shown in FIG. 4. In FIG. 4, a), b), and c) represent Comparative Example 1, Comparative Example 2, and Example 3, respectively.

Also, IVL characteristics and EL spectrum of electroluminescent (EL) devices of the light-emitting devices of above Example 3 and Comparative Examples 1-2 were measured and shown in the following Table 1 and FIG. 5.

TABLE 1

| | | | FWHM | | |
|---|---|---|---|---|---|
| Color of LED | V_{T} (V) | λₘₐₓ (nm) | (nm) | Lₘₐₓ (cd/m²) | ηA (cd/A) |
| Ex. 3 | 5.2 | 470, 595 | 40 | 2015 | 0.19 |
| Com. Ex. 1 | 4.9 | 590 | 39.2 | 1790 | 1.27 |
| Com. Ex. 2 | 4.4 | 460 | 27.8 | 1502 | 0.29 |

### Example 4

### Fabrication of High Color Purity QD-LED Device

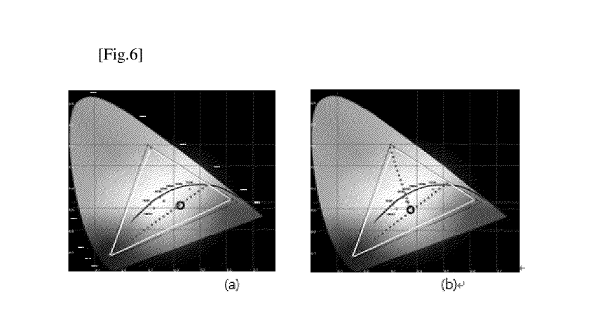

A high color purity QD-LED was produced using the high color purity light-emitting device of Example 2, instead of the light-emitting device of Example 1, in accordance with the method of above Example 3. FIG. 6 shows the color coordinates of the QD-LED devices of Example 3(a) and Example 4(b).

As shown in FIG. 6, the device of Example 4 where blue ligand and green ligand were co-used to orange QD shows white color having higher color purity than the device of Example 3 where blue ligand was used to orange QD to express white color.

The light-emitting quantum dot according to the present invention has excellent dispersibility and stability in an aqueous solution and high color purity and light-emitting properties when applied to a light-emitting device, so that it enables excellent color purity, high stability and high luminous efficiency when compared to the previous light-emitting devices.

What is claimed is:

1. A light-emitting quantum dot comprising a core/shell structure and a ligand which is attached to the surface of the shell, wherein the ligand comprises a light-emitting group.

2. The light-emitting quantum dot as claimed in claim 1, wherein the ligand comprises a light-emitting group, and a linking group for connecting the shell and the light-emitting group.

3. The light-emitting quantum dot as claimed in claim 2, wherein the ligand further comprises a spacer between the linking group and the light-emitting group.

4. The light-emitting quantum dot as claimed in claim 1, wherein the light-emitting group is one or more selected from the group consisting of the following materials: 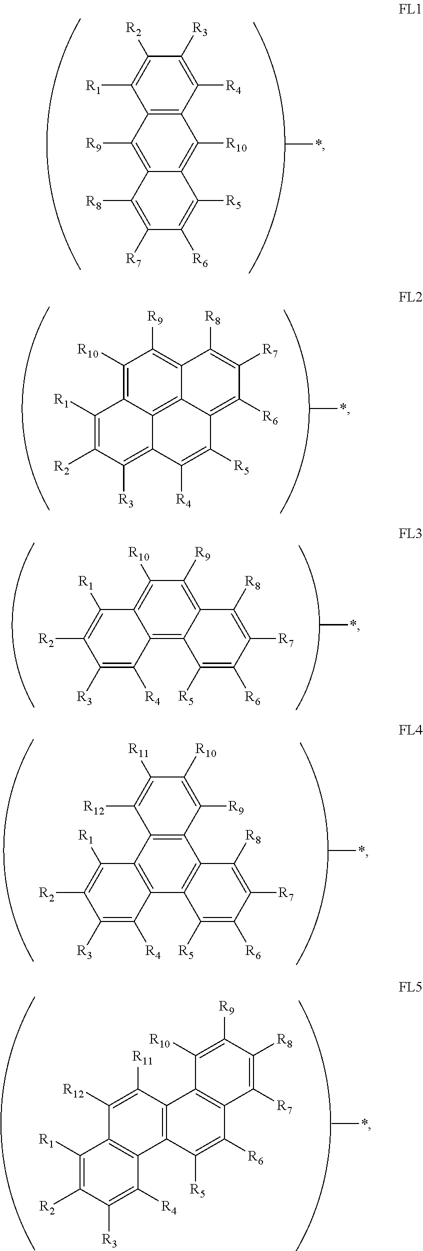 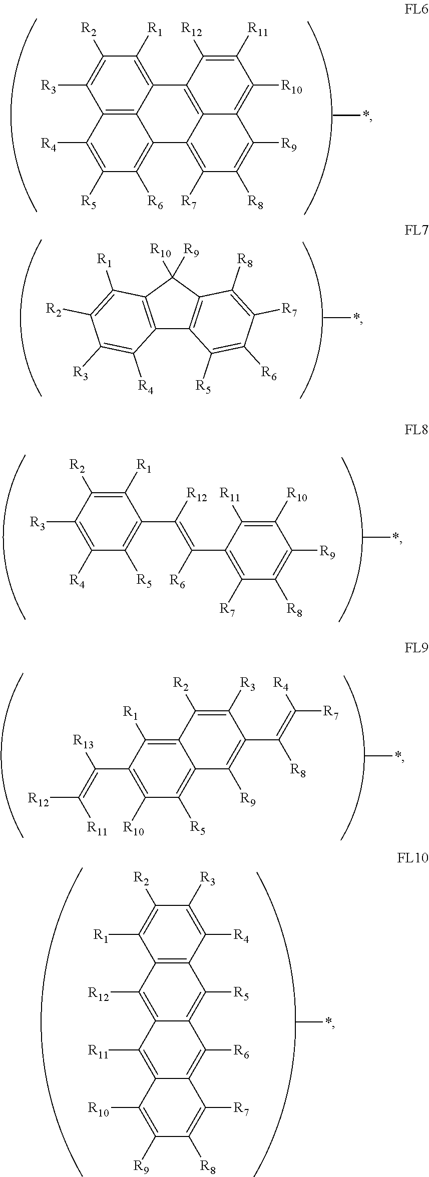 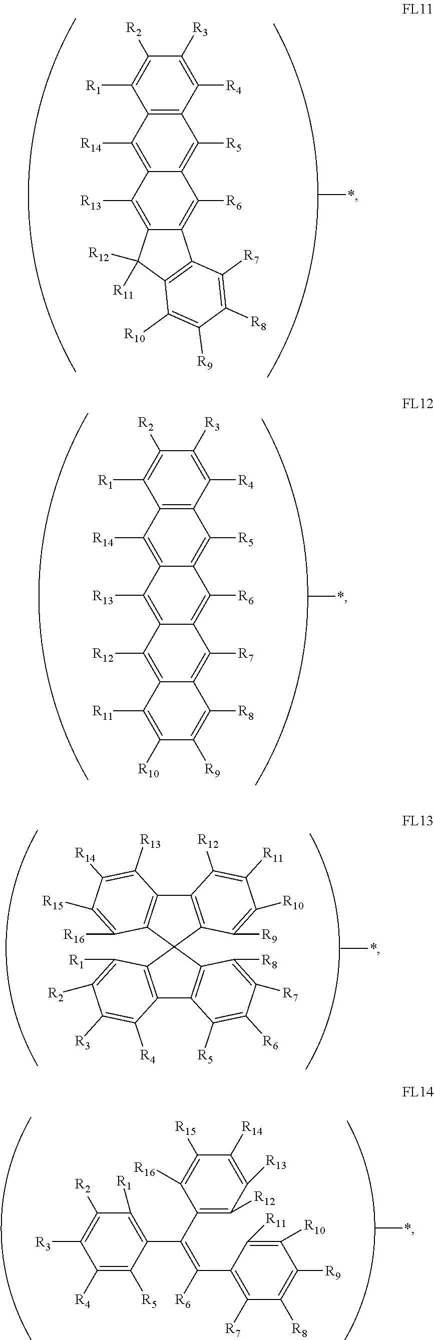 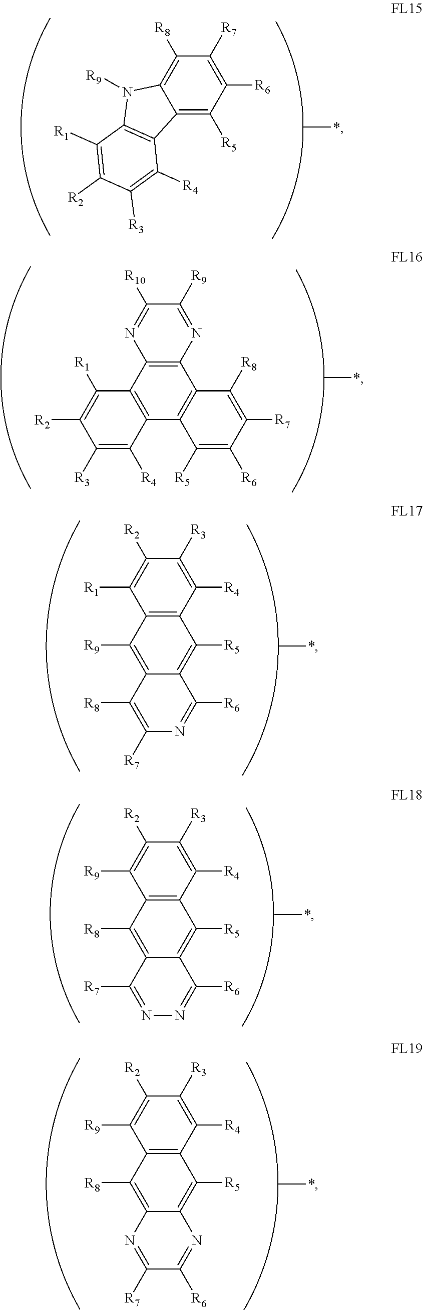 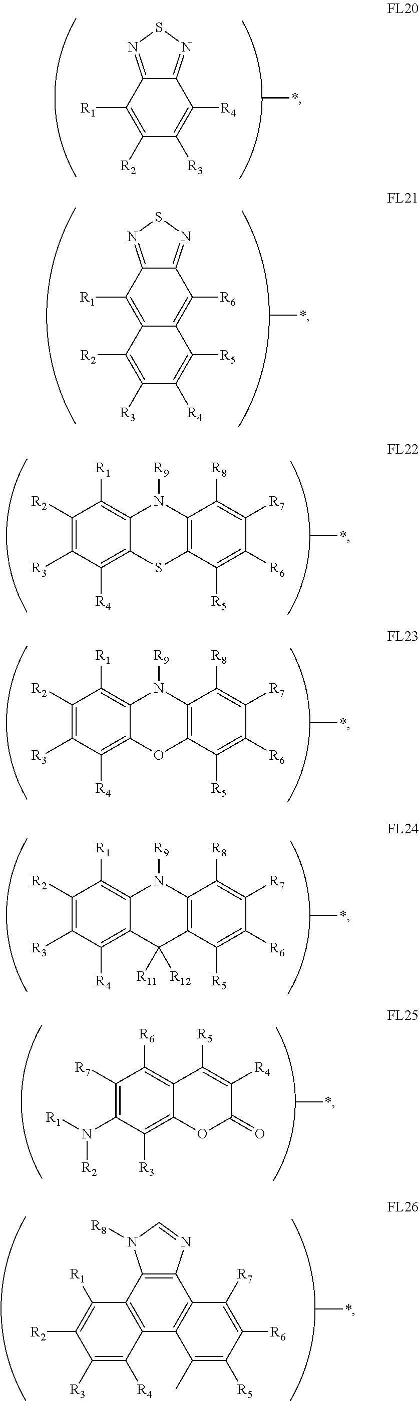 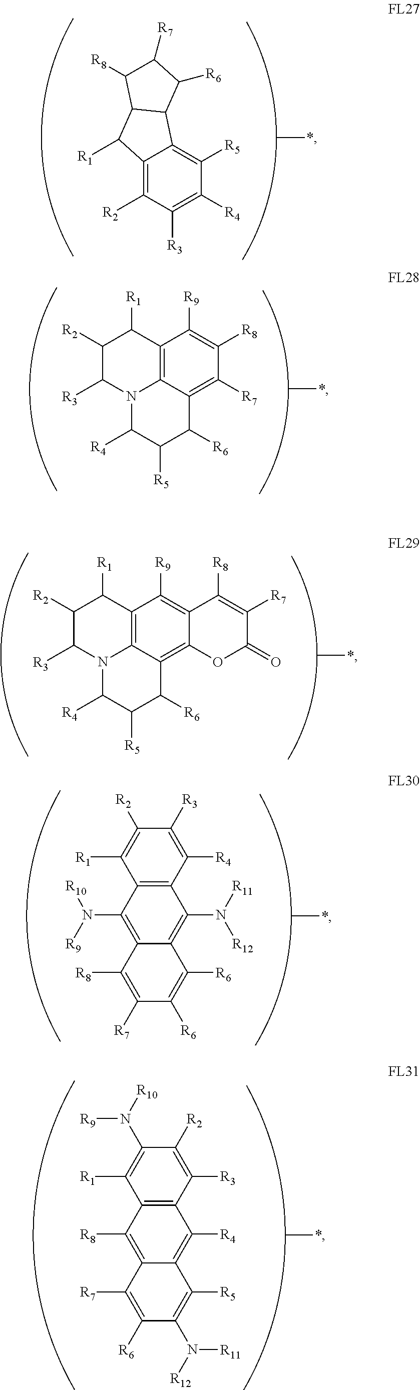 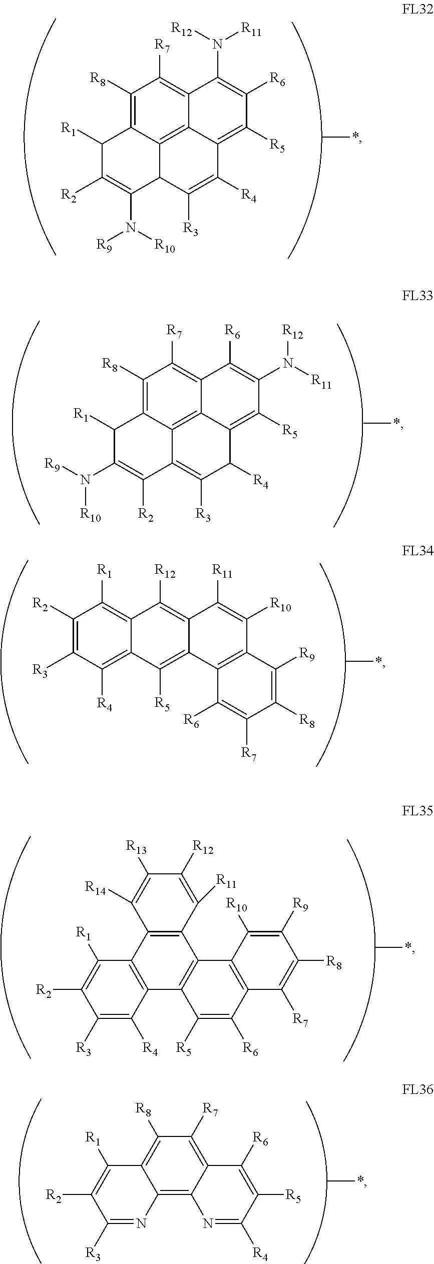 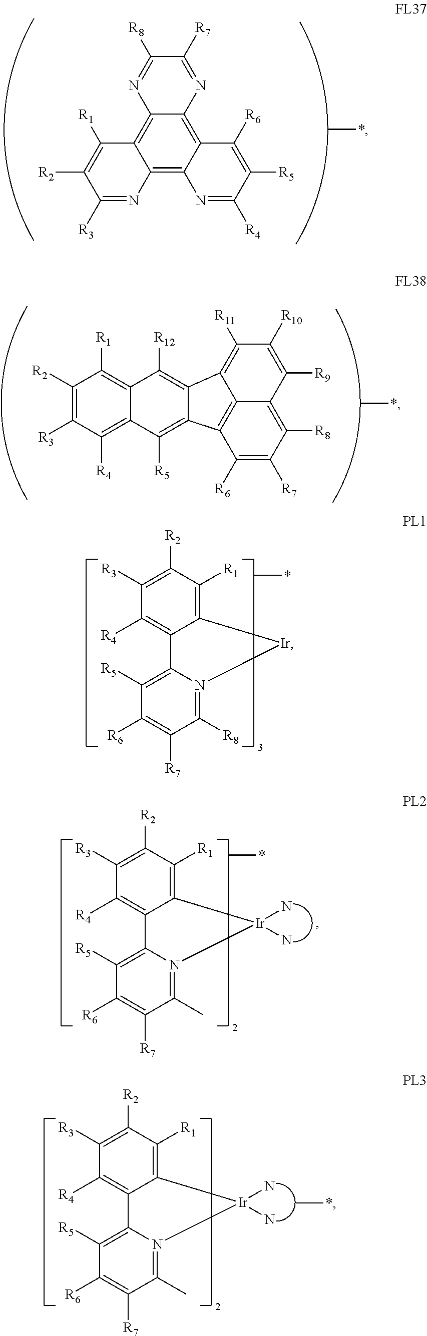 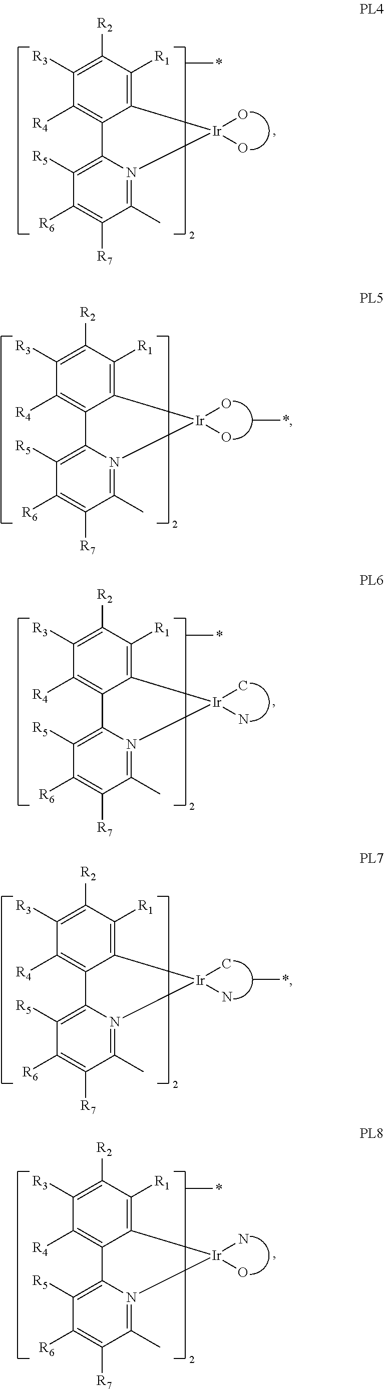 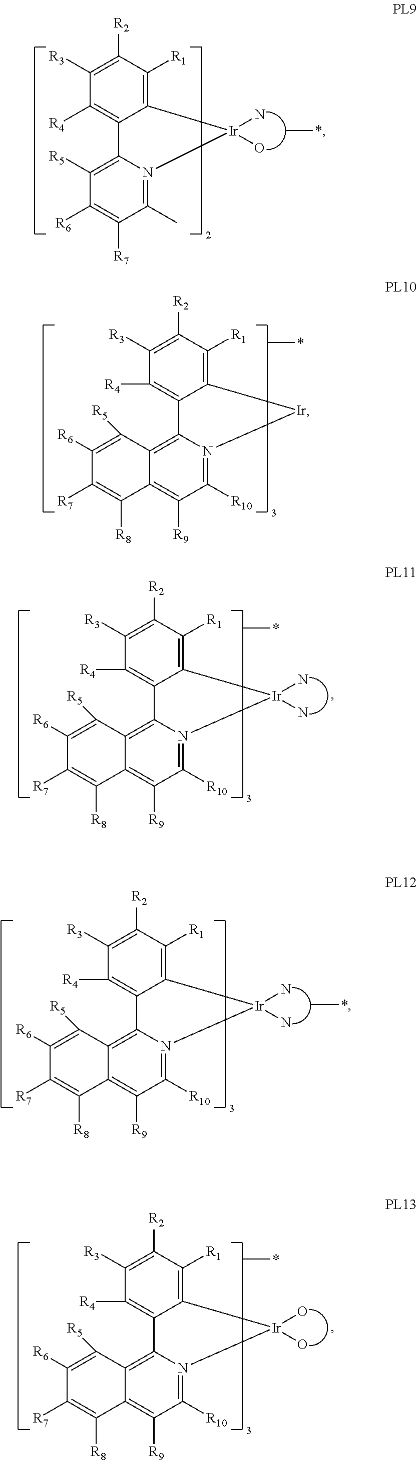 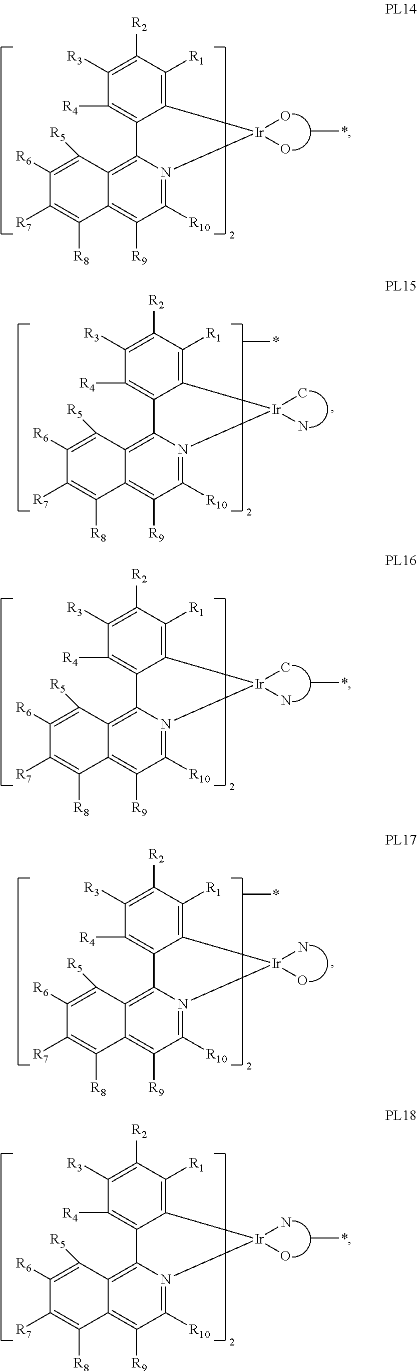 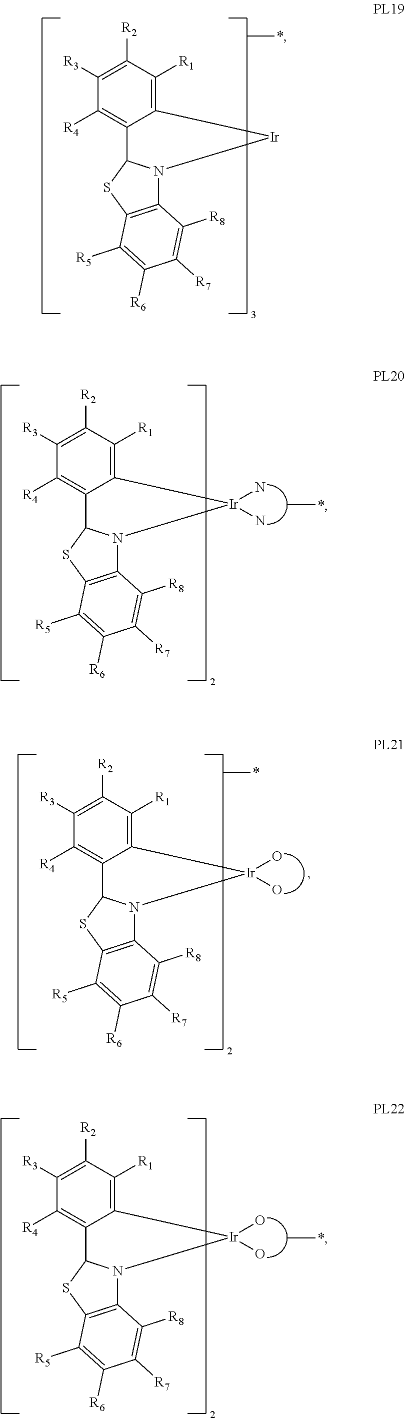 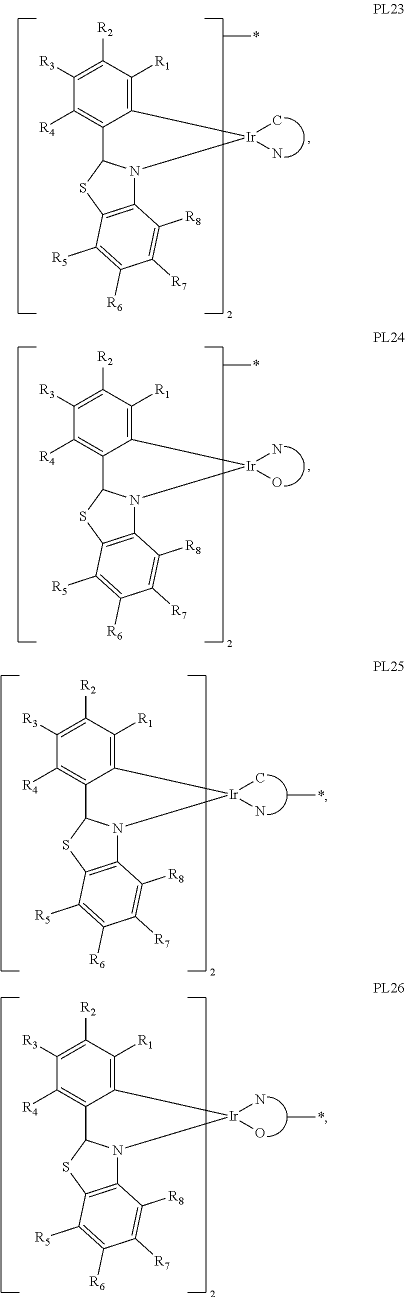 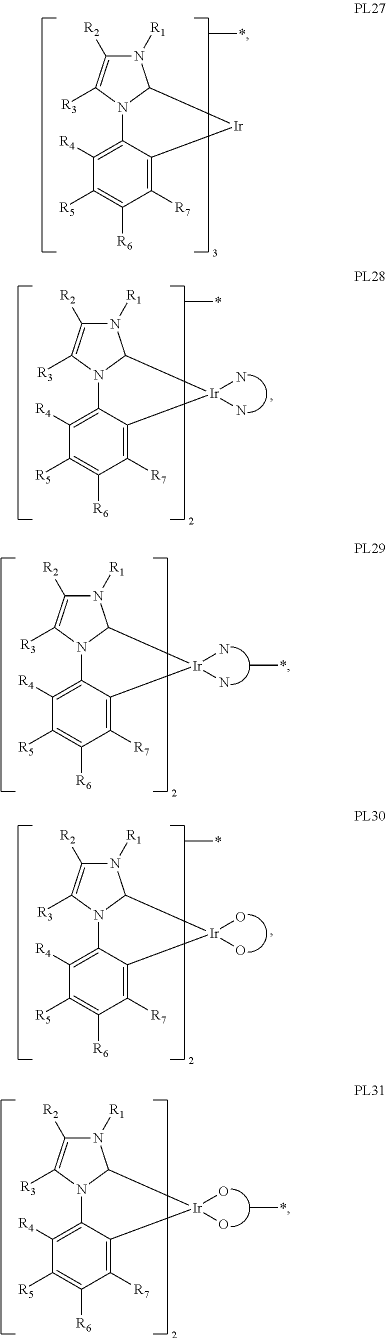 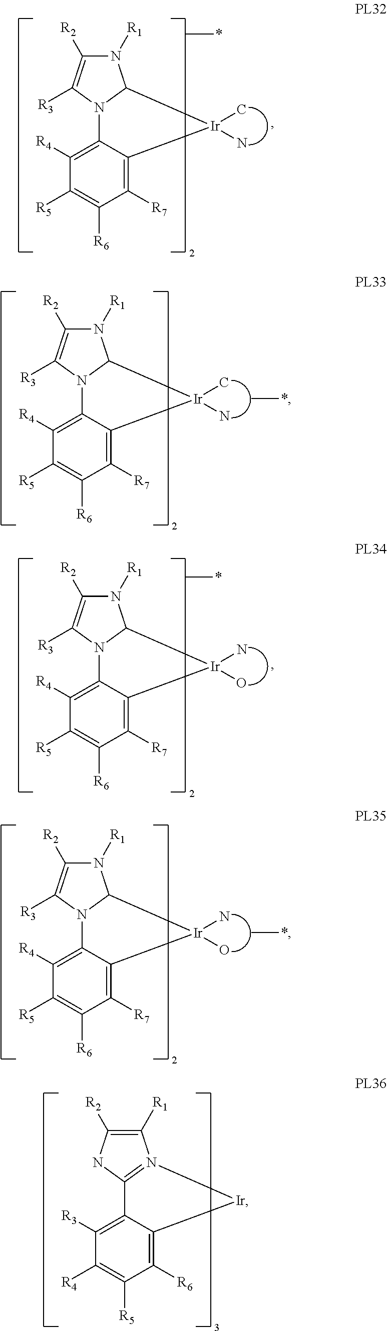 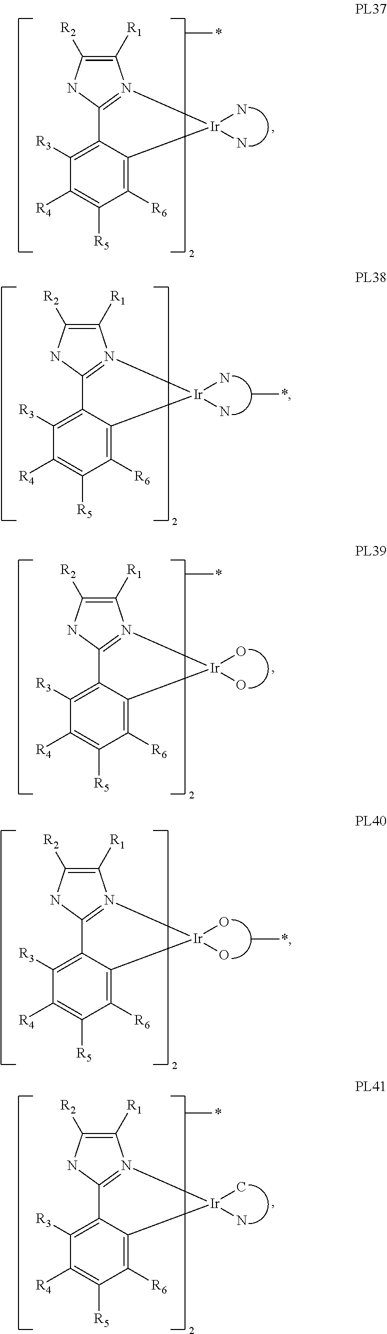 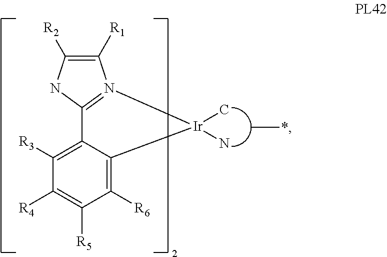 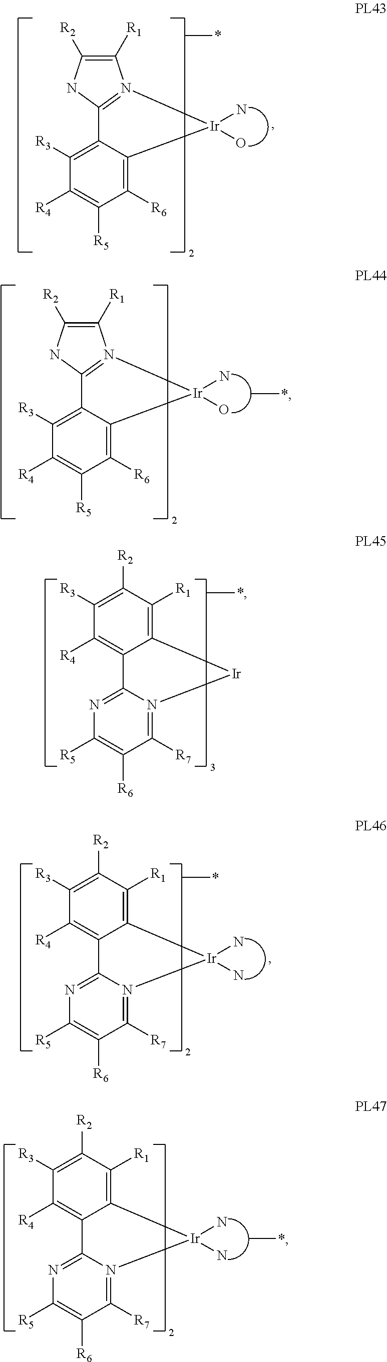 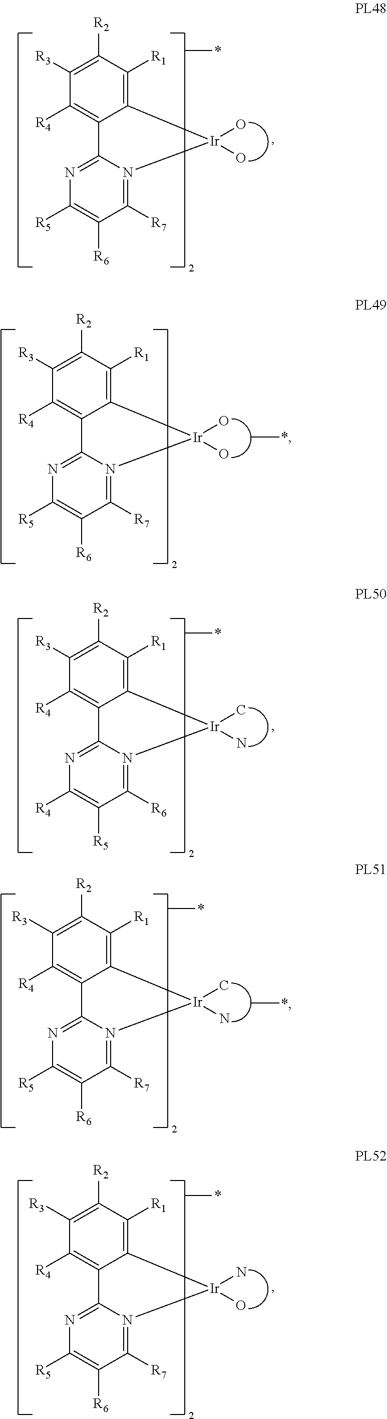 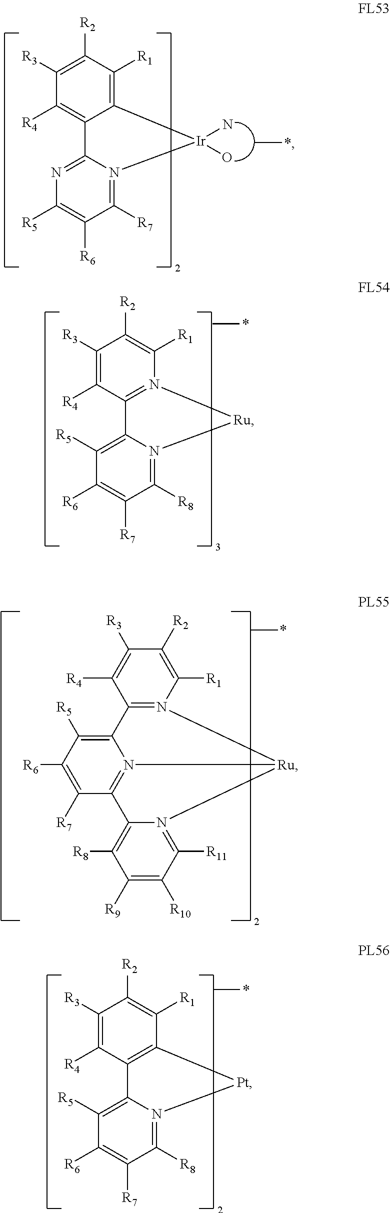 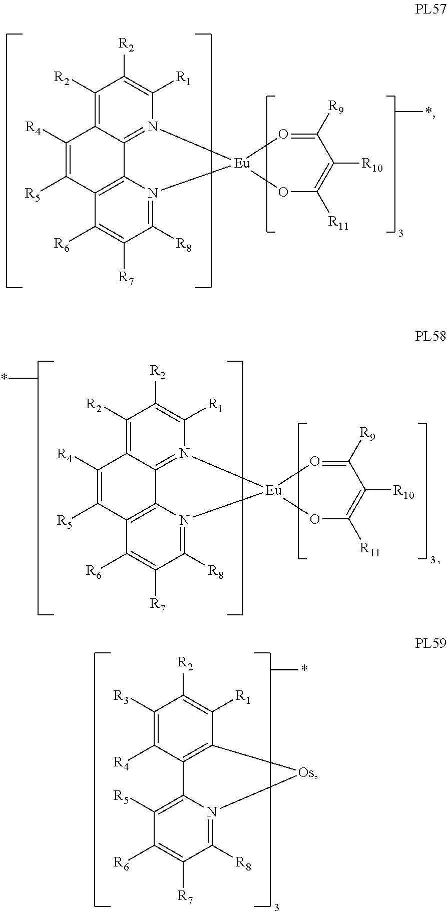
(In above FL1 to FL38, or PL1 to PL59, * is a connection portion wherein the connection portion may be connected to at least one of the substitution positions in parentheses, and R1 to R16 are each independently hydrogen; deuterium; halogen; an amino group; a nitrile group; a nitro group; an alkyl group of C₁-C₄₀; an alkenyl group of C₂-C₄₀; an alkoxy group of C₁-C₄₀; a cycloalkyl group of C₃-C₄₀; a heterocycloalkyl group of C₃-C₄₀; an aryl group of C₆-C₄₀; a heteroaryl group of C₃-C₄₀; an aralkyl group of C₃-C₄₀; an aryloxy group of C₃-C₄₀; an arylthio group of C₃-C₄₀ optionally substituted with deuterium, halogen, an amino group, a nitrile group or a nitro group; or Si. Optionally, two or more selected from R1 to R16 may be bonded to one another to form a ring, and S, N, O, or Si may be included.)

5. The light-emitting quantum dot as claimed in claim 1, wherein the light-emitting group emits light in the region of 400 to 800 nm.

6. The light-emitting quantum dot as claimed in claim 2, wherein the linking group is at least one selected from the group consisting of a thiol group, a carboxy group, an amine group, a phosphine group, and a phosphide group.

7. The light-emitting quantum dot as claimed in claim 3, wherein the spacer is a substituted or unsubstituted, saturated or unsaturated alkyl group of C₁-C₃₀, cycloalkyl group of C₃-C₄₀, or silane of Si₁-Si₃₀.

8. The light-emitting quantum dot as claimed in claim 3, wherein the ligand is one of the following structures: 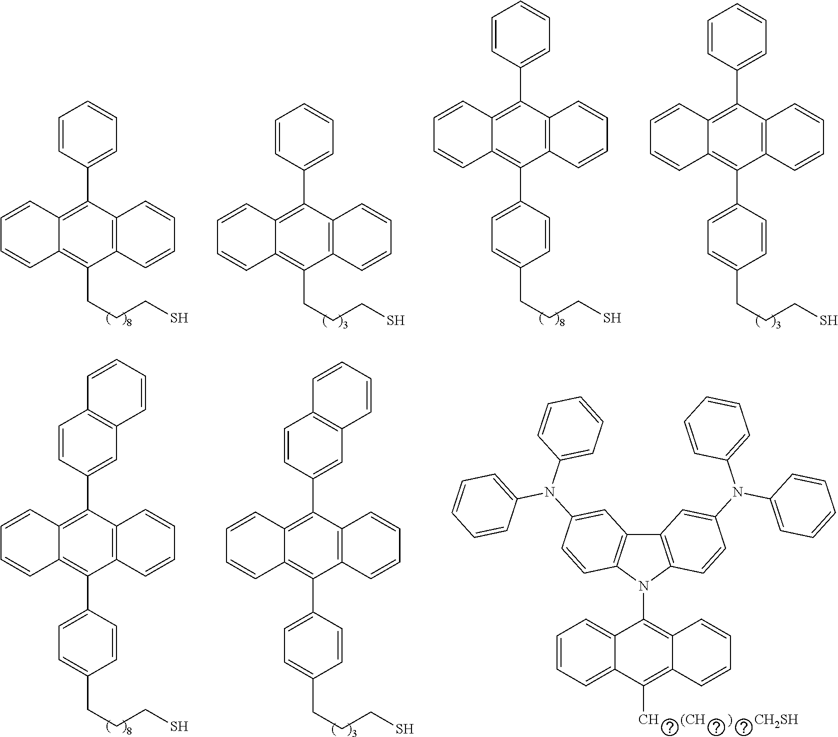 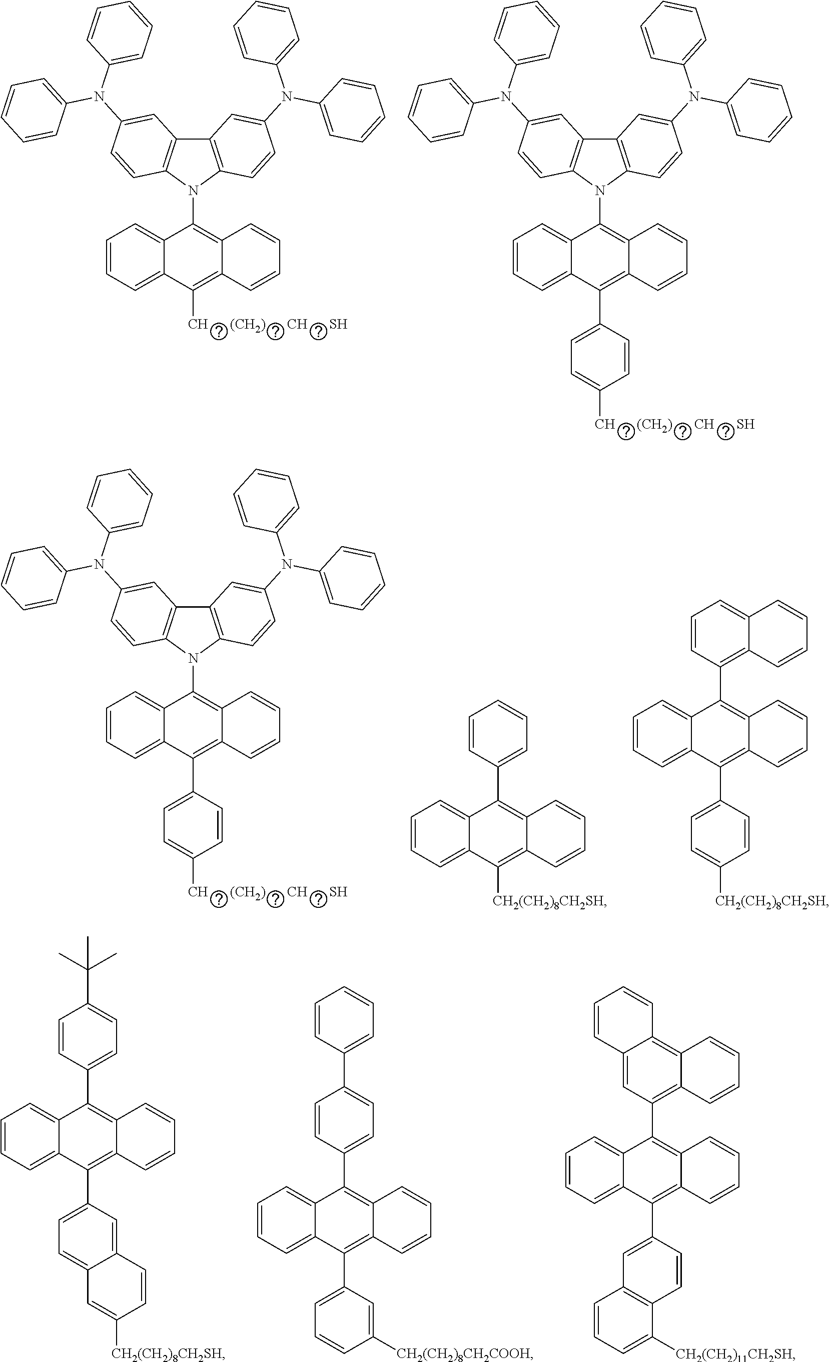 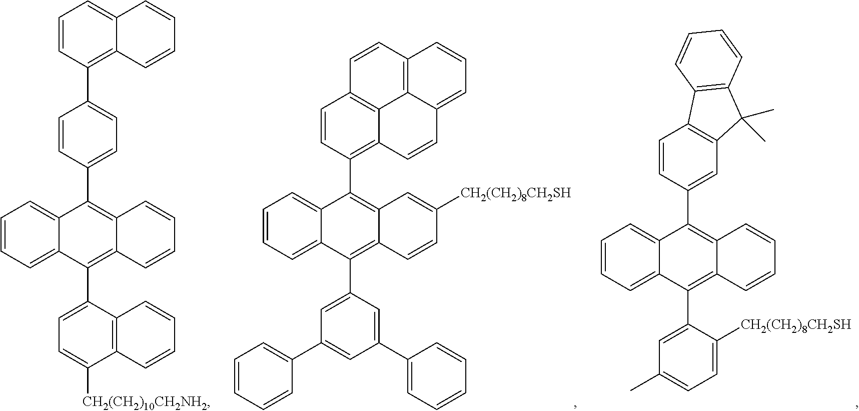 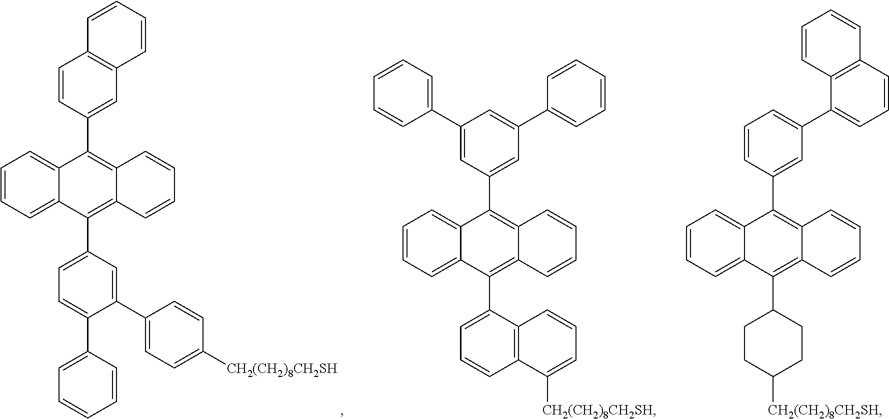 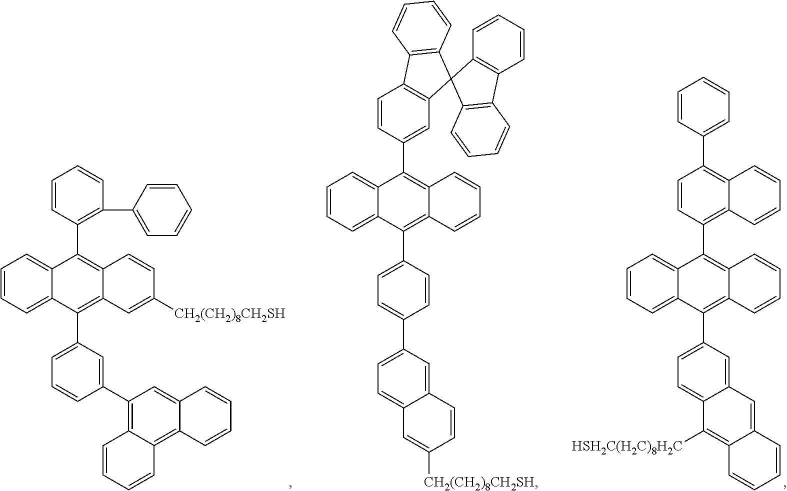 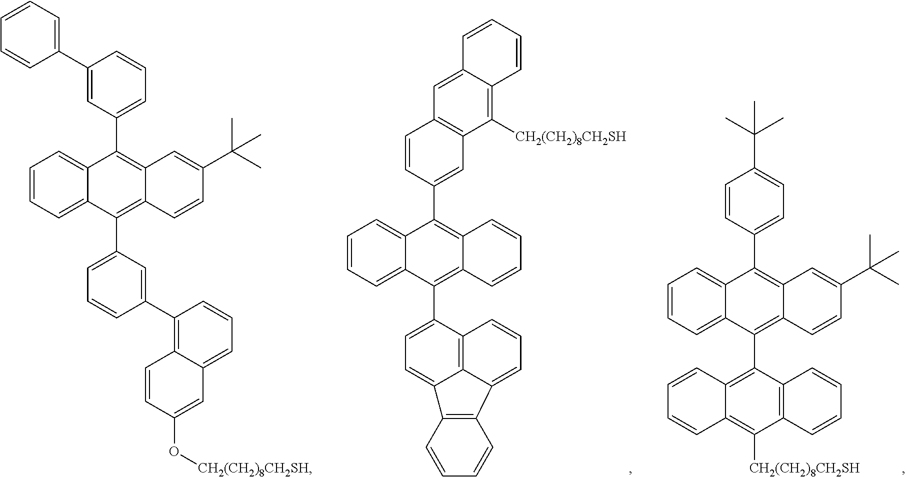 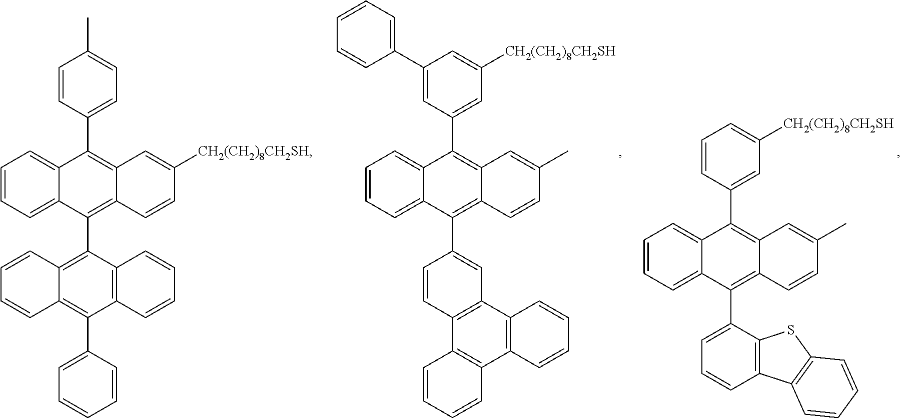 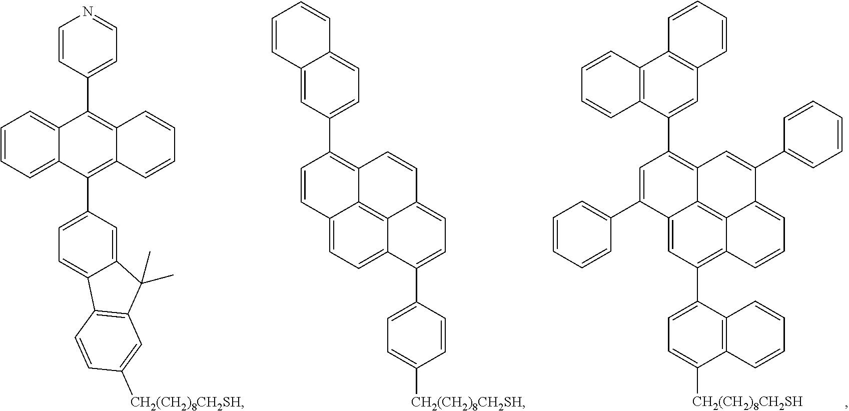 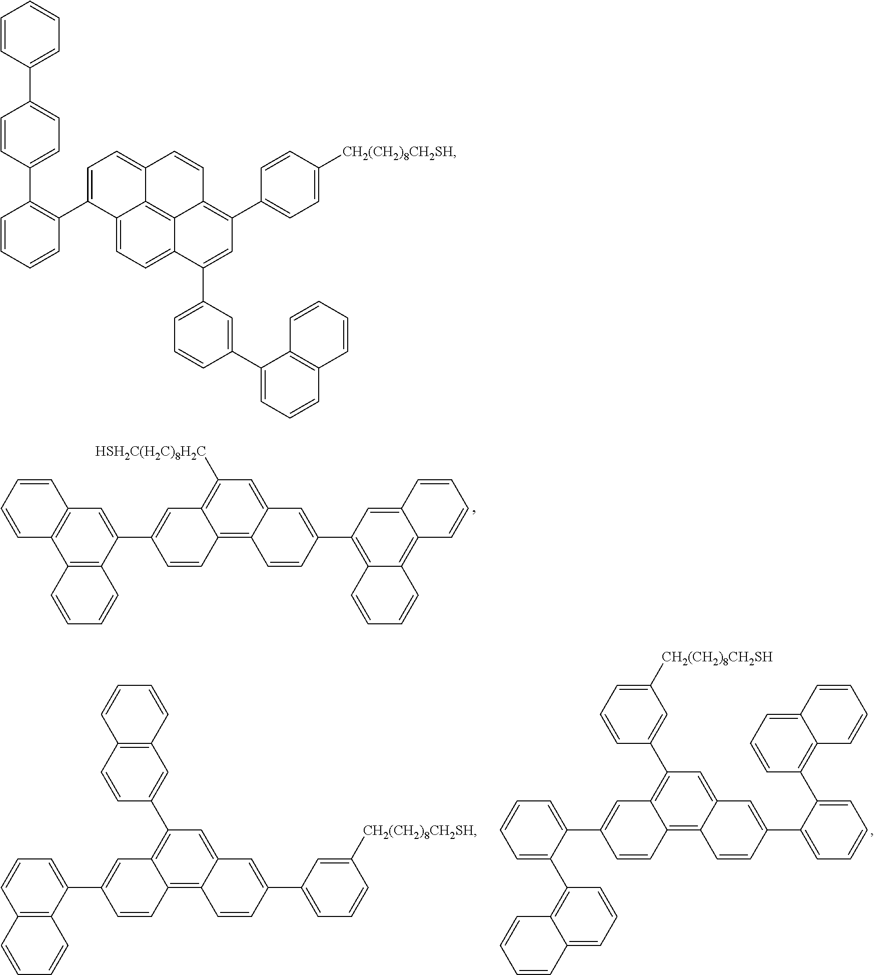 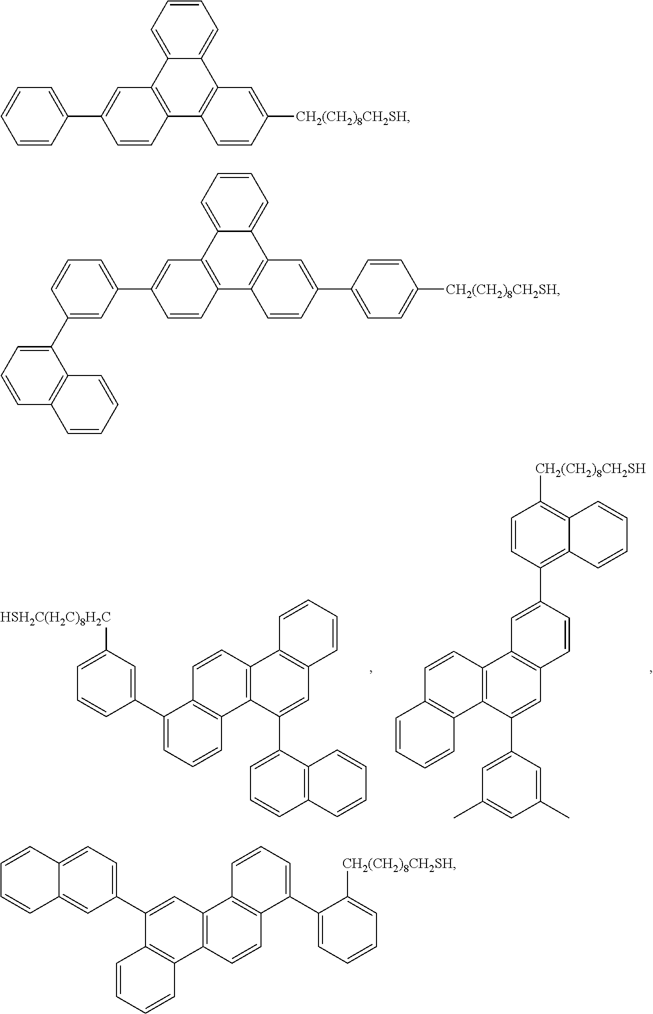 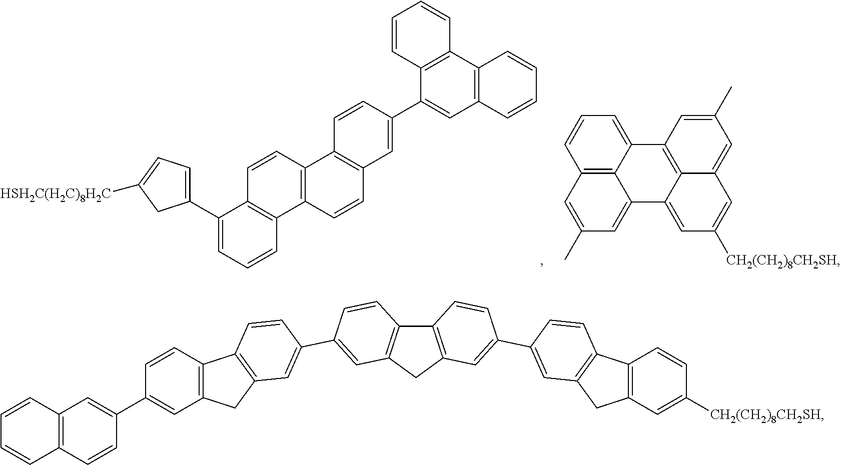 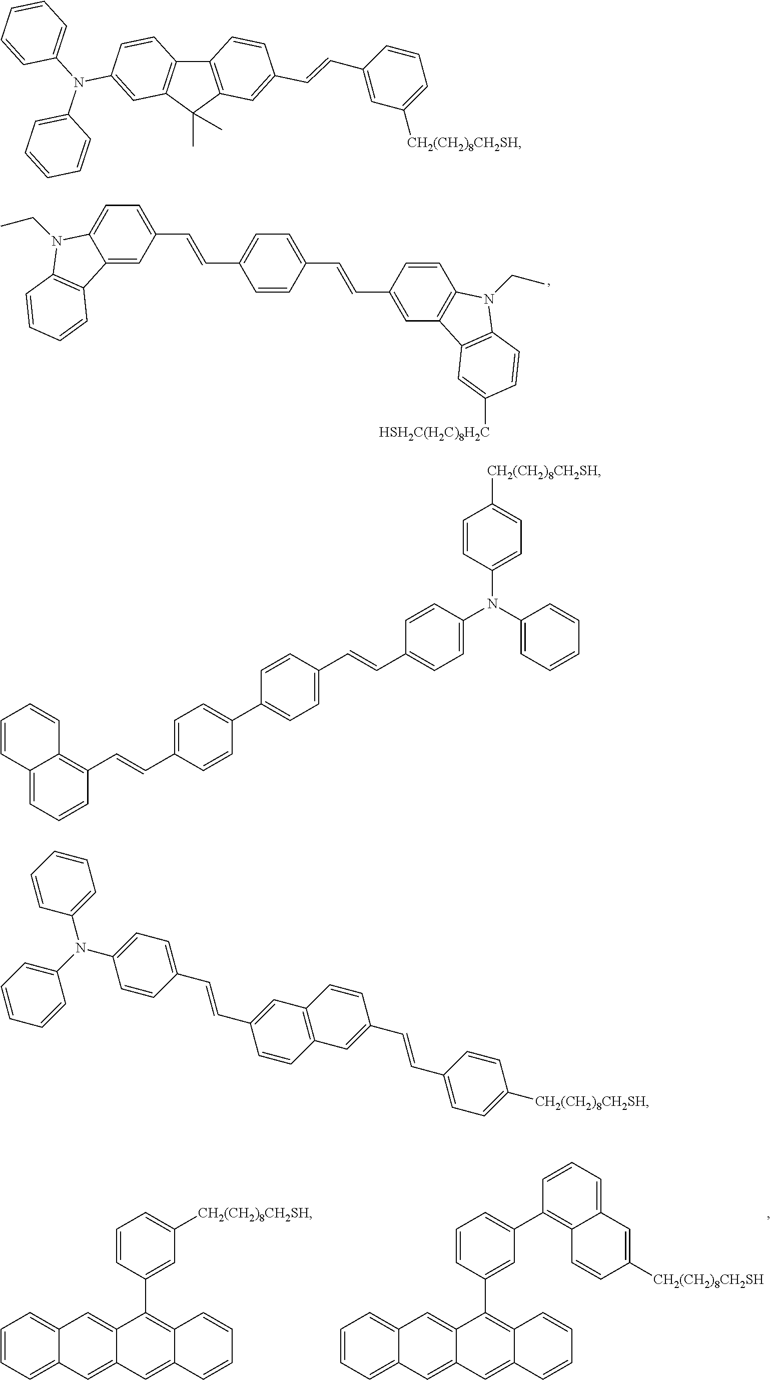 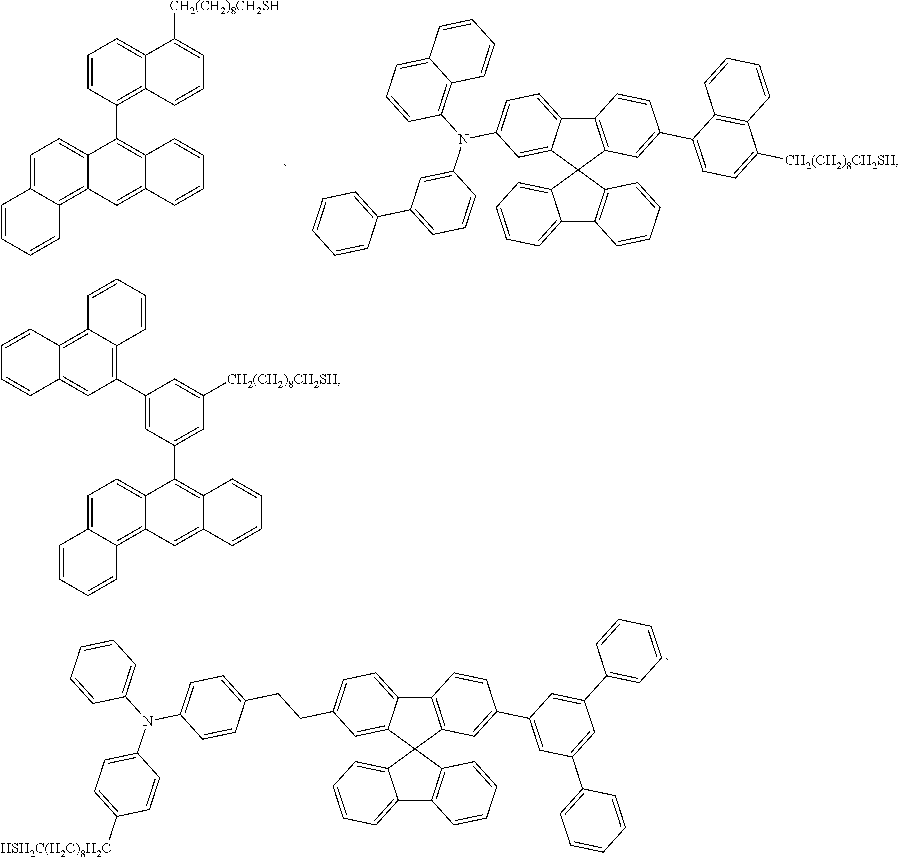 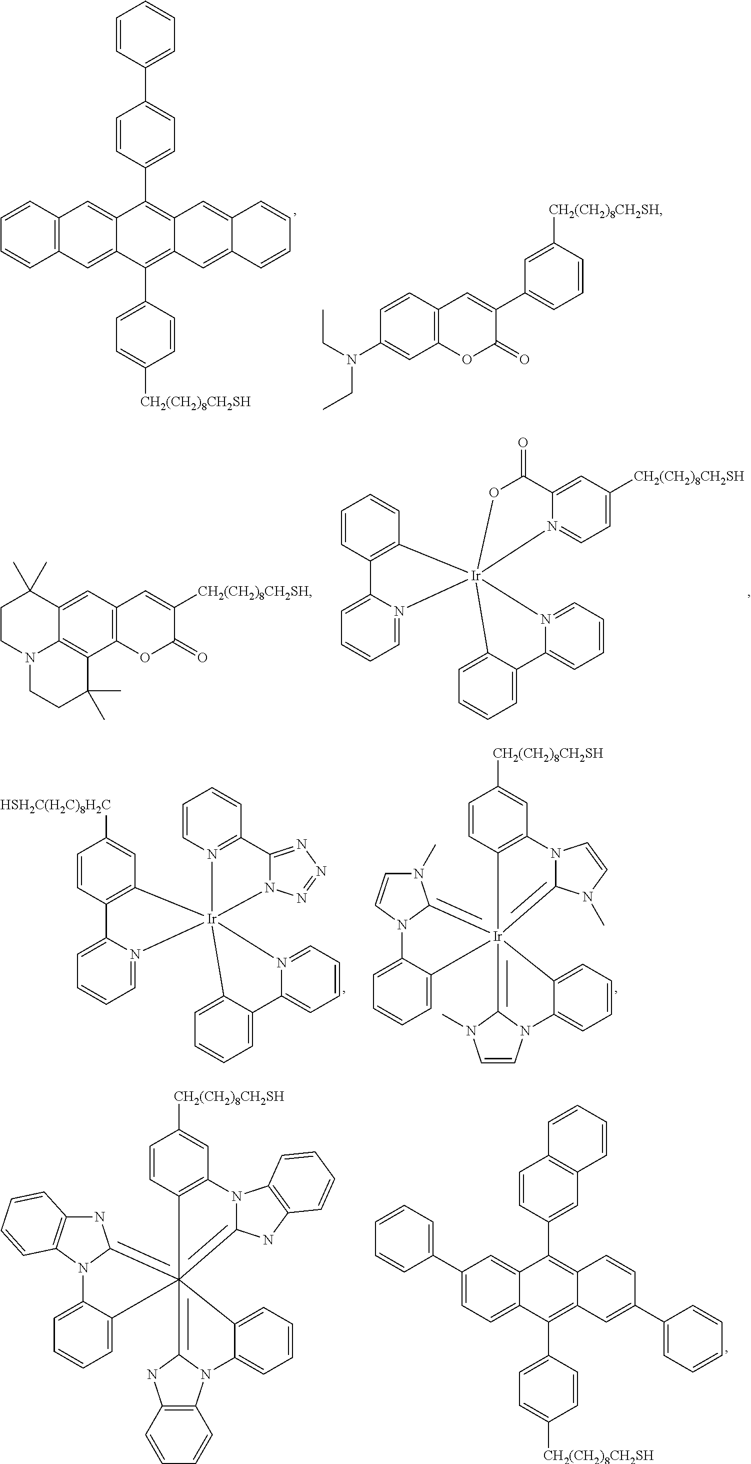 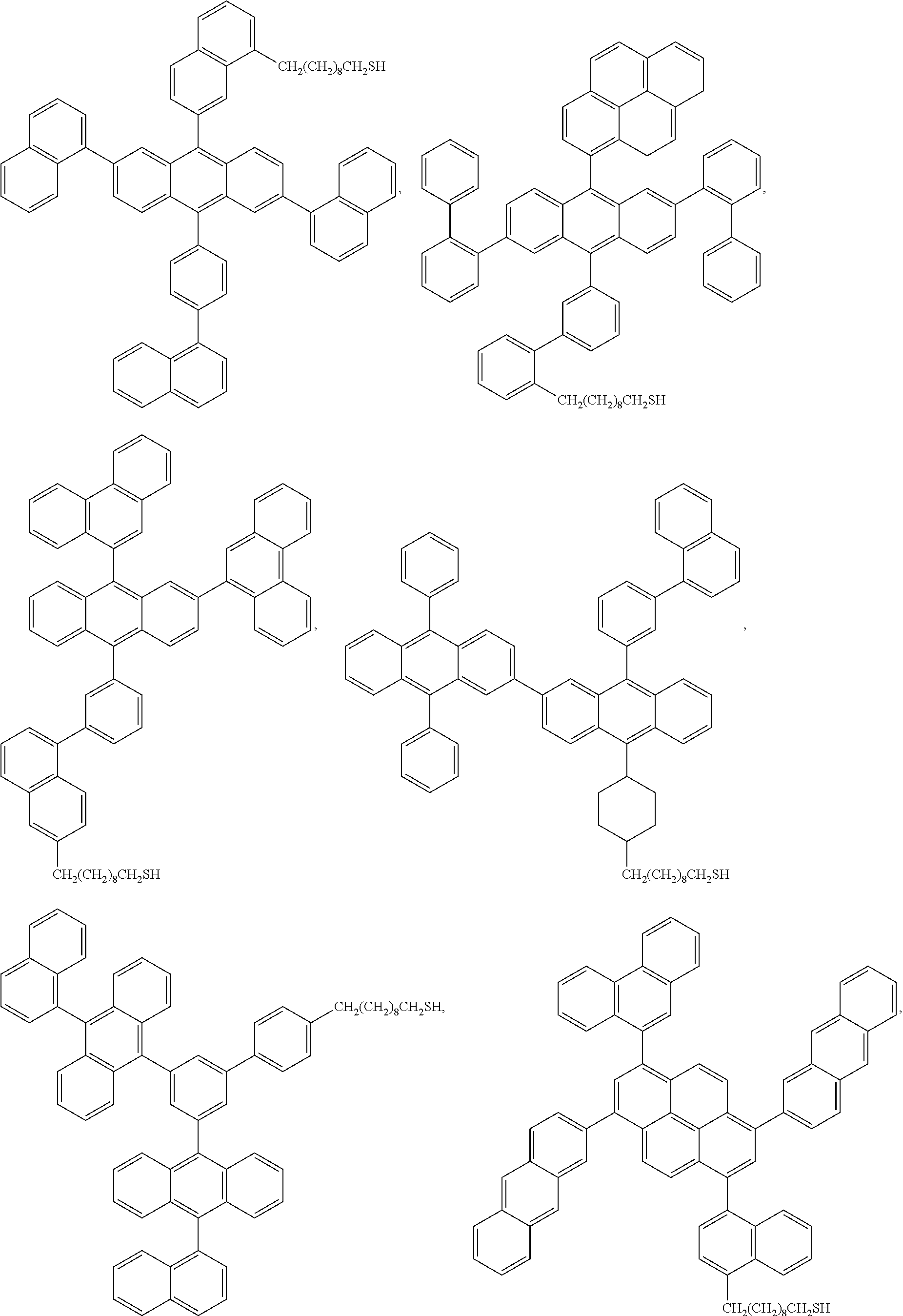 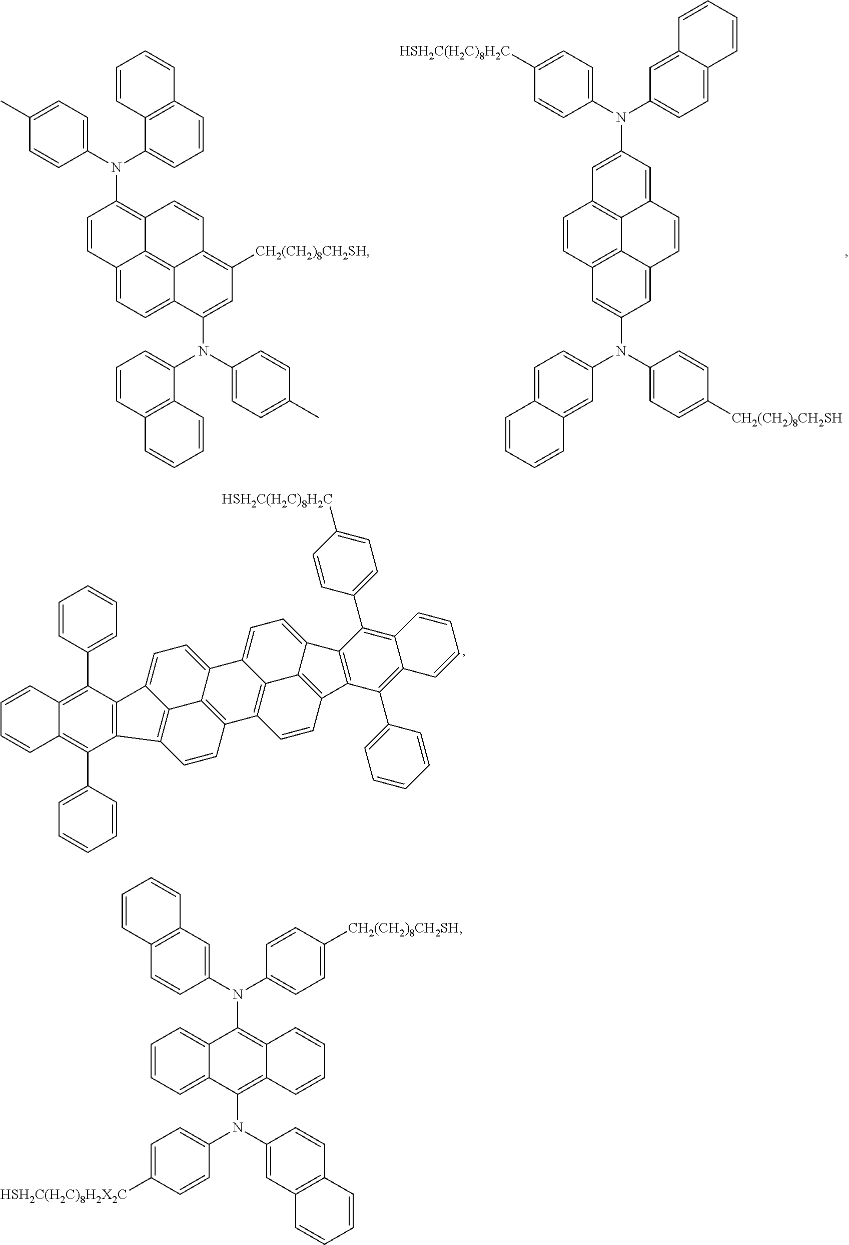 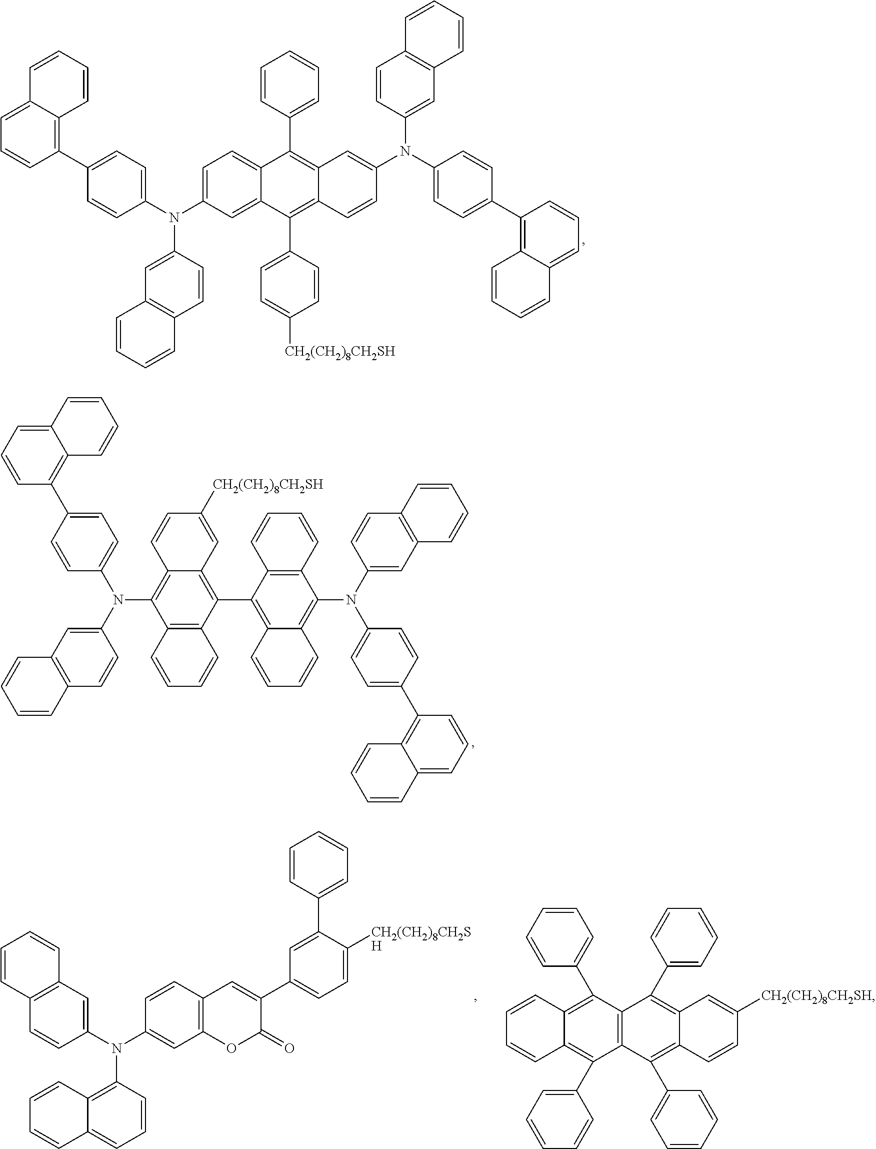 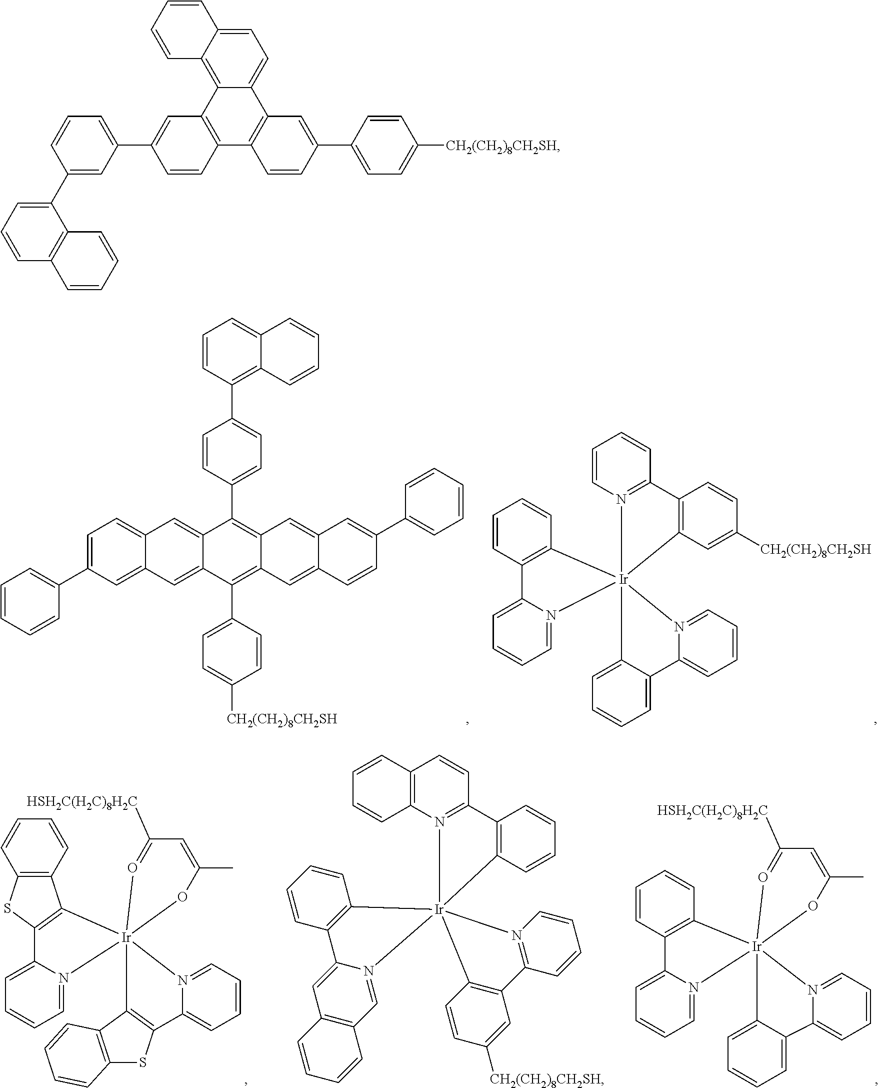 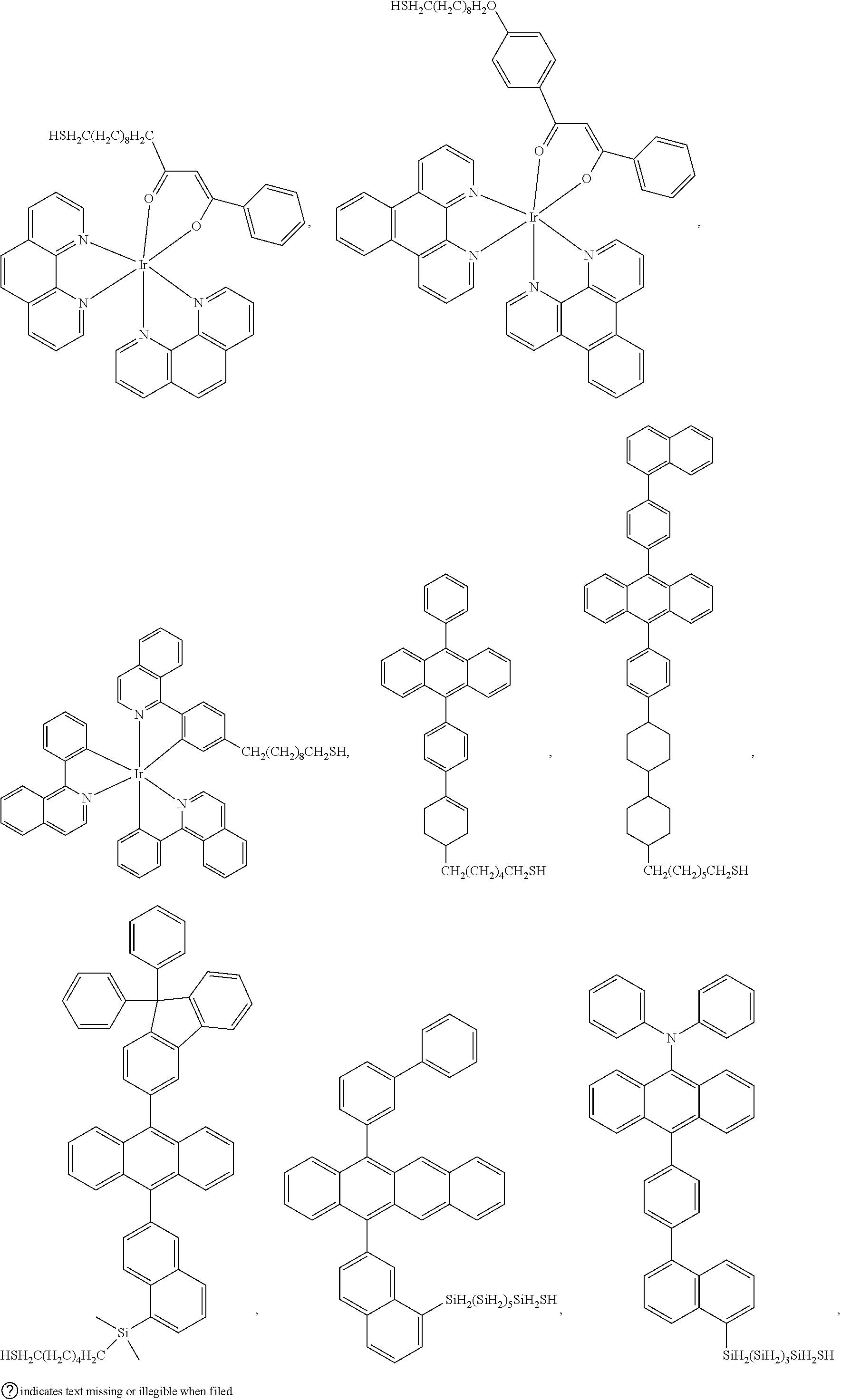
(In the above structures, a portion H in —SH, COOH, and NH is a portion for binding to the core/shell structure.)

9. The light-emitting quantum dot as claimed in claim 1, wherein the diameter of the quantum dot is 5 to 30 nm.

10. A method for the preparation of the light-emitting quantum dot as defined in claim 1, comprising adding a ligand containing a light-emitting group to a solution dispersed with a core/shell structure, and then stirring it.

11. The method for the preparation of the light-emitting quantum dot as claimed in claim 10, wherein the stirring is conducted at a temperature from a room temperature to 100° C. for 0.1 to 100 hours.

12. A light-emitting device characterized by comprising the light-emitting quantum dot as defined in claim 1 as a light-emitting material.

13. A method of manufacturing a light-emitting device characterized by comprising a step of forming a light-emitting layer using the light-emitting quantum dot as defined in claim 1.
